(19) United States
(12) Patent Application Publication
(10) Pub. No.: US 2025/0243224 A1
(43) Pub. Date: Jul. 31, 2025

(54) COMPOUND AND ORGANIC ELECTROLUMINESCENT DEVICE

(71) Applicant: Samsung Electronics Co., Ltd., Suwon-si (KR)

(72) Inventors: Keisuke KORAI, Kanagawa (JP); Rie SAKURAI, Kanagawa (JP); Satoshi INAYAMA, Kanagawa (JP); Eigo MIYAZAKI, Kanagawa (JP); Raesung KIM, Suwon-si (KR); Sungho NAM, Suwon-si (KR)

(21) Appl. No.: 19/021,469

(22) Filed: Jan. 15, 2025

(30) Foreign Application Priority Data
Jan. 25, 2024 (JP) 2024-009321
Oct. 22, 2024 (KR) 10-2024-0145153

(51) Int. Cl. C07F 5/02; C09K 11/06; H10K 50/12; H10K 85/40; H10K 85/60; H10K 101/00; H10K 101/20

(52) U.S. Cl. CPC C07F 5/027; C09K 11/06; H10K 50/12; H10K 85/40; H10K 85/633; H10K 85/656; H10K 85/6572; H10K 85/6574; H10K 85/6576; H10K 85/658; H10K 2101/20; H10K 2101/27

(57) ABSTRACT

A luminescent material including a polycyclic group structure represented by Formula 2 connected to ring Ar¹ or ring Ar² of a structure represented by Formula 1, and at least one group structure, but not more than four group structures, each represented by Formula 3 connected to at least one of ring Ar⁵ or ring Ar⁶ in the polycyclic group structure represented by Formula 2. Formulae 1, 2, and 3 are described herein.

### CROSS-REFERENCE TO RELATED APPLICATION

This application claims priority to Korean Patent Application No. 10-2024-0145153, filed on Oct. 22, 2024, in the Korean Intellectual Property Office, and to Japanese Patent Application No. 2024-009321, filed on Jan. 25, 2024, in the Japanese Patent Office, and the benefits accruing therefrom under 35 U.S.C. § 119, the disclosures of which in their entirety are incorporated by reference herein.

### BACKGROUND

### 1. Field

The disclosure relates to a compound and an organic electroluminescent (EL) device.

### 2. Description of the Related Art

Organic electroluminescent (EL) devices have been employed as displays in smartphones as well as other consumer-oriented display devices or the like. Accordingly, there are continuing efforts to improve display performance as well as achieving high color purity by using the cavity effect of a top emission method. However, though the cavity effect may achieve improvement in color purity, luminescence efficiency may decrease.

Currently, fluorescent materials and phosphorescent materials are used as luminescent materials in most organic EL devices to achieve the requisite three pixel colors, i.e., red, green, and blue. Among such luminescent materials, there is continued development with blue luminescent materials in terms of improvements in luminescence efficiency, device lifespan, color purity, and the like. One way to improve the luminescence efficiency of a top emission type, blue organic EL device may include the use of a luminescent dopant material that imparts narrow full width at half maximum (FWHM) and high efficiency characteristics to the organic EL device.

Recently, it has been reported that luminescent materials, e.g. Compound a and Compound b (below), which include boron atoms as ring atoms in a polycyclic ring system exhibit blue luminescence and exhibit a narrow FWHM and high luminescence efficiency in an organic EL device. See, e.g., Non-patent Document 1: Takuji Hatakeyama, et al., in “Ultrapure Blue Thermally Activated Delayed Fluorescence Molecules: Efficient HOMO-LUMO Separation by the Multiple Resonance Effect,” Advanced Materials 2016, 28, 2777-2781, and Non-patent Document 2: Yasuhiro Kondo, et al., in “Narrowband deep-blue organic light-emitting diode featuring an organoboron-based emitter,” Nature Photonics 2019, 13, 678-682.

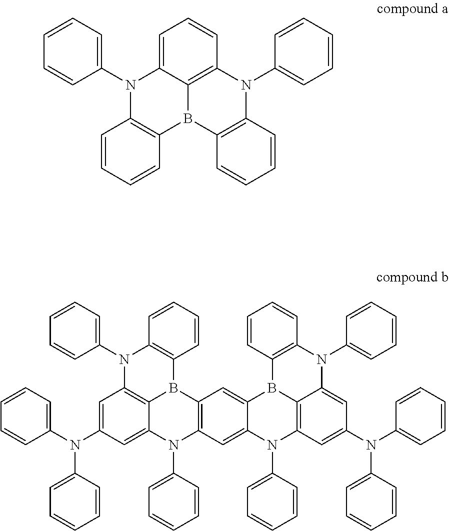 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

### SUMMARY

In an organic electroluminescent (EL) device, a luminescent material with high color purity is required for each of red, green, and blue (R, G, and B) to cover a wide color region. However, for a blue luminescent material, it can be difficult to achieve acceptable luminescence with high color purity. In addition, the materials described in Non-patent Documents 1 and 2 have a wide emission spectrum and insufficient color purity.

Accordingly, we describe herein a novel blue luminescent material which has both a narrow emission spectrum and high color purity, and in addition, exhibits improvement in luminescence efficiency and/or lifespan of an organic EL device.

A compound including: a polycyclic group structure represented by Formula 2 connected to at least one of ring Ar¹ or ring Ar² of a structure represented by Formula 1; and at least one group structure, but not more than four group structures, each represented by Formula 3 connected to at least one of ring Ar⁵ or ring Ar⁶ of the polycyclic group structure represented by Formula 2.

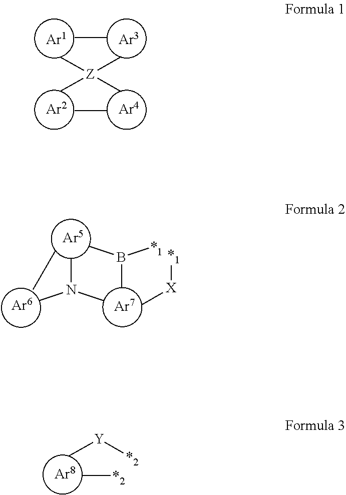

In Formulae 1, 2, and 3,
Ar¹ to Ar⁸ may each independently be a substituted or unsubstituted aromatic hydrocarbon ring having 6 to 30 ring-forming atoms, or a substituted or unsubstituted heteroaromatic ring having 5 to 30 ring-forming atoms,
in Formula 1, Z may be C or Si,
in Formula 2, X may be —O—, —S—, —NR²¹—, or —CR²²R²³—, wherein R²¹, R²², and R²³ may each independently be hydrogen, deuterium, a substituted or unsubstituted alkyl group, a substituted or unsubstituted aryl group, or a substituted or unsubstituted heteroaryl group,
wherein, if X is —NR²¹—, then R²¹ may be bonded to a ring-forming atom of Ar⁷,
in Formula 2, binding sites *1 may be bonded to adjacent ring-forming atoms of Ar¹, or binding sites *1 may be bonded to adjacent ring-forming atoms of Ar², in the structure represented by Formula 1 to form a six-membered ring, and
in Formula 3, Y may be —O—, —S—, or —NR³¹—,
wherein R³¹ may be hydrogen, deuterium, a substituted or unsubstituted alkyl group, a substituted or unsubstituted aryl group, or a substituted or unsubstituted heteroaryl group, and
binding sites *2 may be bonded to adjacent ring-forming atoms of Ar⁵, or binding sites *2 may be bonded to adjacent ring-forming atoms of Ar⁶, in the polycyclic group structure represented by Formula 2 to form a five-membered ring.

A compound including a group structure represented by Formula 6 that connects to ring Ar¹ or ring Ar² in the structure represented by Formula 1 above:

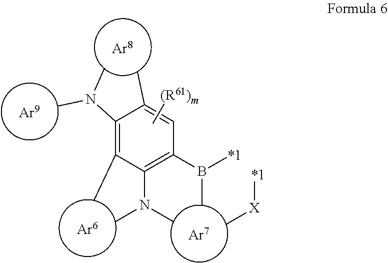

wherein, in Formula 6,
R⁶¹ is deuterium, a substituted or unsubstituted alkyl group, a substituted or unsubstituted aryl group, or a substituted or unsubstituted heteroaryl group,
m is 0 or 1,
Ar⁶, Ar⁷, X, and binding sites *1 are each as described in Formula 2,
Ar⁸ is as described in Formula 3, and
Ar⁹ is as described in Formula 5 as described herein.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional representation illustrating an organic electroluminescent (EL) device according to an embodiment;

FIG. 2 is a schematic cross-sectional representation illustrating an organic EL device according to another embodiment;

FIG. 3 is a schematic cross-sectional representation illustrating an organic EL device according to another embodiment; and

FIG. 4 is an explanatory diagram qualitatively illustrating energy states and levels.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. In addition, unless otherwise specified, measurements of operation and physical properties are performed at room temperature (about 20° C. to about 25° C.) and at relative humidity of about 40% RH to about 50% RH.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

An aspect of the disclosure provides a compound including a structure including a polycyclic group structure represented by Formula 2 connected to at least one of ring Ar¹ or ring Ar² of a structure represented by Formula 1, and
at least one group structure, but not more than four group structures, each represented by Formula 3 connected to at least one ring Ar⁵ or ring Ar⁶ of the polycyclic group structure represented by Formula 2. For example, the compound may have a structure in which one group structure represented by Formula 3 is added to ring Ar⁵ and/or ring Ar⁶ in the polycyclic group structure represented by Formula 2.

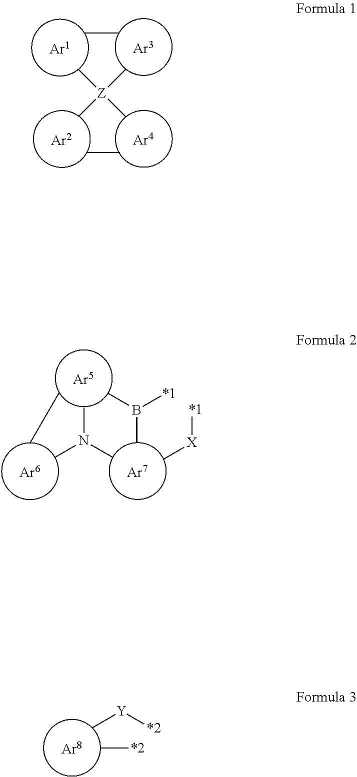

In Formulae 1, 2, and 3,
Ar¹ to Ar⁸ may each independently be a substituted or unsubstituted aromatic hydrocarbon ring having 6 to 30 ring-forming atoms or a substituted or unsubstituted heteroaromatic ring having 5 to 30 ring-forming atoms,
in Formula 1, Z may be C or Si,
in Formula 2, X may be —O—, —S—, —NR²¹—, or —CR²²R²³—, wherein R²¹, R²², and R²³ may each independently be hydrogen, deuterium, a substituted or unsubstituted alkyl group, a substituted or unsubstituted aryl group, or a substituted or unsubstituted heteroaryl group, wherein, if X is —NR²¹—, then R²¹ may be bonded to a ring-forming atom of Ar⁷,
in Formula 2, binding sites *1 may be bonded to adjacent ring-forming atoms of Ar¹, or binding sites *1 may be bonded to adjacent ring-forming atoms of Ar², in the structure represented by Formula 1, and
in Formula 3, Y may be —O—, —S—, or —NR³¹—, wherein R³¹ may be hydrogen, deuterium, a substituted or unsubstituted alkyl group, a substituted or unsubstituted aryl group, or a substituted or unsubstituted heteroaryl group, and
binding sites *2 may be bonded to adjacent ring-forming atoms of Ar⁵, or binding sites *2 may be bonded to adjacent ring-forming atoms of Ar⁶, in the polycyclic group structure represented by Formula 2.

In an embodiment, in Formula 1, Ar¹ to Ar⁴ may each independently be selected from:
a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, or a pyranthrene ring, each of which is unsubstituted; and
a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, or a pyranthrene ring, each of which is substituted with a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, a substituted or unsubstituted arylheteroarylamino group, or a combination thereof.

For example, in Formula 1, Ar¹ to Ar⁴ may each independently be selected from: a benzene ring; and a benzene ring substituted with a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, a substituted or unsubstituted arylheteroarylamino group, or a combination thereof. In this regard, the substituents of the substituted alkyl group, the substituted aryl group, the substituted heteroaryl group, the substituted alkoxy group, the substituted aryloxy group, the substituted heteroaryloxy group, the substituted diarylamino group, the substituted diheteroarylamino group, or the substituted arylheteroarylamino group may each independently be selected from a deuterium atom, a halogen atom, an unsubstituted alkyl group, an unsubstituted aryl group, an unsubstituted heteroaryl group, an unsubstituted alkoxy group, an unsubstituted aryloxy group, an unsubstituted heteroaryloxy group, an unsubstituted diarylamino group, an unsubstituted diheteroarylamino group, or an unsubstituted arylheteroarylamino group.

Hereinafter, a compound according to the disclosure is referred to at time as a “condensed cyclic compound”. In addition, an organic electroluminescent (EL) device is at times referred to as an “organic EL device.”

The condensed cyclic compound according may exhibit a relatively narrow maximum peak emission spectrum, may realize high color purity, and may also improve the luminescence efficiency and/or lifespan of an organic EL device.

Although the inventors of the disclosure may speculate on the mechanism for solving the technical issues in the art, in no way does any proposed mechanism or technical reason provided limit the scope of the disclosure, and certainly, no proposed mechanism or reason provided is to further limit the claims recited herein.

The condensed cyclic compound of the disclosure has an electron-donating nitrogen atom (N) and an electron-accepting boron atom (B), and the described compound structures allow for these atoms to be arranged in a conjugated system that is relatively rigid. As a result of this structural rigidity, changes in the molecular structure (bond length, bond angle, etc.) between the ground state (S₀) and the first excitation state (S₁), may be suppressed, which in turn may provide the relatively narrow emission spectra observed for the compounds. Accordingly, high-color purity luminescence, in particular, high-color purity blue luminescence with a narrow spectrum, may be realized. In addition, the electronic effect due to the structural arrangement may contribute to increasing the oscillator strength as well as contributing to an emission intensity with high efficiency.

In addition, the condensed cyclic compound of the disclosure includes a spiro structure represented by Formula 1 in the parent skeleton, and thus has an improved three-dimensional volume height of the molecule. Accordingly, Dexter energy transfer between the condensed cyclic compound and another compound may be suppressed, and thus, a blue EL device having a long lifespan may be realized.

In particular, an organic EL device that includes a condensed cyclic compound of the disclosure in an emission layer and a thermally activated delayed fluorescence (TADF) material as luminescent materials may have suppressed Dexter energy transfer from a luminescent material (in particular, a phosphorescent material). Accordingly, a blue EL device having high efficiency and a long lifespan may be realized.

A stated, the above structural/electronic mechanism is based in-part on speculation, and whether the mechanism is right or wrong does not affect the technical scope of the disclosure.

The structure represented by Formula 2 has two binding sites *1, and each binding site *1 represents a bonding point to respective adjacent ring-forming atoms of Ar¹, or each binding site *1 represents a bonding point to respective adjacent ring-forming atoms of Ar², in the structure represented by Formula 1. The condensed cyclic compound of the disclosure includes one structure represented by Formula 2.

The structure represented by Formula 3 has two binding sites *2, and each binding site *2 represents a bonding point to respective adjacent ring-forming atoms of Ar⁵, or each binding site *2 represents a bonding point to respective adjacent ring-forming atoms of Ar⁶, in the structure represented by Formula 2. The condensed cyclic compound of the disclosure has at least one, but not more than four group structures, e.g., not more than three or two group structures, each represented by Formula 3.

As used herein, the term “number of ring-forming atoms” refers to the number of atoms constituting the ring itself of a compound (for example, a monocyclic compound, a condensed cyclic compound, a cross-linked compound, a carbocyclic compound, and a heterocyclic compound) having a structure (for example, a monocyclic ring, a condensed ring, and a ring assembly) in which atoms are bonded in a ring-like manner. The number of ring-forming atoms excludes the number of atoms that do not constitute the ring (for example, a hydrogen atom that terminates a bond of atoms constituting the ring), and the number of atoms included in a substituent when the ring is substituted with the substituent. Unless otherwise specified, the same definition of the number of ring-forming atoms applies to descriptions provided below.

For example, a benzene ring has 6 ring-forming atoms (or represents a six-membered ring), a naphthalene ring has 10 ring-forming atoms, a pyridine ring has 6 ring-forming atoms, and a furan ring has 5 ring-forming atoms (or represents a five-membered ring).

For example, when a benzene ring is substituted with an alkyl group as a substituent, the number of carbon atoms of the alkyl group is not included in the number of ring-forming atoms of the benzene ring. Accordingly, the number of ring-forming atoms of a benzene ring substituted with an alkyl group remains 6. For example, when a naphthalene ring is substituted with an alkyl group as a substituent, the number of atoms of the alkyl group is not included in the number of ring-forming atoms of the naphthalene ring. Accordingly, the number of ring-forming atoms of a naphthalene ring substituted with an alkyl group remains 10.

For example, the number of hydrogen atoms bonded to a pyridine ring or the number of atoms constituting a substituent is not included in the number of ring-forming atoms of the pyridine ring. Accordingly, the number of ring-forming atoms of a pyridine ring to which a hydrogen atom or a substituent remains 6.

In Formulae 1, 2, and 3, aromatic hydrocarbon rings constituting Ar¹ to Ar⁸ may each be a monocyclic ring or a condensed ring. The number of ring-forming atoms of the aromatic hydrocarbon ring may be 6 to 30, for example, 6 to 10, or for example, 6. Examples of the aromatic hydrocarbon ring having 6 to 30 ring-forming atoms may include, but are not particularly limited to, a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, a pyranthrene ring, and the like. For example, the aromatic hydrocarbon ring may be a benzene ring.

In Formulae 1, 2, and 3, heteroaromatic rings constituting Ar¹ to Ar⁸ may each be a monocyclic ring or a condensed ring. The number of ring-forming atoms of the heteroaromatic ring may be 5 to 30, for example, 5 to 20, or for example, 5 to 18.

The heteroaromatic ring has one or more heteroatoms (for example, nitrogen atoms (N), oxygen atoms (O), phosphorus atoms (P), sulfur atoms (S), and silicon atoms (Si)) as ring-forming atoms, and the remaining ring-forming atom are carbon atoms (C). Examples of the heteroaromatic ring having 5 to 30 ring-forming atoms may include, but are not particularly limited to, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, an benzimidazole ring, a pyrazole ring, an indazole ring, an oxazole ring, an isoxazole ring, a benzoxazole ring, a benzisoxazole ring, a thiazole ring, an isothiazole ring, a benzthiazole ring, a benzisothiazole ring, an imidazolinone ring, a benzimidazolinone ring, an imidazopyridine ring, an imidazopyrimidine ring, an imidazophenanthridine ring, a benzimidazophenanthridine ring, an azadibenzofuran ring, an azacarbazole ring, an azadibenzothiophene ring, a diazadibenzofuran ring, a diazacarbazole ring, a diazadibenzothiophene ring, a xanthone ring, a thioxanthone ring, and the like.

At least one hydrogen atom in the aromatic hydrocarbon ring and the heteroaromatic ring may be substituted. In this case, the type of a substituent may be, but is not particularly limited to, a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, or a substituted or unsubstituted arylheteroarylamino group. When two or more hydrogen atoms are substituted, the types of substituents may be identical to or different from each other.

Examples of the halogen atom as a substituent may include a fluorine atom (F), a chlorine atom (Cl), a bromine atom (Br), an iodine atom (I), and the like.

The alkyl group as a substituent may be linear, branched, or cyclic. The number of carbon atoms of the alkyl group may be, but is not particularly limited to, 1 to 30, or for example, 1 to 20. In addition, the number of carbon atoms of the alkyl group may be 1 to 10, or for example, 1 to 6. Examples of the alkyl group may include, but are not particularly limited to, a methyl group, an ethyl group, an n-propyl group, an isopropyl group, an n-butyl group, a sec-butyl group, a tert-butyl group, an isobutyl group, a 2-ethylbutyl group, a 3,3-dimethylbutyl group, an n-pentyl group, an isopentyl group, a neopentyl group, a tert-pentyl group (a t-pentyl group), a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-tert-butylcyclohexyl group (a 4-t-butylcyclohexyl group), an n-heptyl group, a 1-methylheptyl group, a 2,2-dimethylheptyl group, a 2-ethylheptyl group, a 2-butylheptyl group, an n-octyl group, a tert-octyl group (a t-octyl group), a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like.

The aryl group as a substituent may be, but is not particularly limited to, a monovalent group derived from a hydrocarbon ring including one or more aromatic rings. In addition, the hydrocarbon ring constituting the aryl group may be a condensed ring. In addition, when the aryl group includes two or more aromatic rings, the two or more aromatic rings may be bonded to each other via a single bond (in the form of a ring assembly of aromatic hydrocarbon rings). The number of ring-forming atoms of the aryl group may be, but is not particularly limited to, 6 to 30. In addition, the number of ring-forming atoms of the aryl group may be 6 to 20, or for example, 6 to 18. Examples of the aryl group may include, but are not particularly limited to, a phenyl group, a naphthyl group, a phenanthryl group, a biphenylenyl group, a triphenylene group, an anthryl group, a pyrenyl group, a fluorenyl group, an azulenyl group, an acenaphthenyl group, a fluoranthenyl group, a naphthacenyl group, a perylenyl group, a pentacenyl group, a quaterphenyl group, a chrysenyl group, and the like.

The heteroaryl group as a substituent may be, but is not particularly limited to, a monovalent group derived from a ring including one or more heteroaromatic rings and optionally one or more aromatic rings, the heteroaromatic rings having one or more heteroatoms (for example, nitrogen atoms (N), oxygen atoms (O), phosphorus atoms (P), sulfur atoms (S), and silicon atoms (Si)) as ring-forming atoms, wherein the remaining ring-forming atoms are carbon atoms (C). When the heteroaryl group includes two or more heteroatoms, the heteroatoms may be identical to or different from each other. In addition, a ring constituting the heteroaryl group may be a condensed ring. In addition, when the heteroaryl group includes two or more heteroaromatic rings, the two or more heteroaromatic rings may be bonded to each other via a single bond.

As such, the heteroaryl group may be a monocyclic heteroaryl group or a polycyclic heteroaryl group. The number of ring-forming atoms of the heteroaryl group may be, but is not particularly limited to, 5 to 30. In addition, the number of ring-forming atoms of the heteroaryl group may be 5 to 20, or for example, 5 to 18. Examples of the heteroaryl group may include, but are not particularly limited to, a thienyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, a triazolyl group, an acridinyl group, a pyridazinyl group, a pyridinyl group, a quinolinyl group, a quinazolinyl group, a quinoxalinyl group, a phenoxazinyl group, a phthalazinyl group, a pyridopyrimidinyl group, a pyridopyrazinyl group, a pyrazinopyrazinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzimidazolyl group, a benzothiazolyl group, a benzocarbazolyl group, a benzothiophenyl group, a dibenzothienyl group, a thienothienyl group, a benzofuranyl group, a phenanthrolinyl group, a thiazolyl group, an isoxazolyl group, an oxadiazolyl group, a thiadiazolyl group, a phenothiazinyl group, a dibenzosilolyl group, a dibenzofuranyl group, and a combination thereof.

The alkoxy group as a substituent may be linear, branched, or cyclic. The alkyl group constituting the alkoxy group is not particularly limited, and examples thereof may be the same as those described in the above description of the alkyl group. The number of carbon atoms of the alkoxy group may be, but is not particularly limited to, 1 or more. In addition, the number of carbon atoms of the alkoxy group may be 20 or less, for example, 10 or less, or for example, 4 or less. Examples of the alkoxy group may include, but are not particularly limited to, a methoxy group, an ethoxy group, an n-propyloxy group, an isopropyloxy group, an n-butyloxy group, a sec-butyloxy group, a tert-butyloxy group, an iso-butyloxy group, a 2-ethylbutyloxy group, a 3,3-dimethylbutyloxy group, an n-pentyloxy group, an isopentyloxy group, a neopentyloxy group, a tert-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a cyclohexyloxy group, a 4-methylcyclohexyloxy group, a 4-tert-butylcyclohexyloxy group, an n-heptyloxy group, a 1-methylheptyloxy group, a 2,2-dimethylheptyloxy group, a 2-ethylheptyloxy group, a 2-butylheptyloxy group, an n-octyloxy group, a tert-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, an adamantyloxy group, and the like.

The aryloxy group as a substituent is not particularly limited. The number of carbon atoms of the aryloxy group may be, but is not particularly limited to, 6 to 30. The number of carbon atoms of the aryloxy group may be 6 to 12, or for example, 6. Examples of the aryloxy group may include, but are not particularly limited to, a phenyloxy group, a biphenyloxy group, a terphenyloxy group, a naphthyloxy group, a fluorenyloxy group, an anthracenyloxy group, a quaterphenyloxy group, a quinquephenyloxy group, a triphenyleneoxy group, a pyrenyloxy group, a benzofluorenyloxy group, a chrysenyloxy group, and a combination thereof.

The heteroaryloxy group as a substituent is not particularly limited. The heteroaryl group constituting the heteroaryloxy group is not particularly limited, and examples thereof may be the same as those described in the above description of the heteroaryl group. The number of carbon atoms of the heteroaryloxy group may be, but is not particularly limited to, 5 to 30. In addition, the number of ring-forming atoms of the heteroaryloxy group may be 5 to 14, or for example, 5 to 13. The number of heteroatoms as ring-forming atoms of the heteroaryloxy group may be, but is not particularly limited to, 1 to 3. In addition, the number of heteroatoms as ring-forming atoms of the heteroaryloxy group may be 1 or 2, or for example, 1. Examples of the heteroaryloxy group may include, but are not particularly limited to, a thienyloxy group, a furanyloxy group, a pyrrolyloxy group, an imidazolyloxy group, a thiazolyloxy group, an oxazolyloxy group, an oxadiazolyloxy group, a triazolyloxy group, a pyridyloxy group, a bipyridyloxy group, a pyrimidyloxy group, a triazinyloxy group, a triazolyloxy group, an acridinyloxy group, a pyridazinyloxy group, a pyridinyloxy group, a quinolinyloxy group, a quinazolinyloxy group, a quinoxalinyloxy group, a phenoxazinyloxy group, a phthalazinyloxy group, a pyridopyrimidinyloxy group, a pyridopyrazinyloxy group, a pyrazinopyrazinyloxy group, an isoquinolinyloxy group, an indolyloxy group, a carbazolyloxy group, a benzoxazolyloxy group, a benzimidazolyloxy group, a benzothiazolyloxy group, a benzocarbazolyloxy group, a benzothiophenyloxy group, a dibenzothienyloxy group, a thienothienyloxy group, a benzofuranyloxy group, a phenanthrolinyloxy group, a thiazolyloxy group, an isoxazolyloxy group, an oxadiazolyloxy group, a thiadiazolyloxy group, a phenothiazinyloxy group, a dibenzosilolyloxy group, a dibenzofuranyloxy group, a xanthonyloxy group, and a combination thereof.

The diarylamino group, the diheteroarylamino group, and the arylheteroarylamino group as substituents are not particularly limited. Examples of the aryl group and the heteroaryl group constituting the diarylamino group, the diheteroarylamino group, and the arylheteroarylamino group may be the same as those described in the above descriptions of the aryl group and the heteroaryl group, respectively. Examples of the diarylamino group may include, but are not particularly limited to, a diphenylamino group, a bis(4-tert-butylphenyl)amino group, a phenyl(naphthyl)amino group, a di(biphenyl)amino group, a di(p-terphenyl)amino group, and the like. Examples of the arylheteroarylamino group may include, but are not particularly limited to, a phenyl(2-pyridyl)amino group and the like. Examples of the diheteroarylamino group may include, but are not particularly limited to, a di(2-pyridyl)amino group and the like.

When the above (primary) substituent is further substituted, the type of the additional (or secondary) substituent is not particularly limited. When the above substituent is further substituted with a secondary substituent, the secondary substituent may be, for example, a deuterium atom, a halogen atom, an unsubstituted alkyl group, an unsubstituted aryl group, an unsubstituted heteroaryl group, an unsubstituted alkoxy group, an unsubstituted aryloxy group, an unsubstituted heteroaryloxy group, an unsubstituted diarylamino group, an unsubstituted diheteroarylamino group, or an unsubstituted arylheteroarylamino group. In the case where the above substituent is further substituted with a substituent, when two or more substituents are further substituted to the above substituent, the types of the two or more substituents may be identical to different from each other. In addition, the substituent further substituted to the above substituent may not substitute a group of the same type. For example, a substituent substituting an alkyl group as a substituent may not include an alkyl group. The unsubstituted alkyl group, the unsubstituted aryl group, the unsubstituted heteroaryl group, the unsubstituted alkoxy group, the unsubstituted aryloxy group, the unsubstituted heteroaryloxy group, the unsubstituted diarylamino group, the unsubstituted diheteroarylamino group, and the unsubstituted arylheteroarylamino group as the secondary substituent may be as defined above for the alkyl group, the aryl group, the heteroaryl group, the alkoxy group, the aryloxy group, the heteroaryloxy group, the diarylamino group, the diheteroarylamino group, and the arylheteroarylamino group as the primary substituent, respectively.

For example, a substituent (primary or secondary) may be independently deuterium atom, halogen atom, a C₁-C₂₀ alkyl group (e.g., C₁-C₂₀ (e.g., C₁-C₁₀) linear alkyl group, or C₃-C₂₀ (e.g., C₃-C₁₀) branched alkyl group), a phenyl group, a tert-butyl group, a pyridyl group, a pyrrolyl group, a 4-tert-butylphenyl group, a 3-tert-butylphenyl group, a 2-tert-butylphenyl group, a 2-phenylphenyl group, a 2,6-di-isopropylphenyl group, a 3,5-di-tert-butylphenyl group, a 2,6-di-tert-butylphenyl group, a 2,6-diphenylphenyl group, a 2,4-diphenylphenyl group, a 2,5-diphenylphenyl group, a 4-(4-tert-butylphenyl)phenyl group, a 2,6-bis(4-tert-butylphenyl)phenyl group, a 2,6-bis(3-tert-butylphenyl)phenyl group, a 4-(3,5-di-tert-butylphenyl)phenyl group, a 2,6-bis(3,5-di-tert-butylphenyl)phenyl group, a 4-tert-butyl-2,6-bis(4-tert-butylphenyl)phenyl group, a 2,4,5-triphenylphenyl group, a 2,4,6-triphenylphenyl group, a 2,4,6-tri-tert-butylphenyl group, a 4-(4-tert-butylphenyl)-2,5-diphenylphenyl group, a 4-(3,5-di-tert-butylphenyl)-2,5-diphenylphenyl group, a 5-tert-butyl-2,4-diphenylphenyl group, a 4-phenyl-2,6-di-tert-butylphenyl group, a 4-phenyl-2,5-di-tert-butylphenyl group, a carbazolyl group, a 1,8-dimethylcarbazolyl group, a 1,8-dimethyl-3,6-di-tert-butylcarbazolyl group, a 3,6-di-tert-butylcarbazolyl group, a diphenylamino group, a bis(2,6-dimethylphenyl)amino group, a bis(2,6-dimethyl-4-tert-butylphenyl)amino group, or a bis(4-tert-butylphenyl)amino group.

In Formula 2, X may be —O—, —S—, —NR²¹—, or —CR²²R²³—, wherein R²¹, R²², and R²³ may each independently be hydrogen, deuterium, a substituted or unsubstituted alkyl group, a substituted or unsubstituted aryl group, or a substituted or unsubstituted heteroaryl group, wherein if X is —NR²¹—, then R²¹ may be bonded to a ring-forming atom of Ar⁷. Examples of the alkyl group, the aryl group, and the heteroaryl group may be the same as the examples of the alkyl group, the aryl group, and the heteroaryl group described in the above description of the substituent. For example, in Formula 2, X may be —O— or —S—.

In Formula 1, Z may be C or Si, for example, C.

In Formula 3, Y may be —O—, —S—, or —NR³¹—, wherein R³¹ may be hydrogen, deuterium, a substituted or unsubstituted alkyl group, a substituted or unsubstituted aryl group, or a substituted or unsubstituted heteroaryl group. Examples of the alkyl group, the aryl group, and the heteroaryl group may be the same as the examples of the alkyl group, the aryl group, and the heteroaryl group described in the above description of the substituent.

In an embodiment, the structure of Formula 1 may be represented by one of Formulae 1-1 to 1-6:

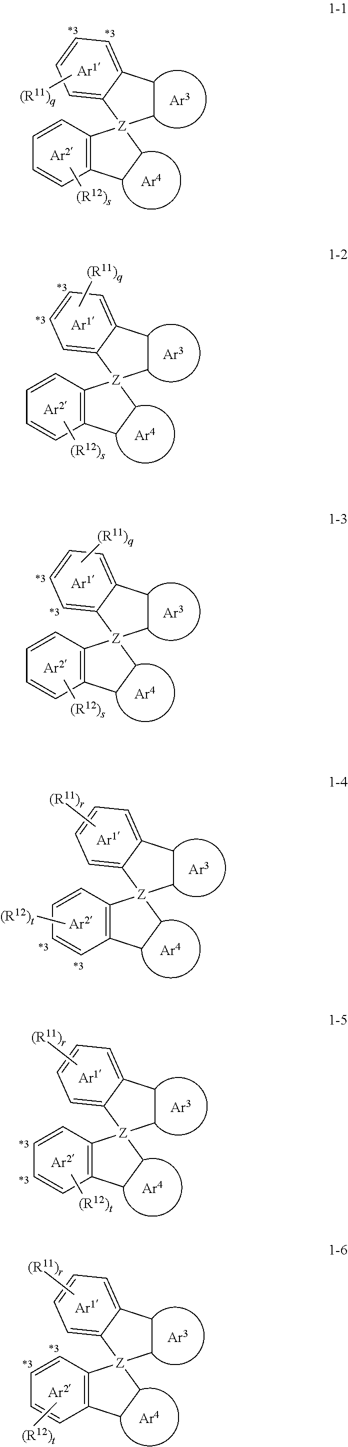

wherein, in Formulae 1-1 to 1-6,
R¹¹ and R¹² may each independently be deuterium, a substituted or unsubstituted alkyl group, a substituted or unsubstituted aryl group, or a substituted or unsubstituted heteroaryl group,
q and t may each independently be 0, 1, or 2, wherein, when q is 2, two R¹¹(s) may be identical to or different from each other, and when t is 2, two R¹²(s) may be identical to or different from each other,
s and r may each independently be 0, 1, 2, 3, or 4, wherein, when s is 2 or more, two or more R¹²(s) may be identical to or different from each other, and when r is 2 or more, two or more R¹¹(s) may be identical to or different from each other,
binding sites *3 designate the adjacent ring atoms that connect with the binding sites *1 in the polycyclic group structure represented by Formula 2, and
Ar³, Ar⁴, and Z may each be the same as described in Formula 1.

The condensed cyclic compound of the disclosure may be a compound having a structure in which a polycyclic group structure represented by Formula 4 that is connected to a ring Ar¹ or ring Ar² in the structure represented by Formula 1, and, at least one group structure, but not more than four group structures, each represented by Formula 5 is connected to ring Ar⁵′ or ring Ar⁶ in the polycyclic group structure represented by Formula 4.

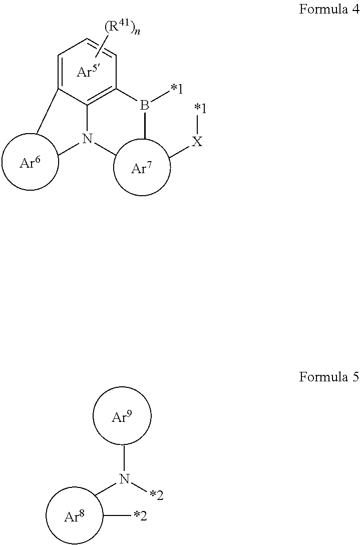

In Formula 4,
R⁴¹ may be deuterium, a substituted or unsubstituted alkyl group, a substituted or unsubstituted aryl group, or a substituted or unsubstituted heteroaryl group,
n may be 0, 1, 2, or 3, wherein, when n is 2 or more, two or more R⁴¹(s) may be identical to or different from each other, and
Ar⁶, Ar⁷, X, and a binding site *1 may each be the same as described in Formula 2.

In Formula 5,
Ar⁹ may be a substituted or unsubstituted aromatic hydrocarbon ring having 6 to 30 ring-forming atoms or a substituted or unsubstituted heteroaromatic ring having 5 to 30 ring-forming atoms,
binding sites *2 may be bonded to adjacent ring-forming atoms of ring Ar^{5′} or ring Ar⁶ in the group structure represented by Formula 5, and
Ar⁸ may be the sane as described in connection with Formula 3.

Regarding R⁴¹ in Formula 4, examples include an alkyl group, an aryl group, and a heteroaryl group, and may be the same as the examples of the alkyl group, the aryl group, and the heteroaryl group described in the above description of the substituent. In addition, the substituent of the substituted alkyl group, the substituted aryl group, and the substituted heteroaryl group may be as described above in connection with the substituents of the aromatic hydrocarbon ring and the heteroaromatic ring of Ar¹ to Ar⁸.

Regarding Ar⁹ in Formula 5, examples include an aromatic hydrocarbon ring and a heteroaromatic ring, and may be the same as the examples of the aromatic hydrocarbon ring and the heteroaromatic ring in Formulae 1, 2, or 3. In addition, the substituent of the substituted aromatic hydrocarbon ring and the substituted heteroaromatic ring may be as described above in connection with the substituents of the aromatic hydrocarbon ring and the heteroaromatic ring of Ar¹ to Ar⁸.

The condensed cyclic compound of the disclosure may be a compound having a structure in which a structure is represented by Formula 6 is connected to adjacent ring-forming atoms of Ar¹, or adjacent ring-forming atoms of Ar², in the structure represented by Formula 1.

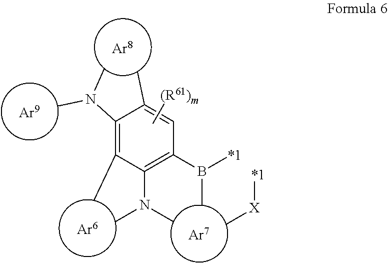

In Formula 6,
R⁶¹ may be deuterium, a substituted or unsubstituted alkyl group, a substituted or unsubstituted aryl group, or a substituted or unsubstituted heteroaryl group,
m may be 0 or 1,
Ar⁶, Ar⁷, X, and a binding site *1 may each be the same as described in Formula 2,
Ar⁸ may be the same as described in Formula 3, and
Ar⁹ may be the same as described in Formula 5.

Regarding R⁶¹ in Formula 6, examples include an alkyl group, an aryl group, and a heteroaryl group, and may be the same as the examples of the alkyl group, the aryl group, and the heteroaryl group described in the above description of the substituent. In addition, the substituent of the substituted alkyl group, the substituted aryl group, and the substituted heteroaryl group may be as described above in connection with the substituents of the aromatic hydrocarbon ring and the heteroaromatic ring of Ar¹ to Ar⁸.

The condensed cyclic compound of the disclosure may be a compound having a structure in which a structure is represented by Formula 7 is connected to adjacent ring-forming atoms of Ar¹ or adjacent ring-forming atoms of Ar² in the structure represented by Formula 1.

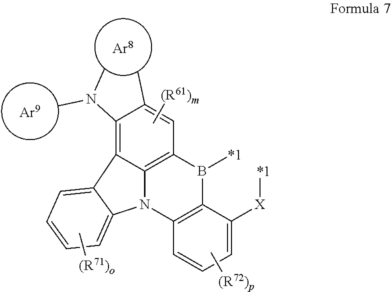

In Formula 7,
R⁷¹ may be deuterium, a substituted or unsubstituted alkyl group, a substituted or unsubstituted aryl group, or a substituted or unsubstituted heteroaryl group,
o may be 0, 1, 2, 3, or 4, wherein, when o is 2 or more, two or more R⁷¹(s) may be identical to or different from each other,
X and a binding site *1 may each be the same as described in Formula 2,
Ar⁸ may be the same as described in Formula 3,
Ar⁹ may be the same as described in Formula 5, and
R⁶¹ and m may each be the same as described in Formula 6.

Regarding R⁷¹ in Formula 7, examples include an alkyl group, an aryl group, and a heteroaryl group, and may be the same as the examples of the alkyl group, the aryl group, and the heteroaryl group described in the above description of the substituent. In addition, the substituent of the substituted alkyl group, the substituted aryl group, and the substituted heteroaryl group may be as described above in connection with the substituents of the aromatic hydrocarbon ring and the heteroaromatic ring of Ar¹ to Ar⁸.

In Formula 7,
R⁷² may be deuterium, a substituted or unsubstituted alkyl group, a substituted or unsubstituted aryl group, or a substituted or unsubstituted heteroaryl group,
p may be 0, 1, 2, or 3, wherein, when p is 2 or more, two or more R⁷²(s) may be identical to or different from each other,

Introducing an electron-donating group or an electron-accepting group as R⁷² in Formula 7 may affect the shape of a spectrum. Regarding R⁷² in Formula 7, examples of an alkyl group, an aryl group, and a heteroaryl group may be the same as the examples of the alkyl group, the aryl group, and the heteroaryl group described in the above description of the substituent.

Provided below are some examples of condensed cyclic compounds according to embodiments. For example, the condensed cyclic compound of the disclosure may be a Compound 1 to 109. However, the disclosure is not limited to the following example compounds.

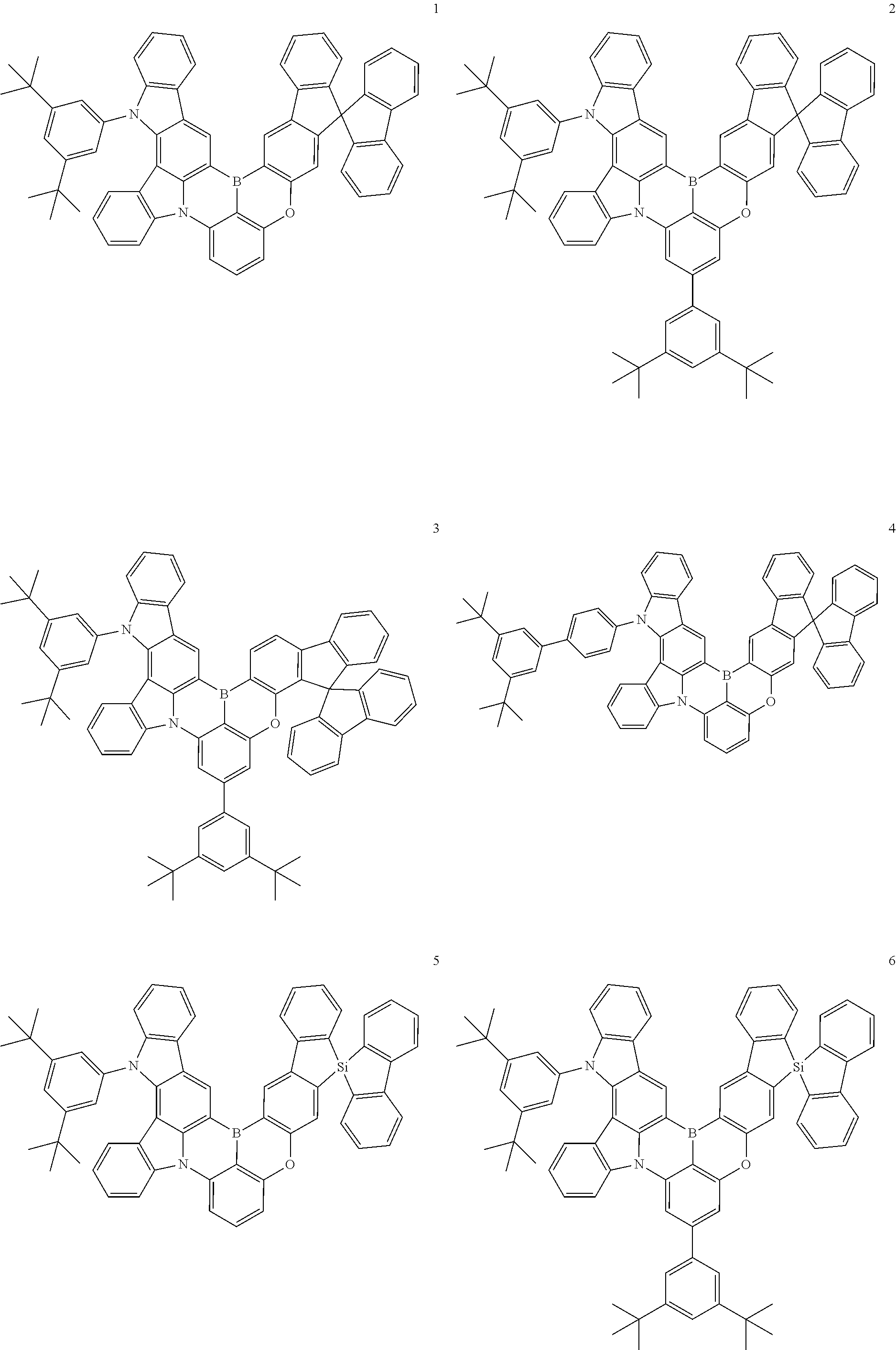

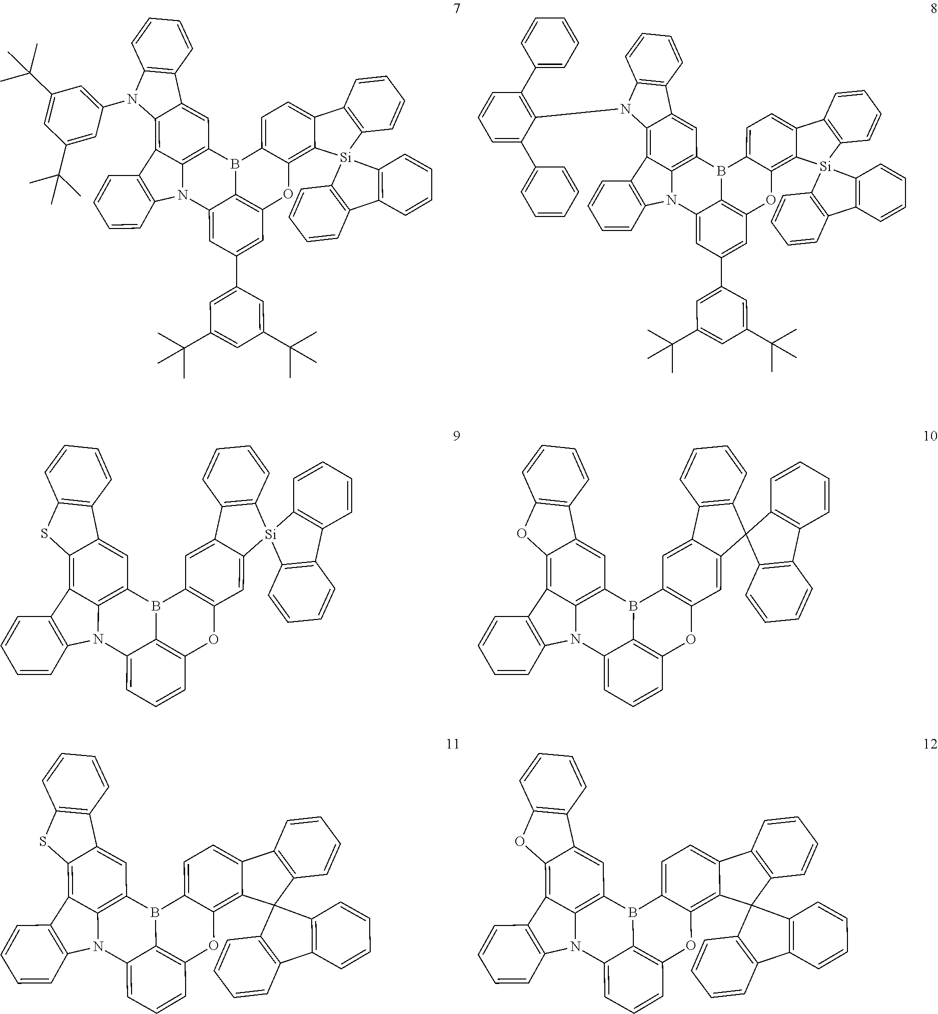

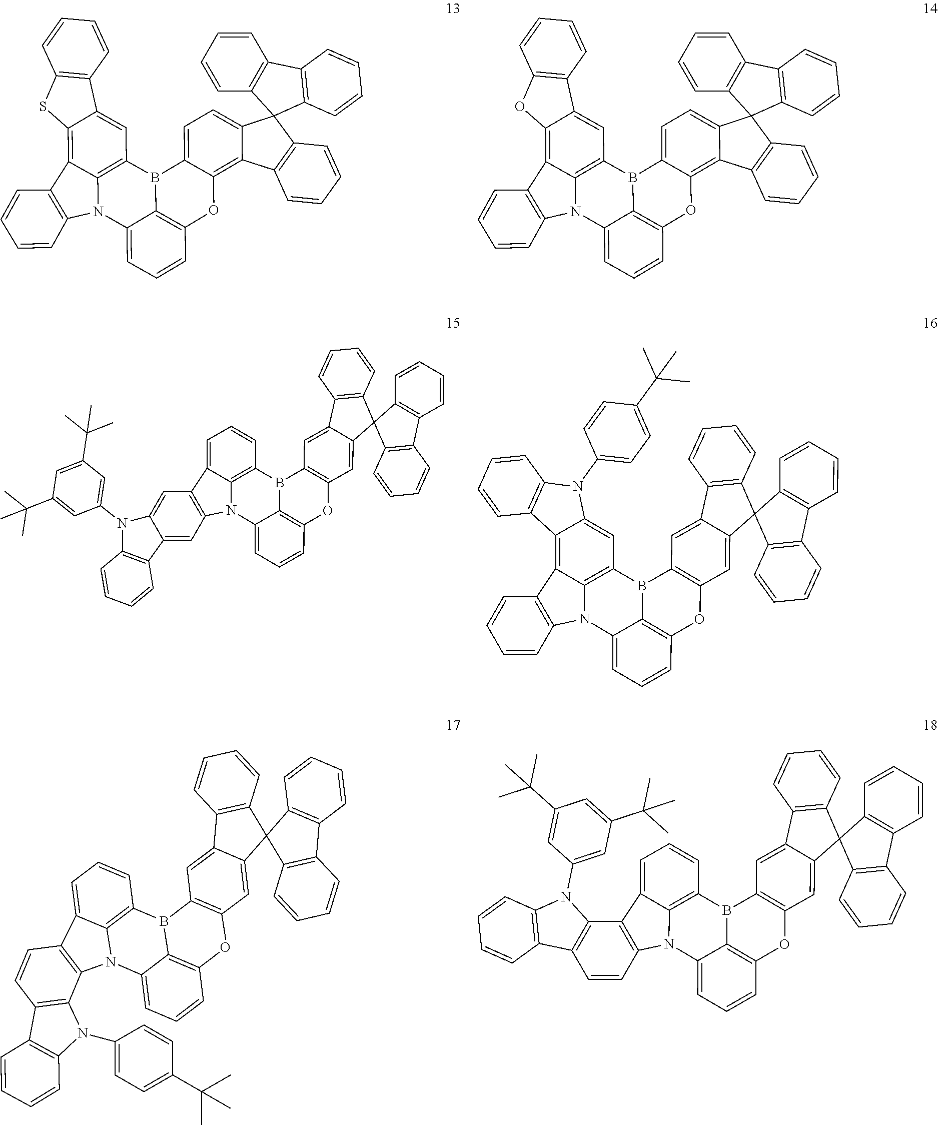

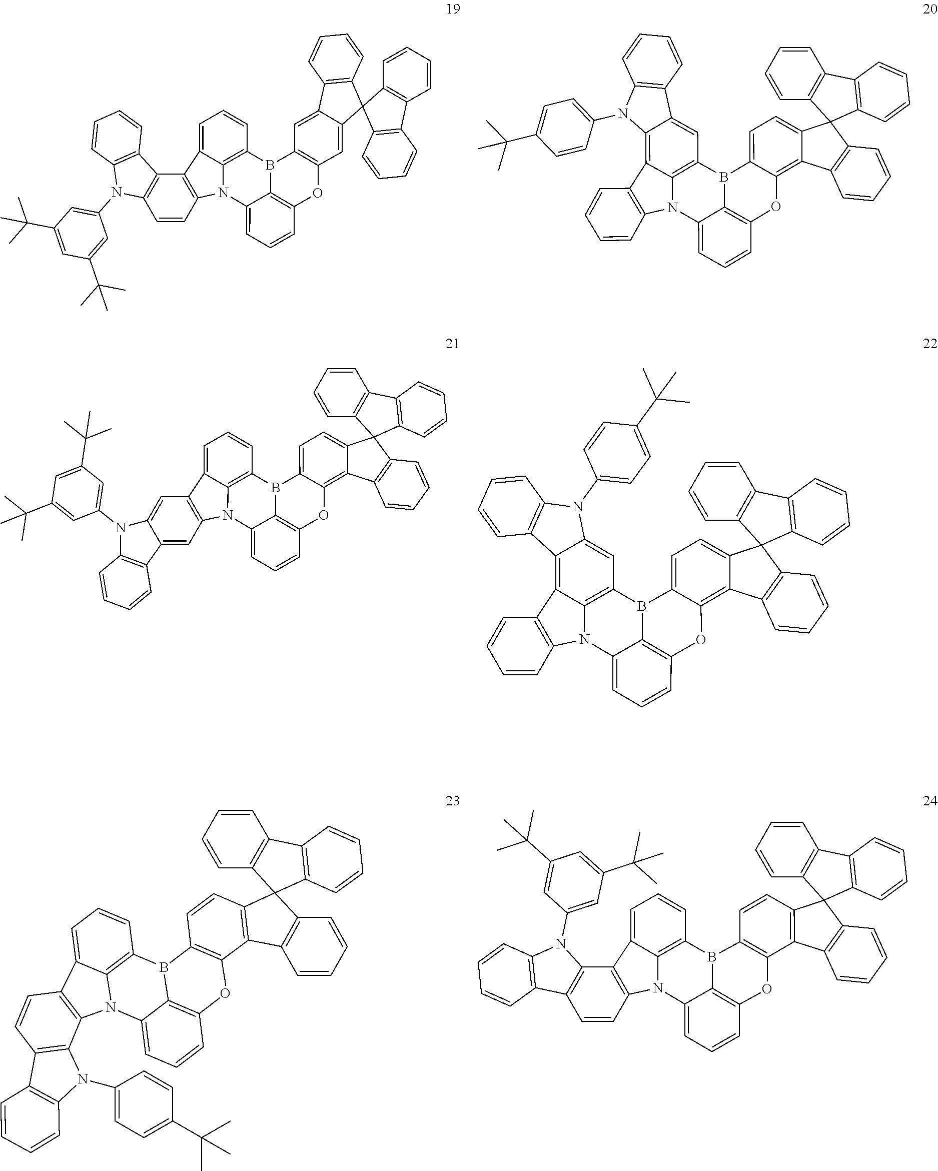

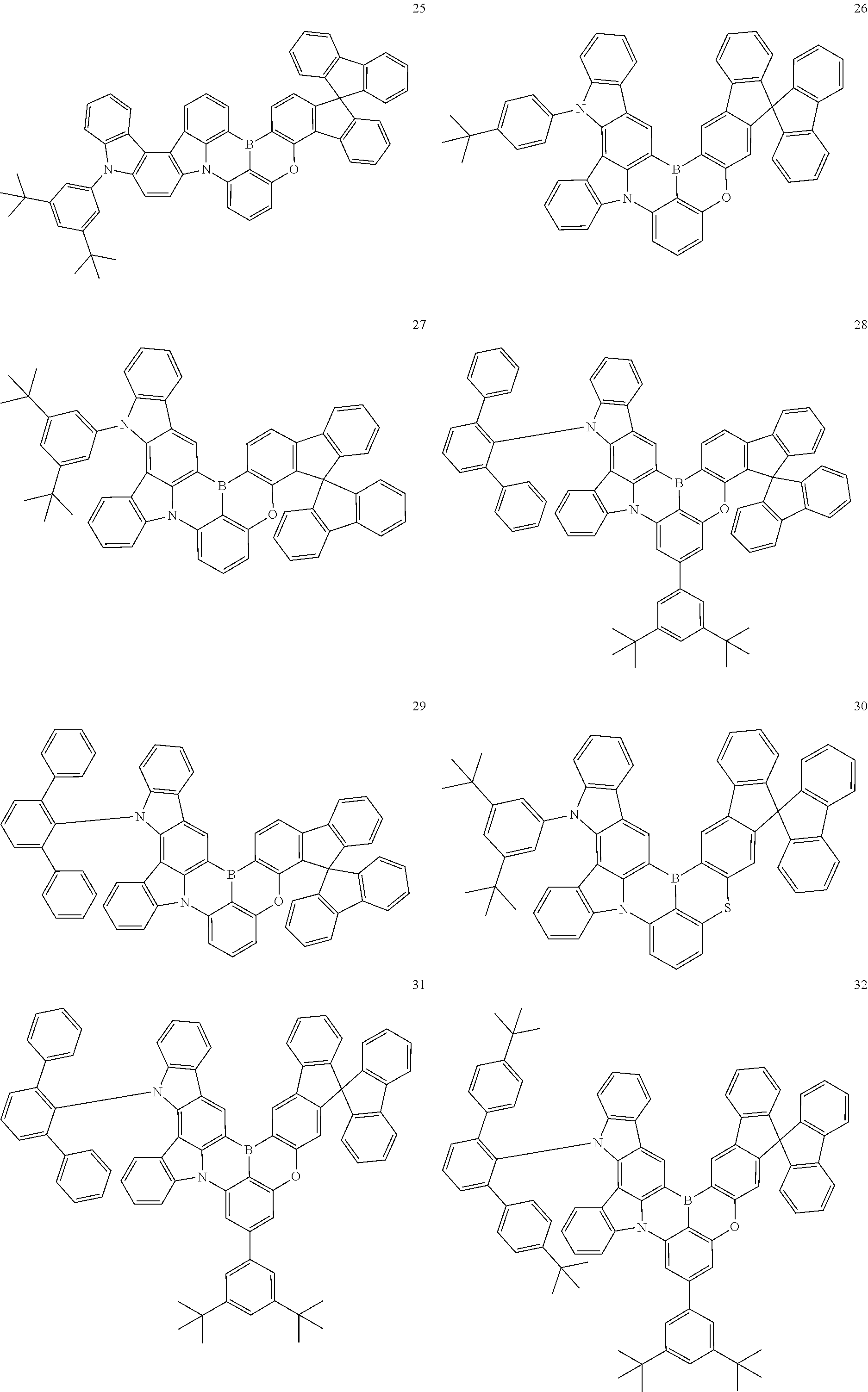

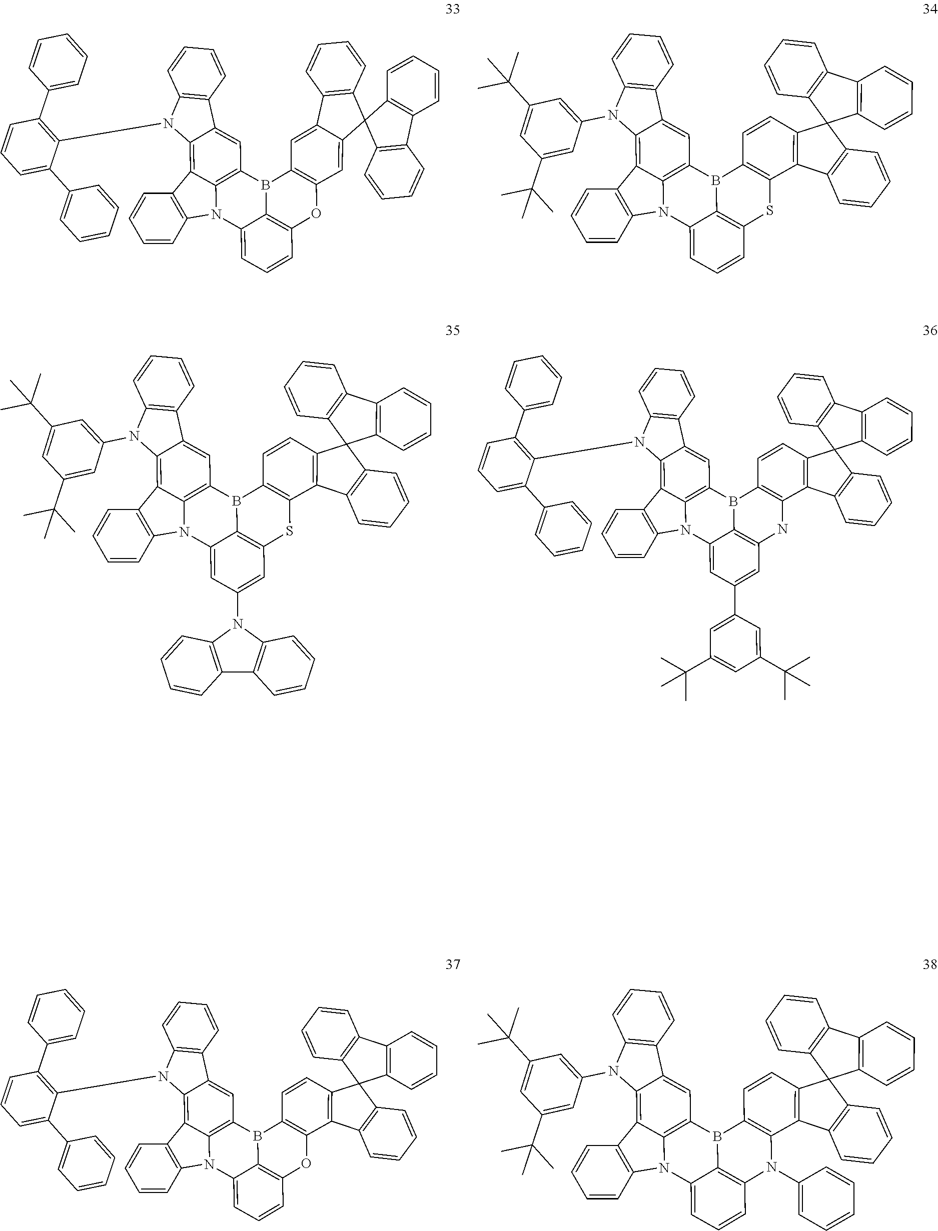

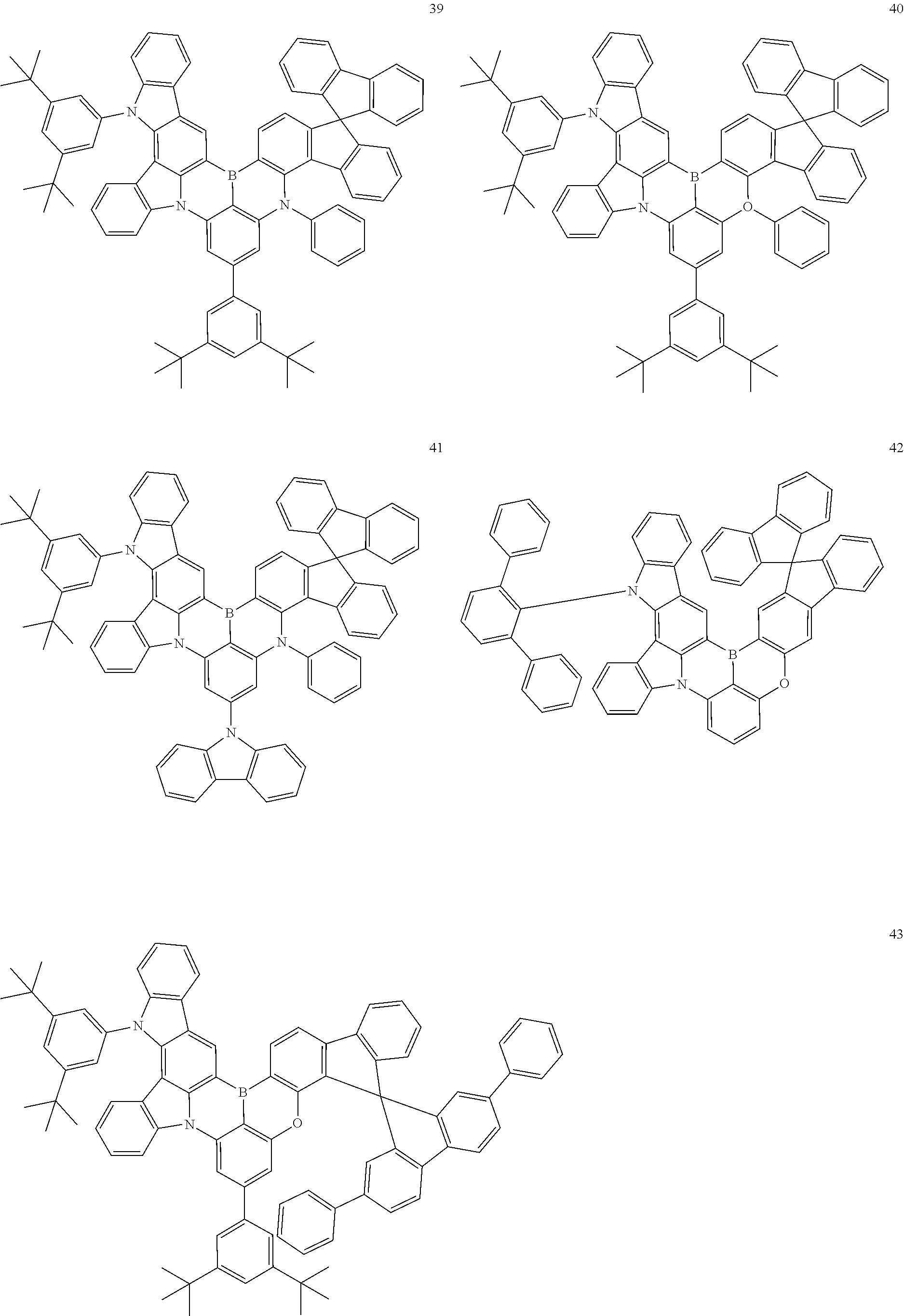

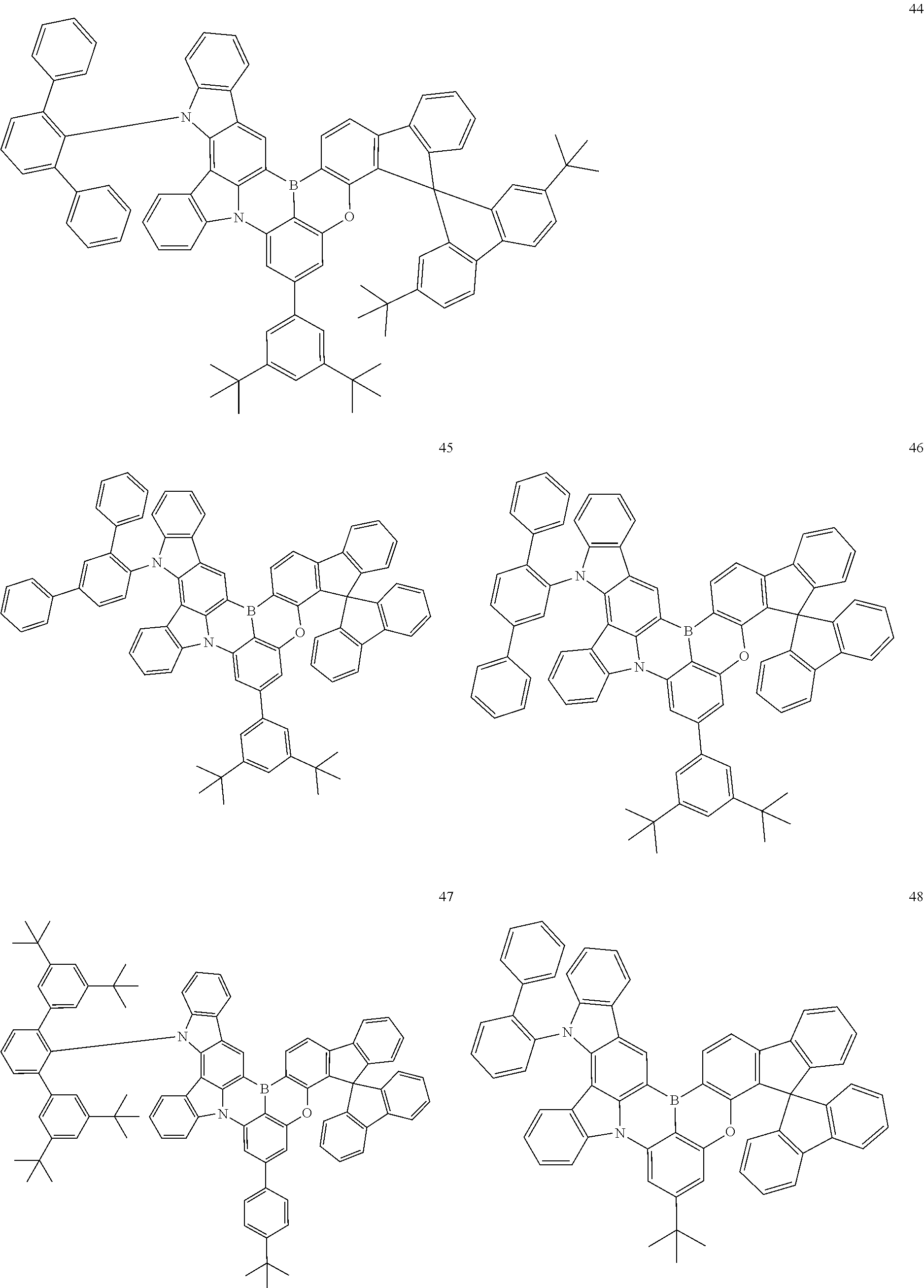

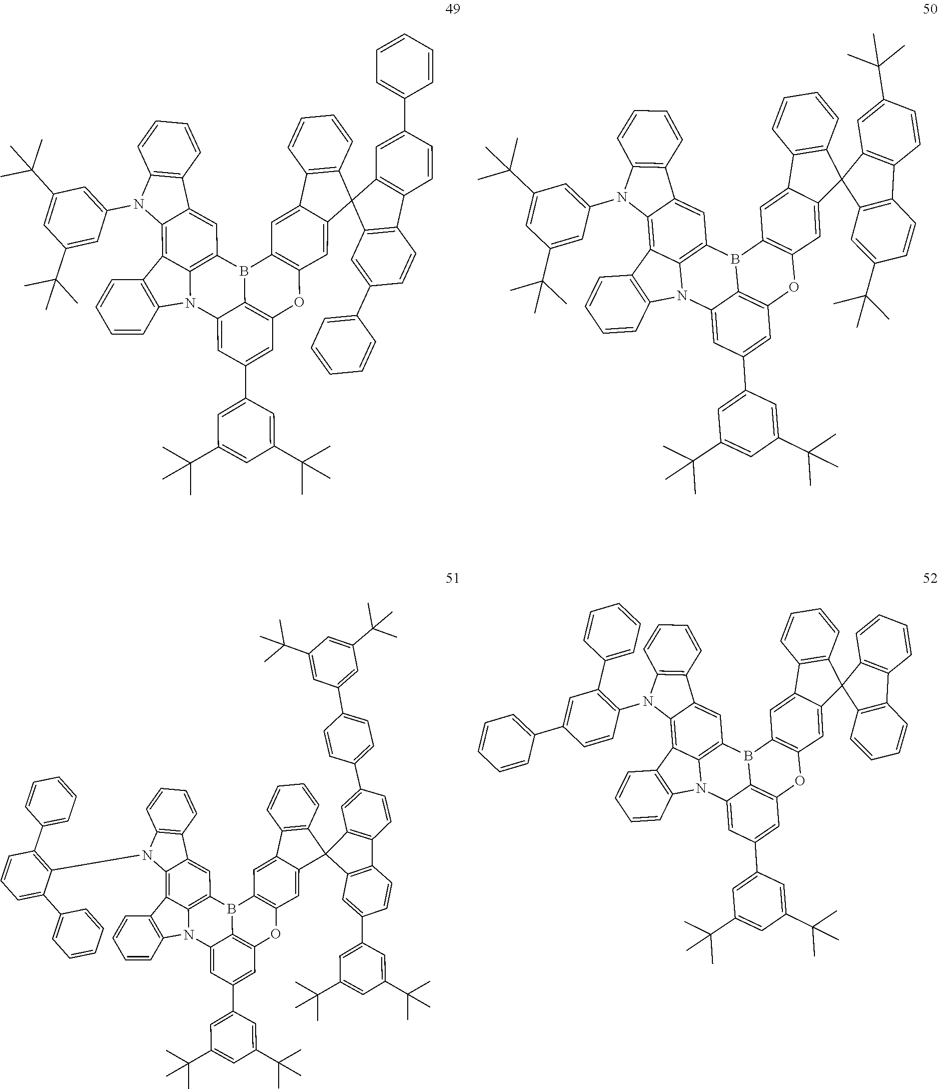

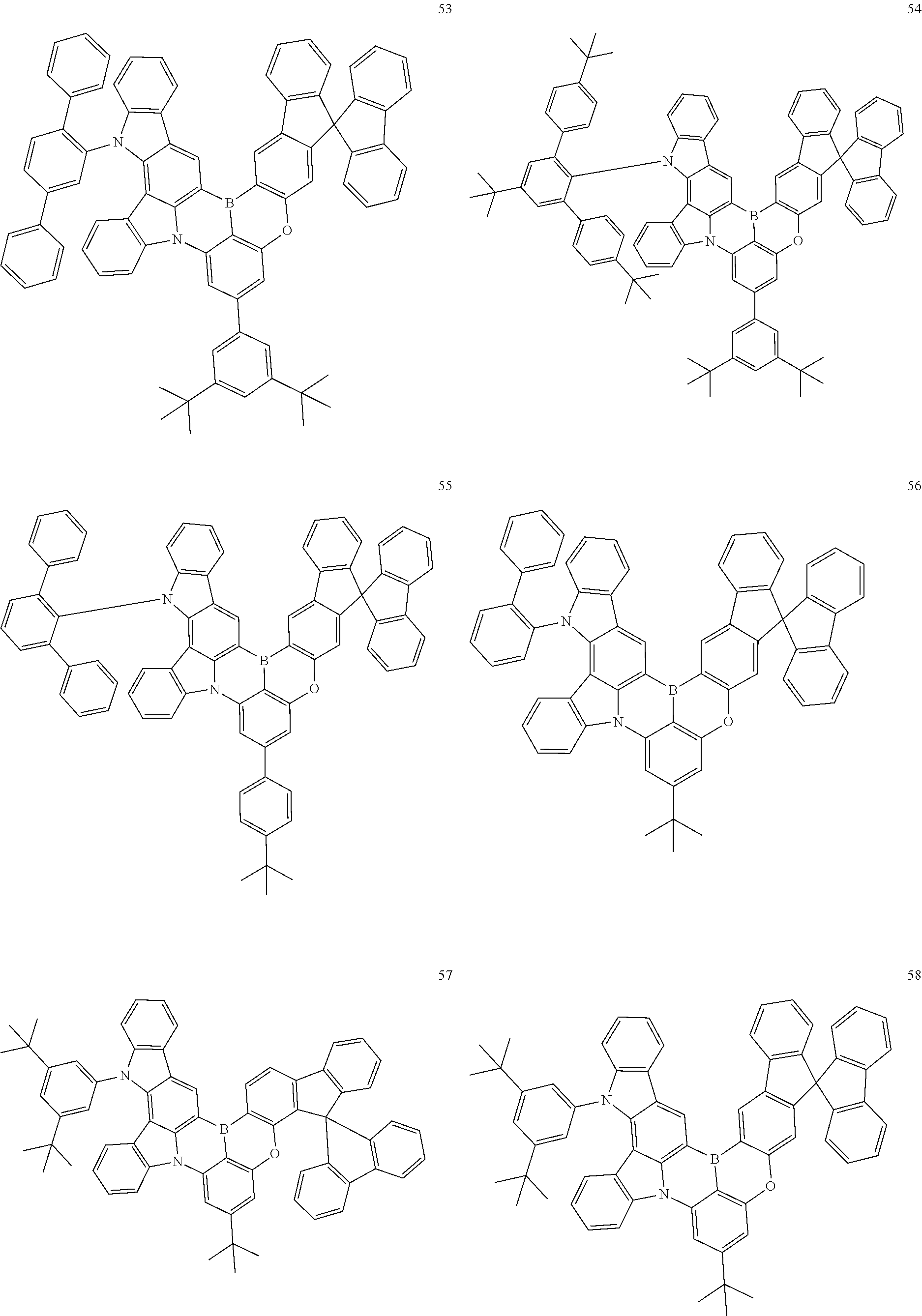

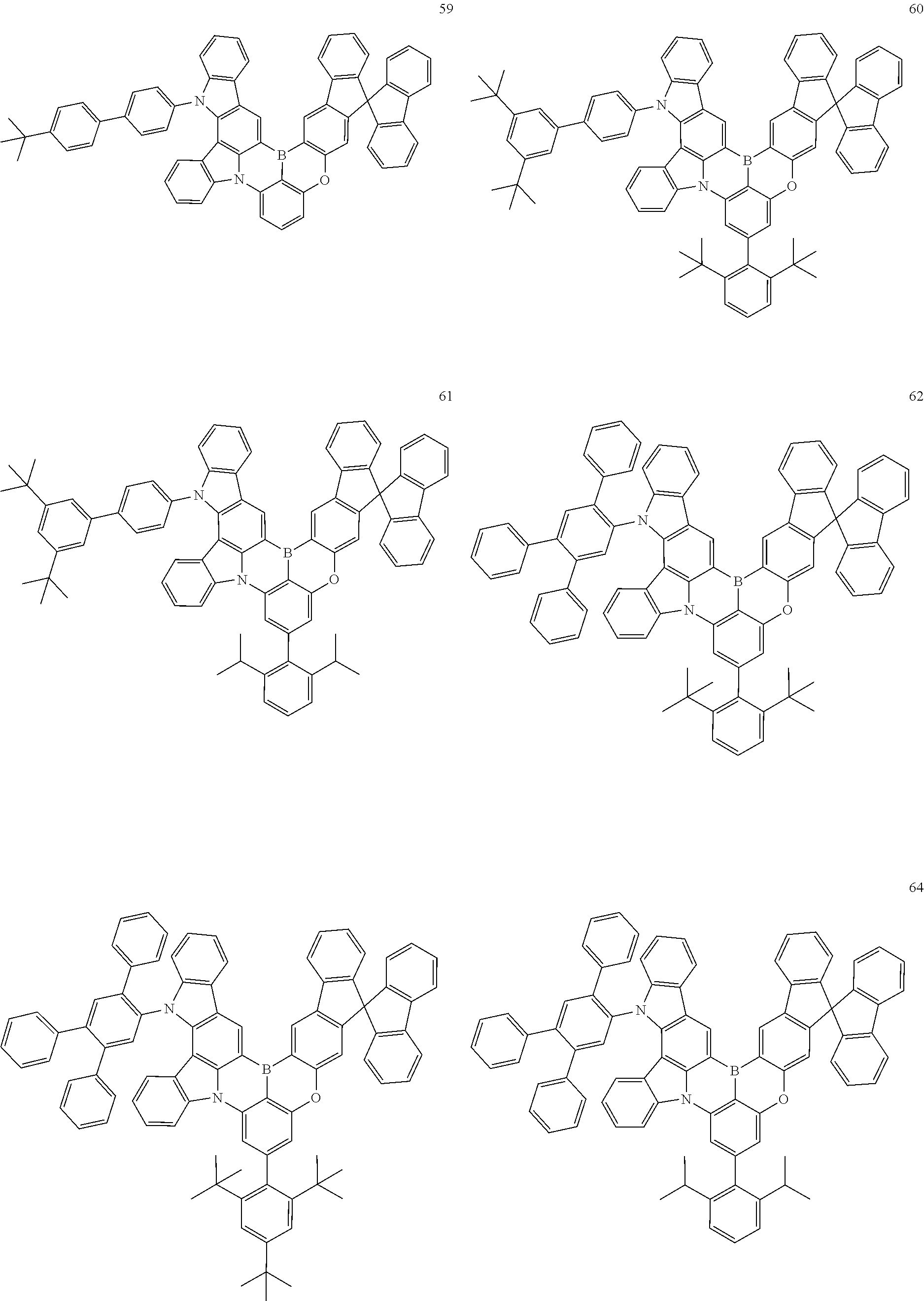

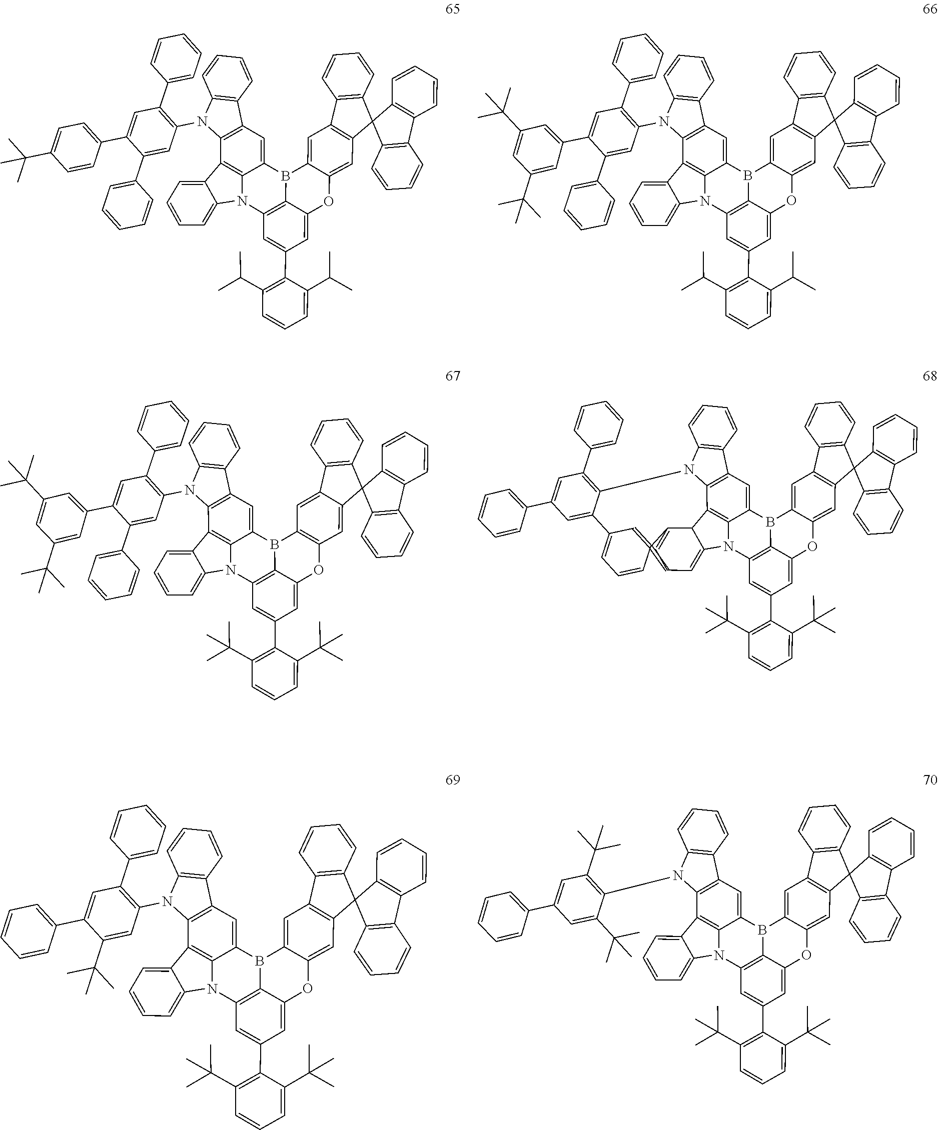

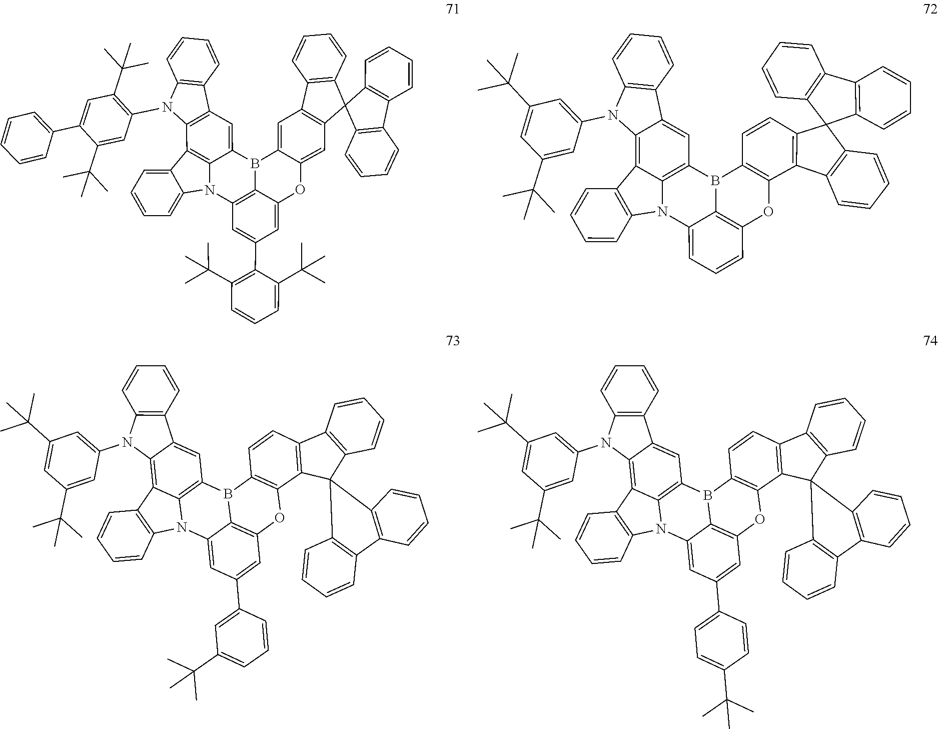

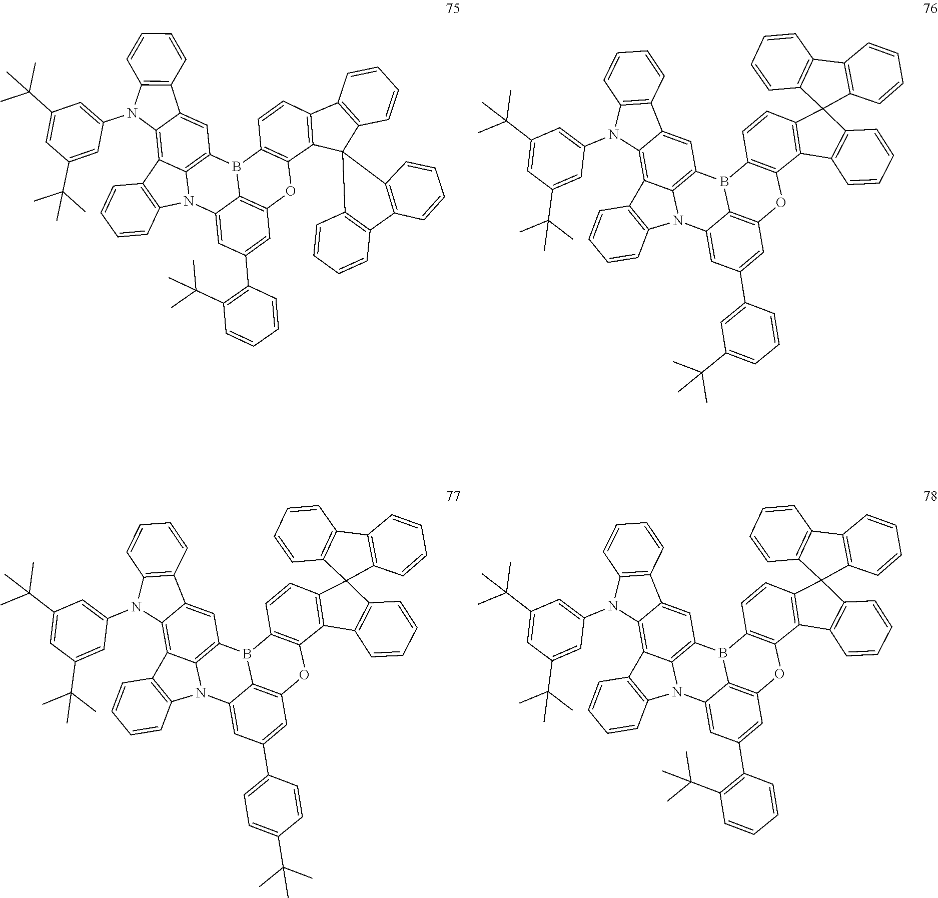

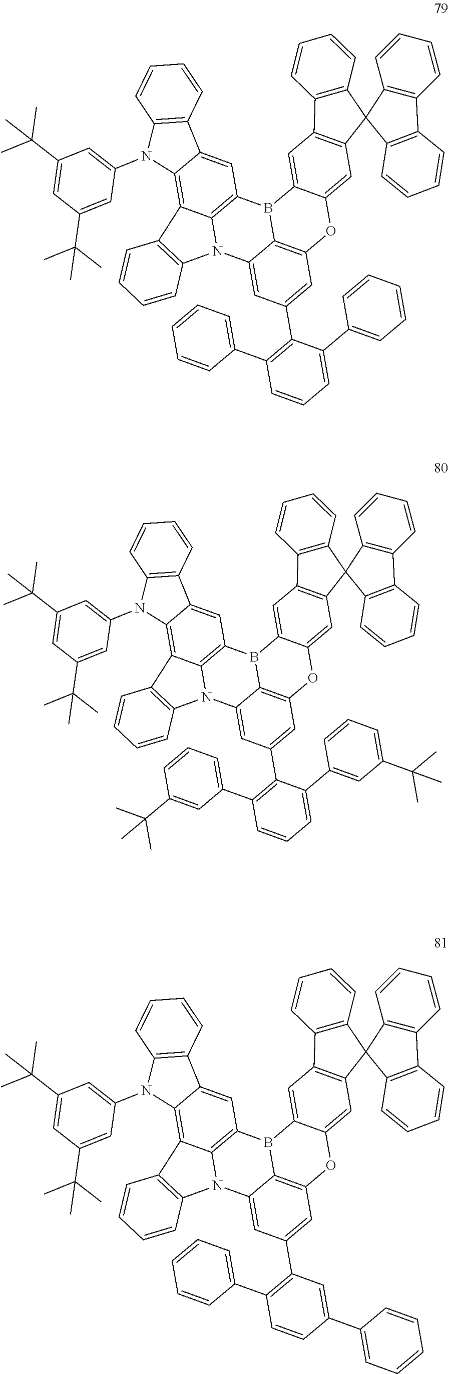

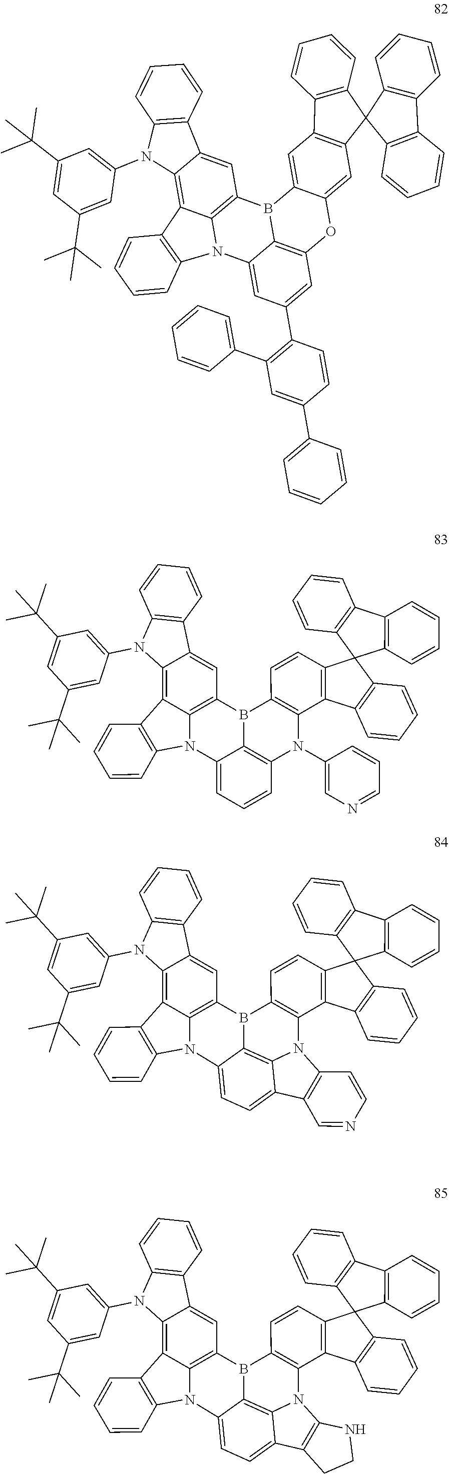

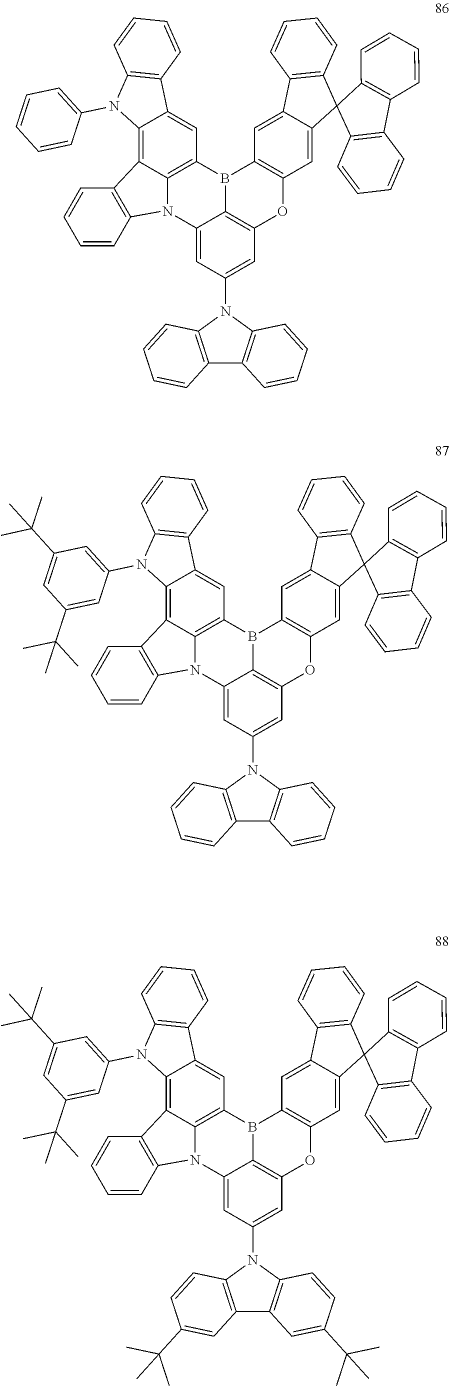 [SMILES: c1ccc(-n2c3ccccc3c3cc4c5c(c6ccccc6n5-c5cc(-n6c7ccccc7c7ccccc76)cc6c5B4c4cc5c(cc4O6)C4(c6ccccc6-c6ccccc64)c4ccccc4-5)c32)cc1 ; CC(C)(C)c1cc(-n2c3ccccc3c3cc4c5c(c6ccccc6n5-c5cc(-n6c7ccccc7c7ccccc76)cc6c5B4c4cc5c(cc4O6)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4O6)C4(c6ccccc6-c6ccccc64)c4ccccc4-5)c32)cc(C(C)(C)C)c1]

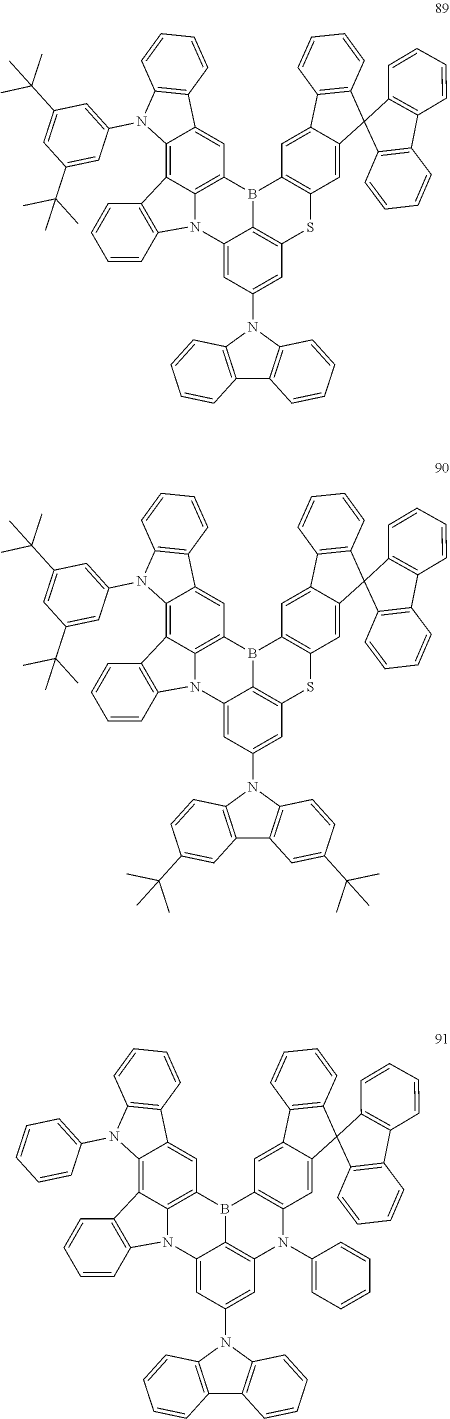 [SMILES: CC(C)(C)c1cc(-n2c3ccccc3c3cc4c5c(c6ccccc6n5-c5cc(-n6c7ccccc7c7ccccc76)cc6c5B4c4cc5c(cc4S6)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4S6)C4(c6ccccc6-c6ccccc64)c4ccccc4-5)c32)cc(C(C)(C)C)c1 ; c1ccc(N2c3cc4c(cc3B3c5c2cc(-n2c6ccccc6c6ccccc62)cc5-n2c5ccccc5c5c2c3cc2c3ccccc3n(-c3ccccc3)c25)-c2ccccc2C42c3ccccc3-c3ccccc32)cc1]

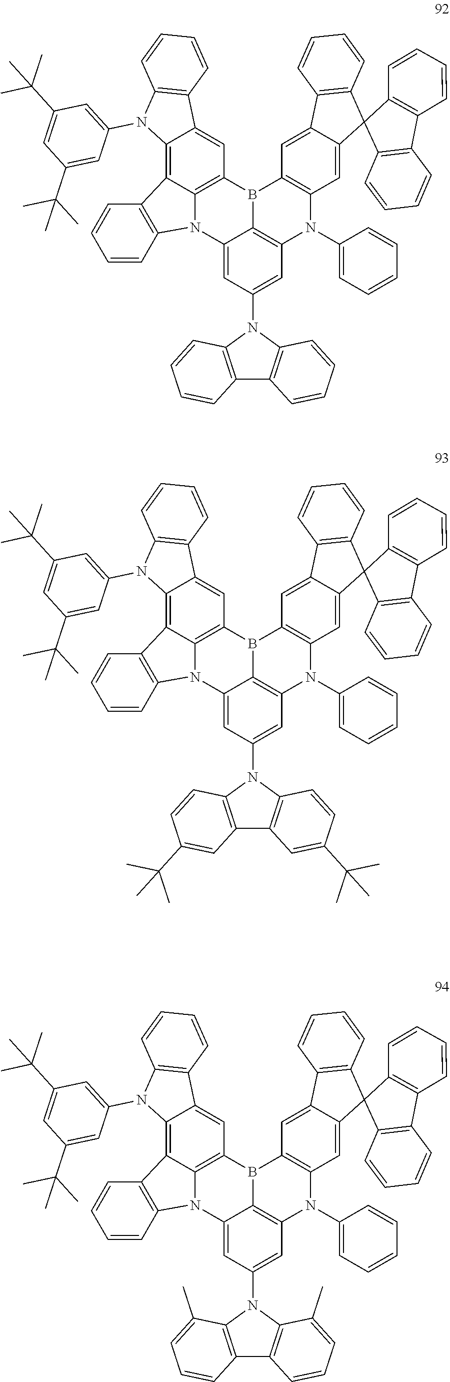 [SMILES: CC(C)(C)c1cc(-n2c3ccccc3c3cc4c5c(c6ccccc6n5-c5cc(-n6c7ccccc7c7ccccc76)cc6c5B4c4cc5c(cc4N6c4ccccc4)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4N6c4ccccc4)C4(c6ccccc6-c6ccccc64)c4ccccc4-5)c32)cc(C(C)(C)C)c1 ; Cc1cccc2c3cccc(C)c3n(-c3cc4c5c(c3)-n3c6ccccc6c6c3c(cc3c7ccccc7n(-c7cc(C(C)(C)C)cc(C(C)(C)C)c7)c36)B5c3cc5c(cc3N4c3ccccc3)C3(c4ccccc4-c4ccccc43)c3ccccc3-5)c12]

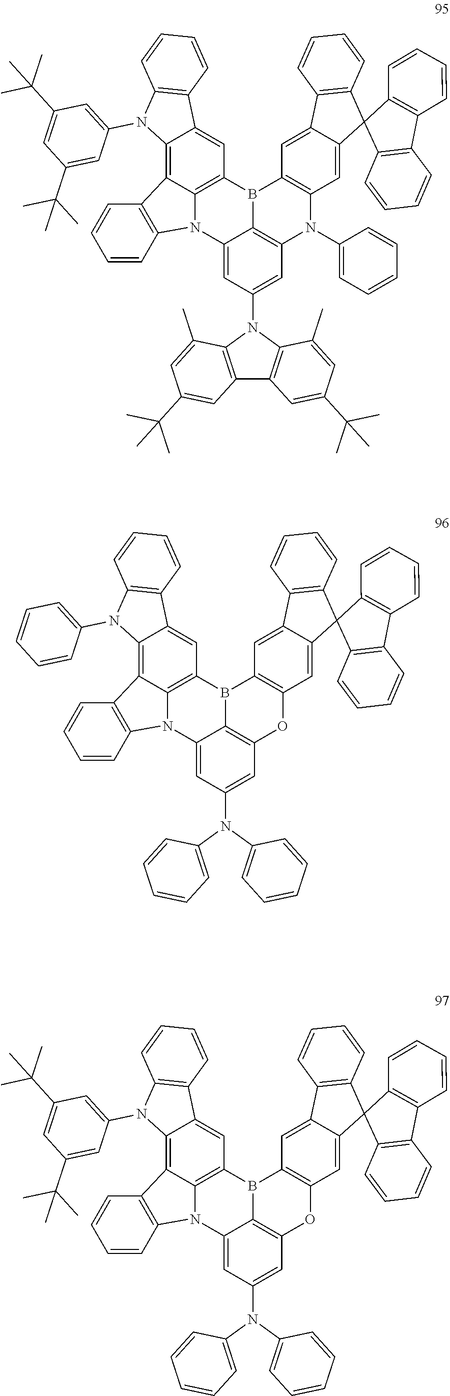 [SMILES: Cc1cc(C(C)(C)C)cc2c3cc(C(C)(C)C)cc(C)c3n(-c3cc4c5c(c3)-n3c6ccccc6c6c3c(cc3c7ccccc7n(-c7cc(C(C)(C)C)cc(C(C)(C)C)c7)c36)B5c3cc5c(cc3N4c3ccccc3)C3(c4ccccc4-c4ccccc43)c3ccccc3-5)c12 ; c1ccc(N(c2ccccc2)c2cc3c4c(c2)-n2c5ccccc5c5c2c(cc2c6ccccc6n(-c6ccccc6)c25)B4c2cc4c(cc2O3)C2(c3ccccc3-c3ccccc32)c2ccccc2-4)cc1 ; CC(C)(C)c1cc(-n2c3ccccc3c3cc4c5c(c6ccccc6n5-c5cc(N(c6ccccc6)c6ccccc6)cc6c5B4c4cc5c(cc4O6)C4(c6ccccc6-c6ccccc64)c4ccccc4-5)c32)cc(C(C)(C)C)c1]

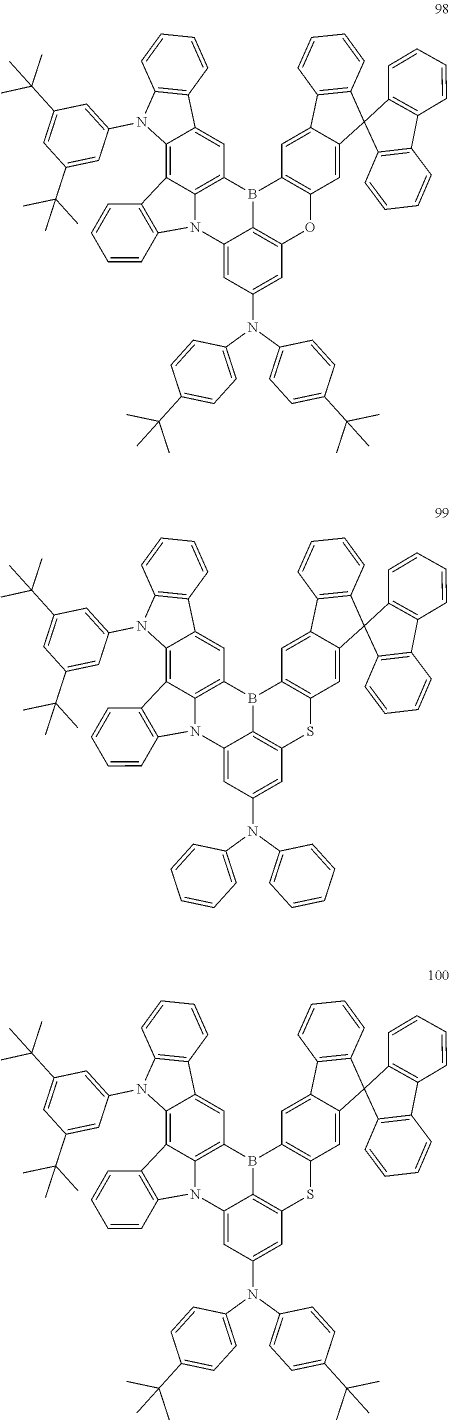 [SMILES: CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2O3)C2(c3ccccc3-c3ccccc32)c2ccccc2-4)cc1 ; CC(C)(C)c1cc(-n2c3ccccc3c3cc4c5c(c6ccccc6n5-c5cc(N(c6ccccc6)c6ccccc6)cc6c5B4c4cc5c(cc4S6)C4(c6ccccc6-c6ccccc64)c4ccccc4-5)c32)cc(C(C)(C)C)c1 ; CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2S3)C2(c3ccccc3-c3ccccc32)c2ccccc2-4)cc1]

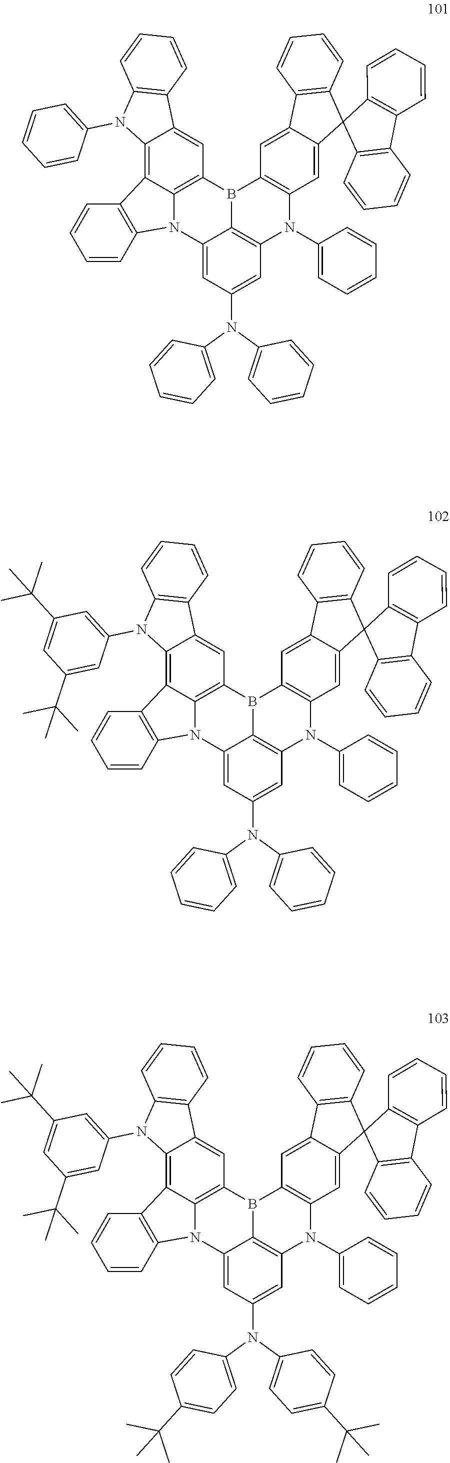 [SMILES: c1ccc(N(c2ccccc2)c2cc3c4c(c2)-n2c5ccccc5c5c2c(cc2c6ccccc6n(-c6ccccc6)c25)B4c2cc4c(cc2N3c2ccccc2)C2(c3ccccc3-c3ccccc32)c2ccccc2-4)cc1 ; CC(C)(C)c1cc(-n2c3ccccc3c3cc4c5c(c6ccccc6n5-c5cc(N(c6ccccc6)c6ccccc6)cc6c5B4c4cc5c(cc4N6c4ccccc4)C4(c6ccccc6-c6ccccc64)c4ccccc4-5)c32)cc(C(C)(C)C)c1 ; CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2N3c2ccccc2)C2(c3ccccc3-c3ccccc32)c2ccccc2-4)cc1]

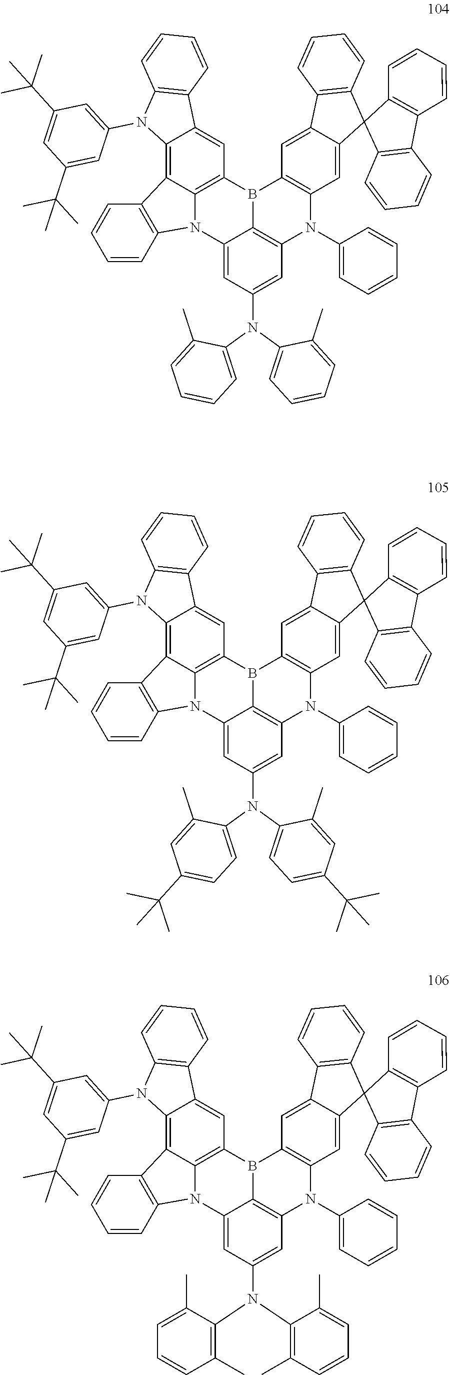 [SMILES: Cc1ccccc1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1ccccc1C ; Cc1cc(C(C)(C)C)ccc1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1ccc(C(C)(C)C)cc1C ; Cc1cccc(C)c1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1c(C)cccc1C]

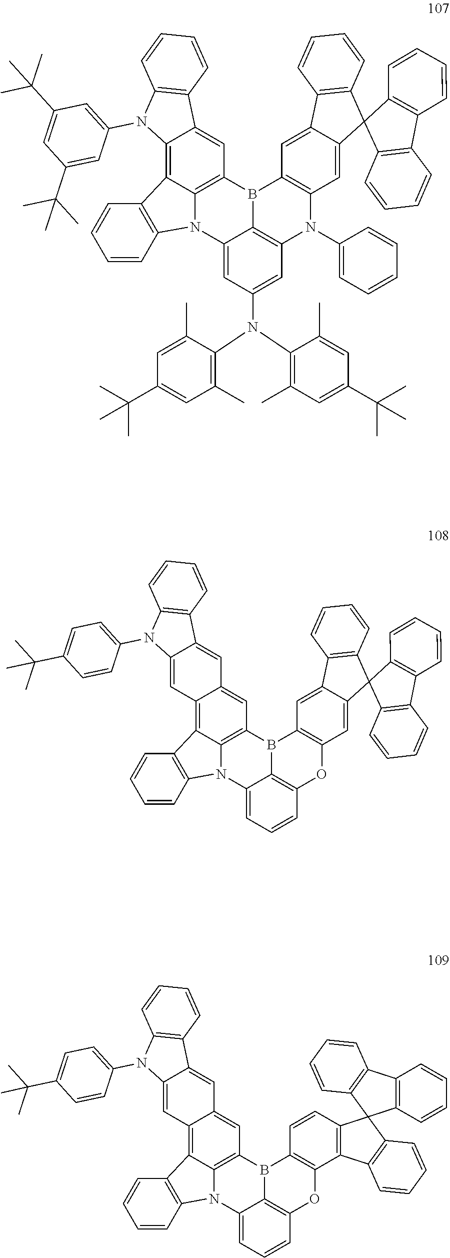 [SMILES: Cc1cc(C(C)(C)C)cc(C)c1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1c(C)cc(C(C)(C)C)cc1C ; CC(C)(C)c1ccc(-n2c3ccccc3c3cc4cc5c6c(c4cc32)c2ccccc2n6-c2cccc3c2B5c2cc4c(cc2O3)C2(c3ccccc3-c3ccccc32)c2ccccc2-4)cc1 ; CC(C)(C)c1ccc(-n2c3ccccc3c3cc4cc5c6c(c4cc32)c2ccccc2n6-c2cccc3c2B5c2ccc4c(c2O3)-c2ccccc2C42c3ccccc3-c3ccccc32)cc1]

The condensed cyclic compound of the disclosure may include at least one selected from among Compound 1, Compound 2, Compound 3, Compound 4, Compound 5, Compound 6, Compound 7, Compound 8, Compound 9, Compound 10, Compound 11, Compound 12, Compound 13, Compound 14, Compound 18, Compound 20, Compound 26, Compound 27, Compound 28, Compound 31, Compound 32, Compound 33, Compound 34, Compound 36, Compound 37, Compound 38, Compound 39, Compound 42, Compound 43, Compound 44, Compound 45, Compound 46, Compound 48, Compound 49, Compound 50, Compound 51, Compound 52, Compound 53, Compound 54, Compound 55, Compound 56, Compound 57, Compound 58, Compound 59, Compound 60, Compound 61, Compound 62, Compound 63, Compound 64, Compound 65, Compound 66, Compound 67, Compound 68, Compound 69, Compound 70, Compound 71, Compound 72, Compound 73, Compound 74, Compound 75, Compound 76, Compound 77, Compound 78, Compound 79, Compound 80, Compound 81, Compound 82, Compound 86, Compound 87, Compound 88, Compound 89, Compound 90, Compound 91, Compound 92, Compound 93, Compound 94, Compound 95, Compound 99, Compound 101, Compound 102, Compound 103, Compound 104, Compound 105, Compound 106, or Compound 107. The condensed cyclic compound of the disclosure may include at least one selected from among Compound 1, Compound 2, Compound 3, or Compound 4.

In the condensed cyclic compound of the disclosure, the fluorescence wavelength peak obtained by converting the adiabatic first excitation singlet state (S₁) energy (hereinafter, also referred to as “adiabatic S₁ excitation energy”) (eV) into a light wavelength (nm), the oscillator strength f of the stable structure in the adiabatic first excitation singlet state (S₁), and the reorganization energy may be calculated by the density functional theory (DFT) using the calculation software Gaussian 16 (Gaussian Inc.). A detailed description of each calculation method is provided in Examples.

In the condensed cyclic compounds of the disclosure, the fluorescence wavelength peak obtained by converting the adiabatic S₁ excitation energy (eV) into a light wavelength (nm) is not particularly limited. In this regard, the maximum fluorescence wavelength peak may be about 360 nm to about 515 nm. For example, the maximum fluorescence wavelength peak may be about 380 nm to about 505 nm, or for example, about 400 nm to about 500 nm. In addition, the maximum fluorescence wavelength peak may be about 420 nm to about 490 nm. In addition, the maximum fluorescence wavelength peak may be about 430 nm to about 480 nm, or for example, about 440 nm to about 470 nm. When the maximum fluorescence wavelength peak is within the above ranges, a device including the condensed cyclic compounds may achieve excellent luminescence, in particular, excellent blue luminescence.

In addition, the range of a peak wavelength of fluorescence in photoluminescence (PL) is the same as the range of the fluorescence wavelength peak obtained by converting the adiabatic S₁ excitation energy into a light wavelength.

In the condensed cyclic compound of the disclosure, the spectrum width of fluorescence in PL (the full width at half maximum (FWHM) of the fluorescence spectrum peak) is not particularly limited, but may be relatively narrower, than similarly structured compounds in the art. In this regard, the spectrum width of fluorescence in PL may be 30 nm or less, or for example, 25 nm or less (lower limit: greater than 0 nm). For example, the spectrum width of fluorescence in PL (FWHM) may be from 5 nm to 30 nm, or 10 nm to 30 nm. When the spectrum width of fluorescence in PL is within the above ranges, a device including the condensed cyclic compounds may achieve luminescence with higher color purity.

In the condensed cyclic compounds of the disclosure, the oscillator strength f of the stable structure in the adiabatic first excitation singlet state (S₁) may be, but is not particularly limited to, 0.22 or more. In addition, the oscillator strength f may be 0.30 or more. In addition, the oscillator strength f may be 0.40 or more, or for example, 0.50 or more. When the oscillator strength f is within the above ranges, a device including the condensed cyclic compounds may achieve high fluorescence intensity. In addition, the theoretical upper limit of the oscillator strength f is the number of electrons included in the molecule. The upper limit of the oscillator strength f may be, for example, 2.0 or 3.0, but is not particularly limited thereto.

In the condensed cyclic compounds of the disclosure, the reorganization energy may be 0.1 eV or less. For example, the reorganization energy may be 0.08 eV or less, or 0.07 eV or less. In addition, the reorganization energy may be 0.065 eV or less, or for example, 0.06 eV or less (lower limit: 0 eV). When the reorganization energy is within the above ranges, a device including the condensed cyclic compounds may achieve luminescence with a narrower emission spectrum and higher color purity.

The singlet energy S₁, triplet energy T₁, peak wavelength of fluorescence in PL, and spectrum width (FWHM) of fluorescence in PL may each be measured using a spectrofluorophotometer F-7000 manufactured by Hitachi High-Tech Science Co., Ltd. A detailed description of each measurement method is provided in the Examples section.

A method of preparing the condensed cyclic compounds according to an embodiment may be realized by those skilled in the art by referring to the synthetic methods described in the Examples. In detail, the condensed cyclic compounds may be prepared, for example, according to the methods described in Examples. For example, the compounds may be prepared by changing raw materials or reaction conditions in the methods described, adding or excluding some processes to or from the method described, or appropriately combining the method described with alternatively known synthetic methods.

For example, Compounds 1 to 4 may be prepared by the method described in the Examples.

A method of identifying the structure of the condensed cyclic compounds according to an embodiment is not particularly limited. The structure of the condensed cyclic compound according an embodiment may be identified by a known method (for example, NMR, LC-MS, or the like).

Another aspect of the disclosure relates to a material for an organic EL device including the condensed cyclic compound of the disclosure. The material for an organic EL device according to an embodiment may include the condensed cyclic compound and other materials, e.g., one or more host materials known to be used in an organic EL device.

The other materials used in an organic EL device may include, but are not particularly limited to, materials known in the art. For example, the other materials used in an organic EL device may include materials constituting each layer described in the below description of an organic EL device. The other materials used in an organic EL device may include, among the materials constituting each layer, at least one of a dopant material and a host material described in the below description of an emission layer. For example, the other materials used in an organic EL device may include at least one selected from among a TADF material (TADF compound), a phosphorescent material (phosphorescent compound), and a host material described in the below. The other materials used in an organic EL device may include (i) a host material or (ii) a host material and a TADF material or a phosphorescent material. The other materials used in an organic EL device may include a host material and a TADF material or a phosphorescent material. The other materials used in an organic EL device may include a host material and a phosphorescent material. The phosphorescent material may be a phosphorescent complex described in the below description of the emission layer. The phosphorescent material may be a platinum complex described in the below description.

Accordingly, an embodiment may include a material for an organic EL device that further includes, in addition to one or more condensed cyclic compounds of the disclosure, at least one of a TADF material and a phosphorescent material to be described below. The phosphorescent material may be a phosphorescent complex, or may be a platinum complex. When the material for an organic EL device, in particular, the material for an emission layer, includes at least one of a TADF material and a phosphorescent material, in addition to one or more of the condensed cyclic compounds of the disclosure, the luminescence efficiency and device lifespan of the organic EL device may be significantly improved.

In an embodiment, a material for an organic EL device may be a liquid material further including a solvent. The solvent may be, but is not particularly limited to, a solvent having a boiling point of about 100° C. to about 350° C. at atmospheric pressure (101.3 kPa, 1 atm). The boiling point of the solvent at atmospheric pressure may be about 150° C. to about 320° C., or for example, about 180° C. to about 300° C. When the boiling point of the solvent at atmospheric pressure is within the above ranges, the film-forming properties or processability in a wet film-forming method (particularly, in an inkjet method) may be improved.

The solvent having a boiling point of about 100° C. to about 350° C. is not particularly limited, and a known solvent may be appropriately used. Hereinafter, the solvent having a boiling point of about 100° C. to about 350° C. will be described in detail, but the disclosure is not limited thereto.

Examples of a hydrocarbon-based solvent may include octane, nonane, decane, undecane, dodecane, and the like. Examples of an aromatic hydrocarbon-based solvent may include toluene, xylene, ethylbenzene, n-propylbenzene, iso-propylbenzene, mesitylene, n-butylbenzene, sec-butylbenzene, 1-phenylpentane, 2-phenylpentane, 3-phenylpentane, phenylcyclopentane, phenylcyclohexane, 2-ethylbiphenyl, 3-ethylbiphenyl, and the like. Examples of an ether-based solvent may include 1,4-dioxane, 1,2-diethoxyethane, diethyleneglycoldimethylether, diethyleneglycoldiethylether, anisole, ethoxybenzene, 3-methylanisole, m-dimethoxybenzene, and the like. Examples of a ketone-based solvent may include 2-hexanone, 3-hexanone, cyclohexanone, 2-heptanone, 3-heptanone, 4-heptanone, cycloheptanone, and the like. Examples of an ester-based solvent may include butyl acetate, butyl propionate, heptyl butyrate, propylene carbonate, methyl benzoate, ethyl benzoate, 1-propyl benzoate, 1-butyl benzoate, and the like. Examples of a nitrile-based solvent may include benzonitrile, 3-methylbenzonitrile, and the like. Examples of an amide-based solvent may include dimethylformamide, dimethylacetamide, N-methylpyrrolidone, and the like. Such solvents may be used alone or in combination of two or more.

The material for an organic EL device according to an embodiment may be a material for an emission layer.

The material for an organic EL device according to an embodiment may be, for example, the material for an organic EL device described above that is not a liquid composition (that is, substantially free of a solvent). In addition, even when the material for an organic EL device is not a liquid composition, the material for an organic EL device may be a material for an emission layer.

The expression “substantially free of a solvent” indicates that the amount of the solvent in the material is less than 1 wt % based on the total weight of the composition. When the material for an organic EL device is not a liquid composition, the material for an organic EL device may be substantially free of a solvent, or may not include a solvent (wherein the amount of the solvent is 0 wt % based on the total weight of the composition).

The amount of the condensed cyclic compound based on the total weight (in the case of a liquid composition, the total weight excluding the solvent) of the material for an organic EL device (in particular, the material for an emission layer) may be the same as the amount of the condensed cyclic compound based on the total weight of the emission layer of the organic EL device to be described below.

The amount of the TADF material or the phosphorescent material (in particular, the phosphorescent material) based on the total weight (in the case of a liquid composition, the total weight excluding the solvent) of the material for an organic EL device (in particular, the material for an emission layer) may be the same as the amount of the TADF material or the phosphorescent material (in particular, the phosphorescent material) based on the total weight of the emission layer of the organic EL device to be described below.

The amount (parts by weight) of the TADF material or the phosphorescent material (in particular, the phosphorescent material) based on 100 parts by weight of the condensed cyclic compound in the material for an organic EL device (in particular, the material for an emission layer) may be the same as the amount (parts by weight) of the TADF material or the phosphorescent material (in particular, the phosphorescent material) based on 100 parts by weight of the condensed cyclic compound in the emission layer of the organic EL device to be described below.

The amount of the host material based on the total weight (in the case of a liquid composition, the total weight excluding the solvent) of the material for an organic EL device (in particular, the material for an emission layer) may be the same as the amount of the host material based on the total weight of the emission layer of the organic EL device to be described below.

The amount (parts by weight) of the host material based on 100 parts by weight of the condensed cyclic compound in the material for an organic EL device (in particular, the material for an emission layer) may be the same as the amount (parts by weight) of the host material based on 100 parts by weight of the condensed cyclic compound in the emission layer of the organic EL device to be described below.

When the amounts of the condensed cyclic compound, the TADF material or the phosphorescent material, and the host material in the material for an organic EL device (in particular, the material for an emission layer) are within the above ranges, respectively, an organic EL device having excellent luminescence color purity, high luminescence efficiency, and a long lifespan may be achieved.

Another aspect of the disclosure relates to a composition including one or more of the condensed cyclic compounds. The composition according to an embodiment may include the condensed cyclic compound and other materials used in an organic EL device.

The types of the other materials used in an organic EL device and the amounts of the other materials in the composition are the same as described above in Material for Organic EL Device, and thus, descriptions thereof are omitted.

In an embodiment, a composition including at least one of a TADF material and a phosphorescent material, in addition to the condensed cyclic compound, may be provided. The phosphorescent compound may be a phosphorescent complex, or may be a phosphorescent platinum complex. When the material for an organic EL device (in particular, the material for an emission layer) includes a TADF material or a phosphorescent material, in addition to one or more of the condensed cyclic compounds, the luminescence efficiency and device lifespan of the organic EL device may be significantly improved.

Another aspect of the disclosure relates to an organic EL device having an organic layer including one or more of the condensed cyclic compounds. The organic EL device may exhibit a relatively narrow emission spectrum, may realize luminescence with high color purity, and may realize high luminescence efficiency, and/or a long lifespan.

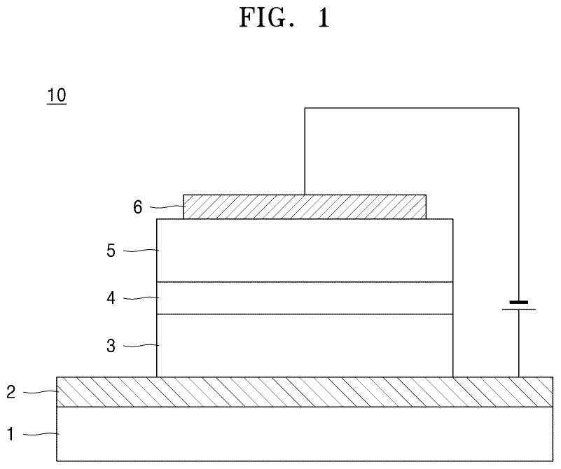

Hereinafter, an organic EL device according to an embodiment will be described in detail with reference to the drawings. FIGS. 1, 2, and 3 are each a schematic representations illustrating an organic EL device according to an embodiment. However, the structure of the organic EL device according to the disclosure is not limited to the embodiments illustrated in FIGS. 1 to 3.

FIG. 1 is a schematic cross-sectional representation illustrating an organic EL device 10 according to an embodiment. The organic EL device 10 according to an embodiment may include a substrate 1, a first electrode 2, a hole transport region 3, an emission layer 4, an electron transport region 5, and a second electrode 6, which are sequentially stacked in the stated order as shown.

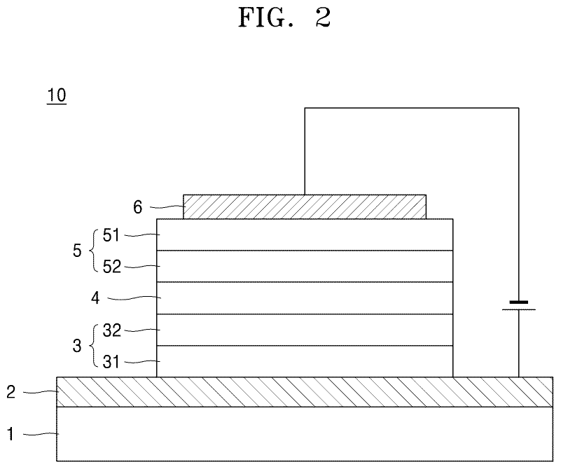

FIG. 2 is a schematic cross-sectional representation illustrating the organic EL device 10 according to an embodiment. The organic EL device 10 may include a substrate 1, a first electrode 2, a hole transport region 3, an emission layer 4, an electron transport region 5, and a second electrode 6, which are sequentially stacked in the stated order. In FIG. 2, the hole transport region 3 may include a hole injection layer 31 and a hole transport layer 32, which are sequentially stacked in the stated order. The electron transport region 5 may include an electron transport layer 52 and an electron injection layer 51, which are sequentially stacked in the stated order.

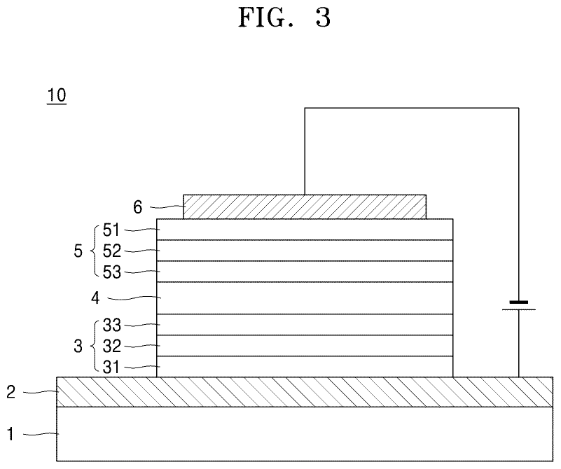

FIG. 3 is a schematic cross-sectional view illustrating the organic EL device 10 according to an embodiment. The organic EL device 10 according to an embodiment may include a substrate 1, a first electrode 2, a hole transport region 3, an emission layer 4, an electron transport region 5, and a second electrode 6, which are sequentially stacked in the stated order. In FIG. 3, the hole transport region 3 includes the hole injection layer 31, the hole transport layer 32, and an electron-blocking layer 33, which are sequentially stacked in the stated order. In addition, in FIG. 3, the electron transport region 5 may include a hole-blocking layer 53, the electron transport layer 52, and the electron injection layer 51, which are sequentially stacked in the stated order.

One or more of the condensed cyclic compounds according to the disclosure may be included, for example, in any organic layer arranged between the first electrode 2 and the second electrode 6. The organic layer may be the hole injection layer 31, the hole transport layer 32, the emission layer 4, the electron transport layer 52, the electron injection layer 51, or the like. For example, the condensed cyclic compound according to the disclosure may be included in the emission layer 4.

An embodiment may include, for example, an organic EL device including a first electrode, a second electrode, and a single or a plurality of emission layers. For example, the second electrode may be arranged on the first electrode.

Herein, when a portion of a layer, film, region, plate, or the like is said to be “under” or “below” another portion, this includes not only a case where the portion is “directly under” the other portion, but also a case where an intervening layer is present therebetween. Herein, being arranged “on” includes not only being arranged on an upper surface but also on a lower or bottom surface.

As described above, one or more of the condensed cyclic compounds of the disclosure may be included in an emission layer. That is, the organic layer may be an emission layer. Hereinafter, an embodiment in which the condensed cyclic compound of the disclosure is included in the emission layer will be described. In addition, the condensed cyclic compound according to the disclosure included in the emission layer may be a single compound or a combination of two or more compounds.

The emission layer may be a single layer including a single material or a single layer including a plurality of different materials. In addition, the emission layer may have a multi-layer structure including a plurality of layers including a plurality of different materials.

The amount of the one or more condensed cyclic compounds based on the total weight of the emission layer may be, but is not particularly limited to, 0.05 wt % or more. For example, the amount may be 0.1 wt % or more, or 0.2 wt % or more. The amount of the condensed cyclic compound based on the total weight of the emission layer may be 50 wt % or less. For example, the amount may be 30 wt % or less, or for example, 25 wt % or less. Within the above ranges, an organic EL device having excellent luminescence color purity, higher luminescence efficiency, and a longer lifespan may be achieved.

The emission layer is not particularly limited, and may include, for example, a host material and a dopant material. The condensed cyclic compound may be used as a host material or a dopant material, and for example, may be used as a dopant material.

The emission layer is not particularly limited, and may include, for example, a known material for an emission layer. For example, the emission layer may include, in addition to the condensed cyclic compound, an anthracene derivative, a pyrene derivative, a fluoranthene derivative, a chrysene derivative, a dihydrobenzoanthracene derivative, or a triphenylene derivative.

In addition, the emission layer may include, in addition to the condensed cyclic compound, a known TADF compound. The term “thermally activated delayed fluorescence” refers to a phenomenon in which reverse intersystem crossing occurs from triplet excitons to singlet excitons in a compound with a small energy difference (ΔE_{ST}) between the singlet level and the triplet level. The term “TADF material” refers to a material in which such a phenomenon occurs.

Examples of the TADF material may include the following compounds.

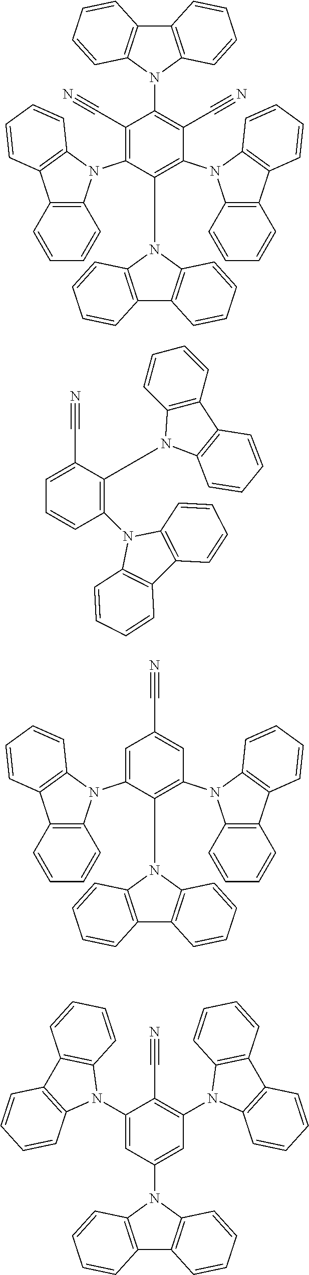

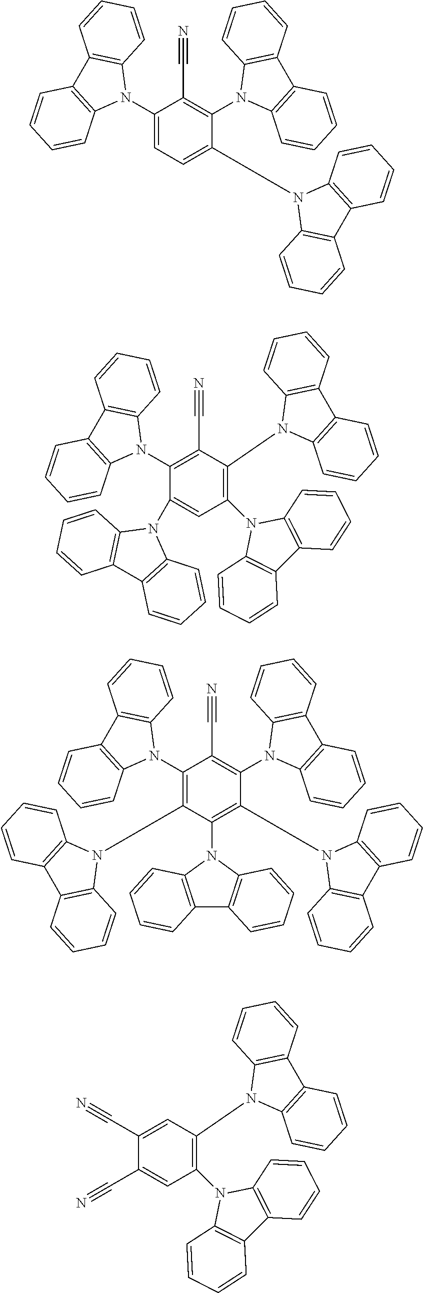

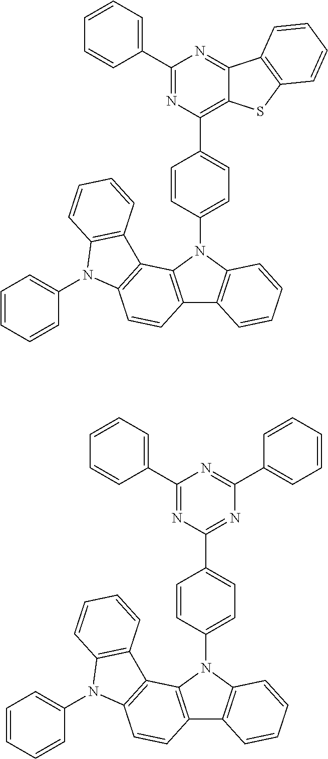 [SMILES: c1ccc(-c2nc(-c3ccc(-n4c5ccccc5c5ccc6c(c7ccccc7n6-c6ccccc6)c54)cc3)c3sc4ccccc4c3n2)cc1 ; c1ccc(-c2nc(-c3ccccc3)nc(-c3ccc(-n4c5ccccc5c5ccc6c(c7ccccc7n6-c6ccccc6)c54)cc3)n2)cc1]

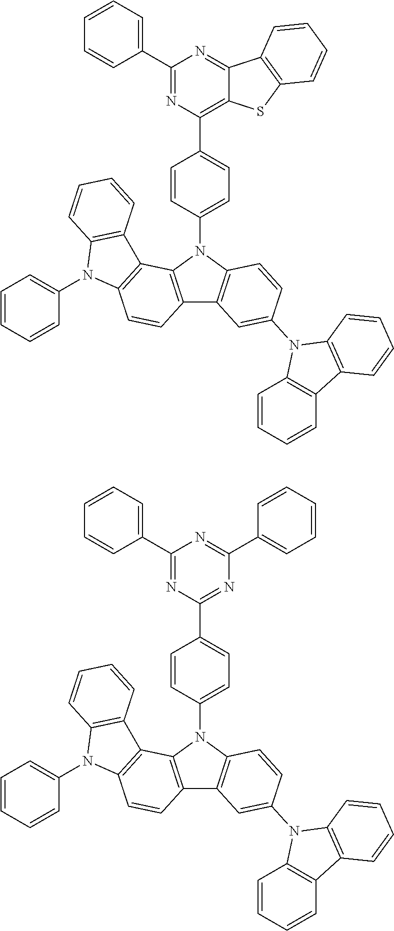

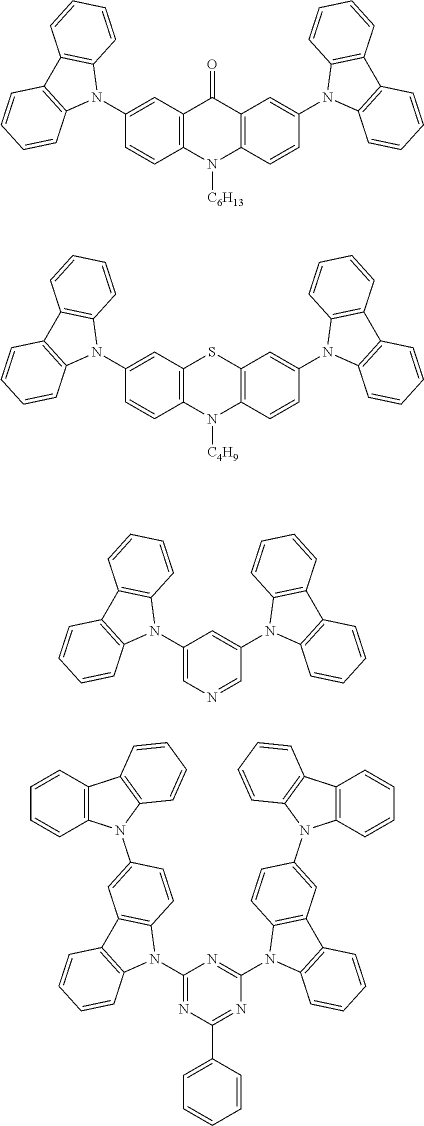

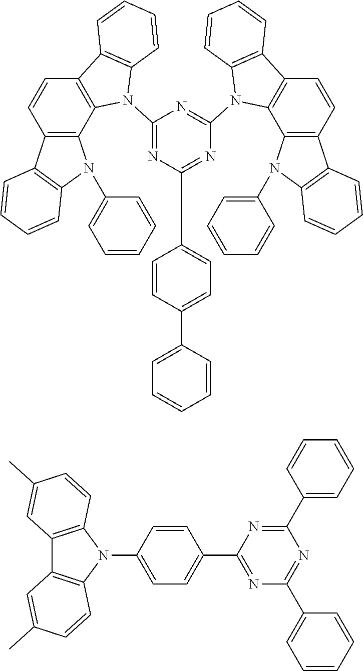 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; Cc1ccc2c(c1)c1cc(C)ccc1n2-c1ccc(-c2nc(-c3ccccc3)nc(-c3ccccc3)n2)cc1]

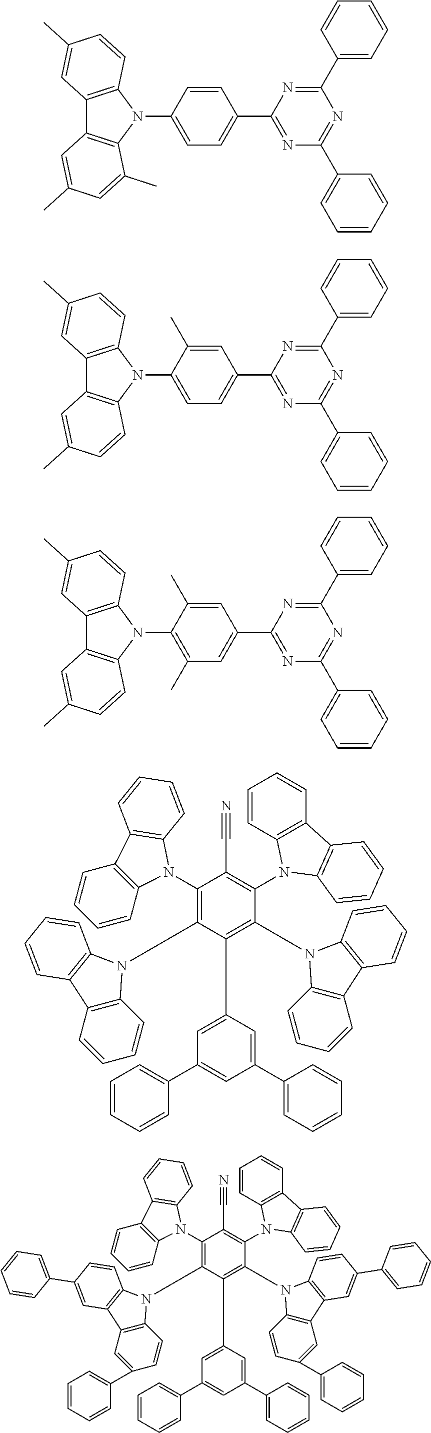

TADF materials may be used alone or in combination of two or more.

In addition, the emission layer may include, in addition to the condensed cyclic compound, a phosphorescent material (phosphorescent compound). The phosphorescent material (phosphorescent compound) is not particularly limited, and a known compound exhibiting phosphorescence may be used. Among known compounds, the phosphorescent material (phosphorescent compound) may be a phosphorescent complex, or may be a phosphorescent platinum complex.

Examples of the phosphorescent material (phosphorescent compound) may include the following compounds.

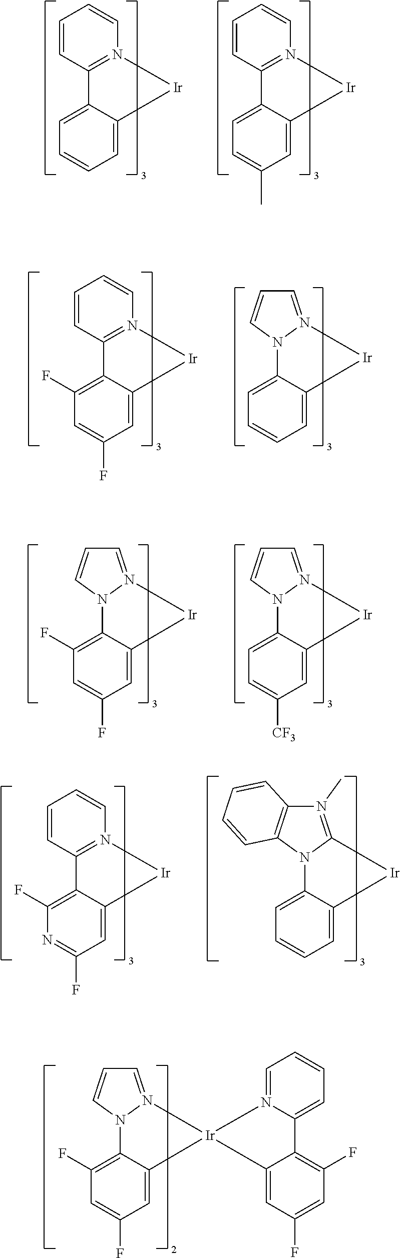

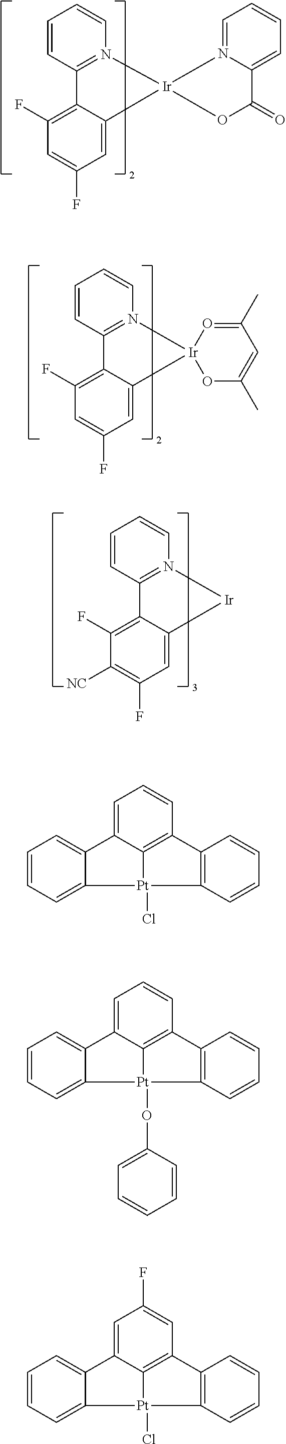

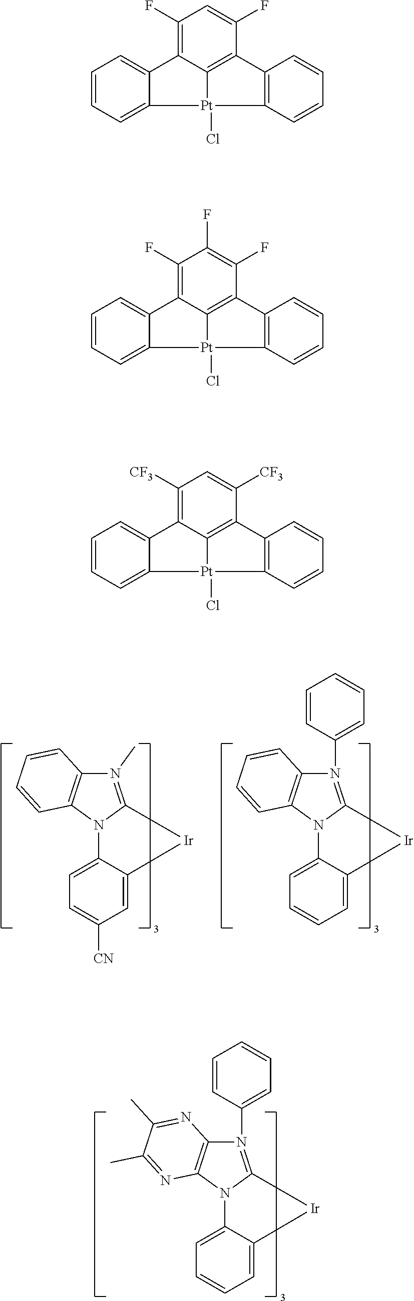

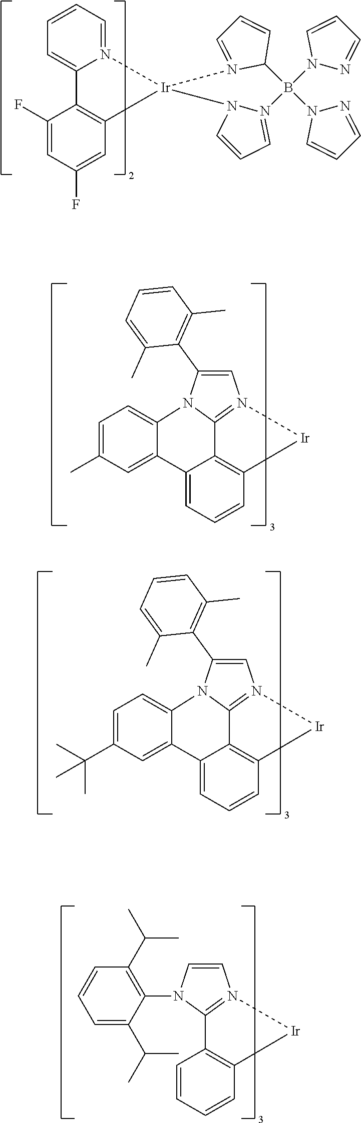

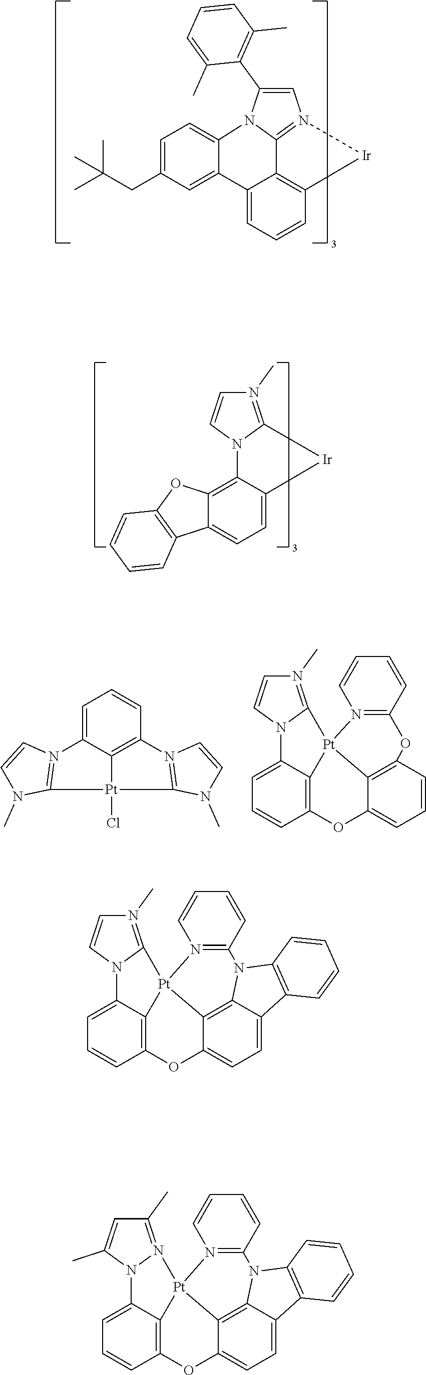

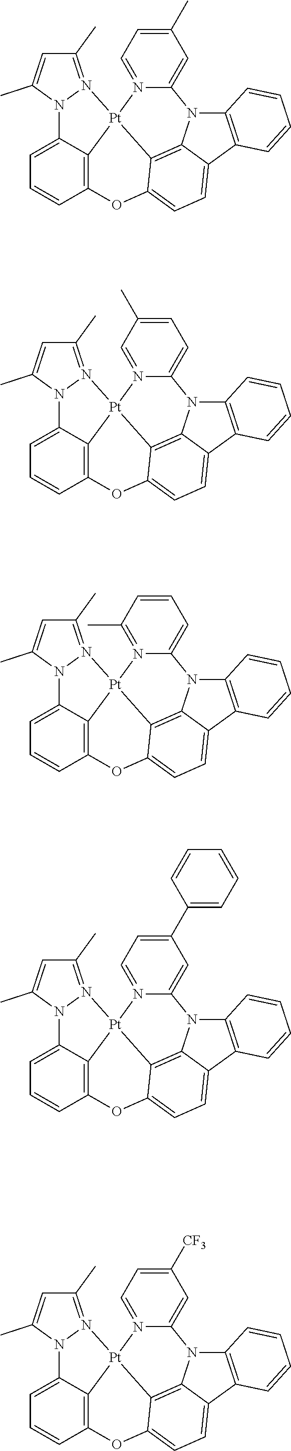

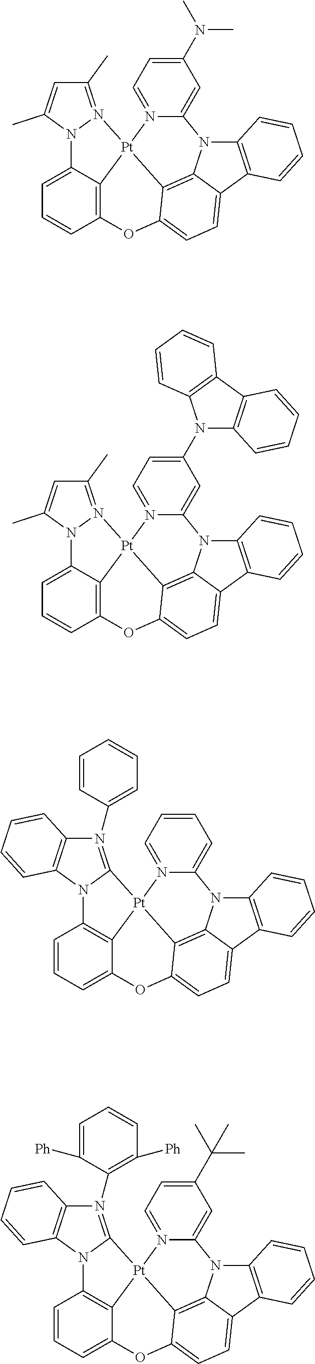

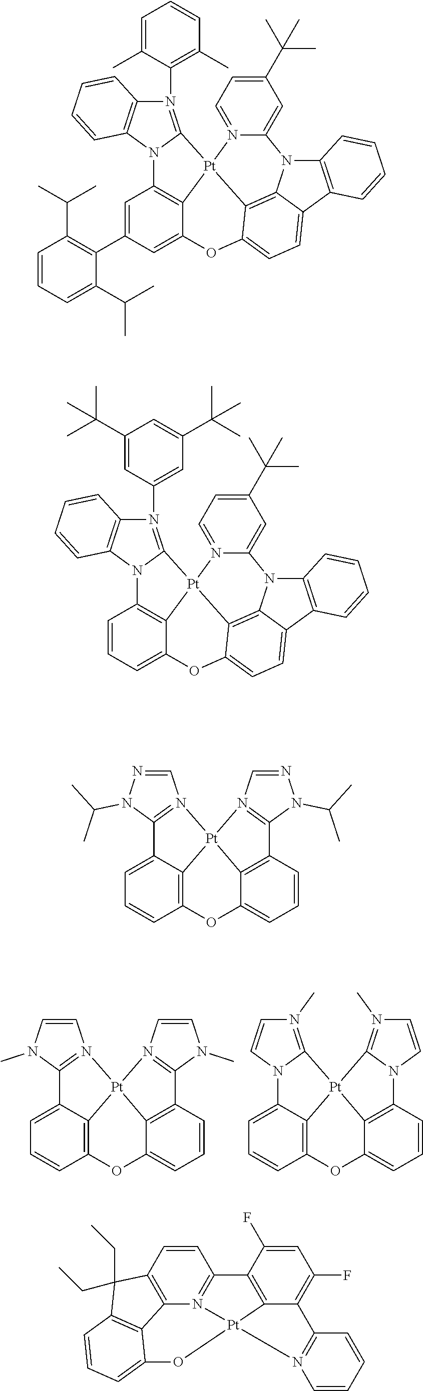

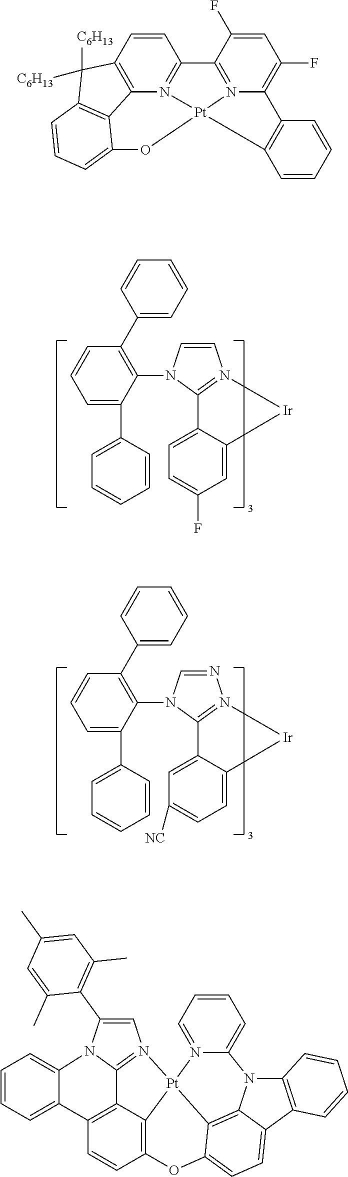

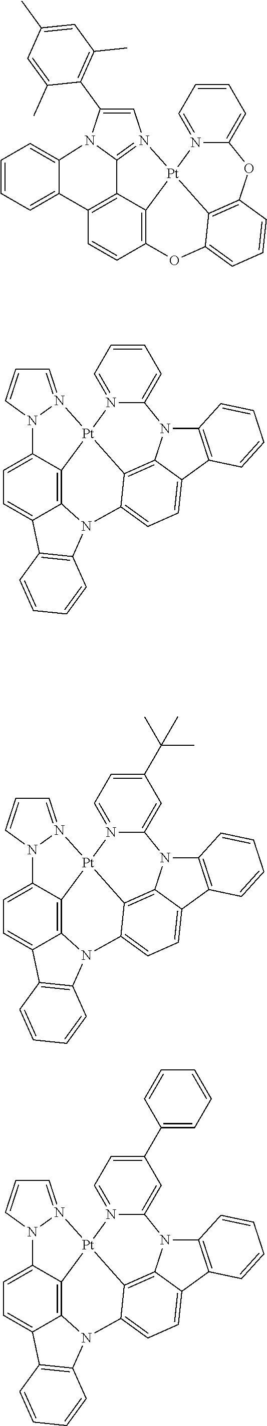

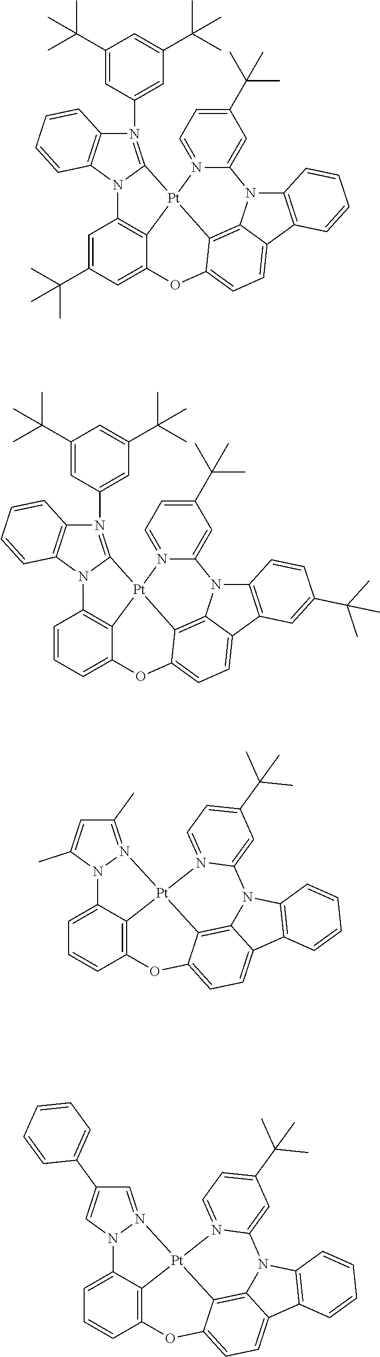

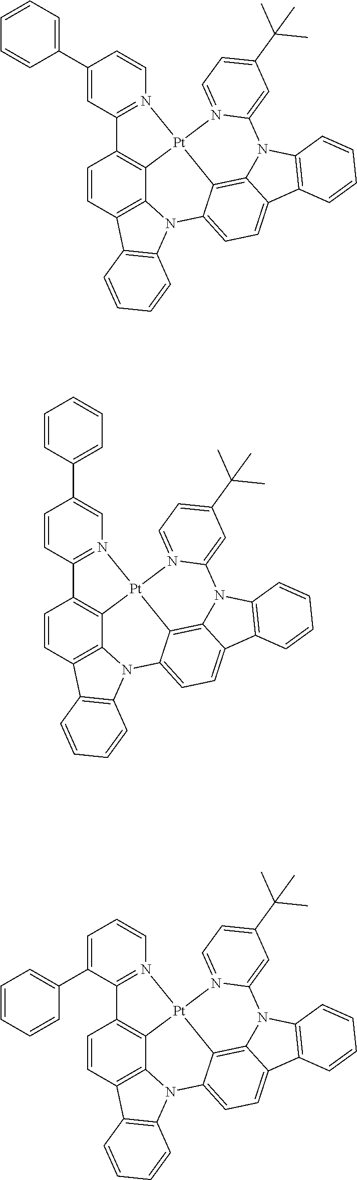

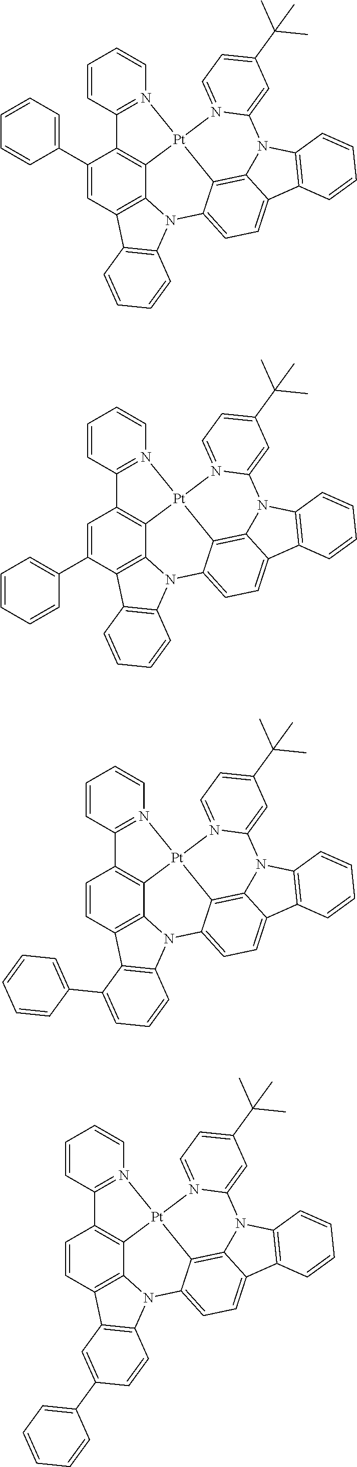

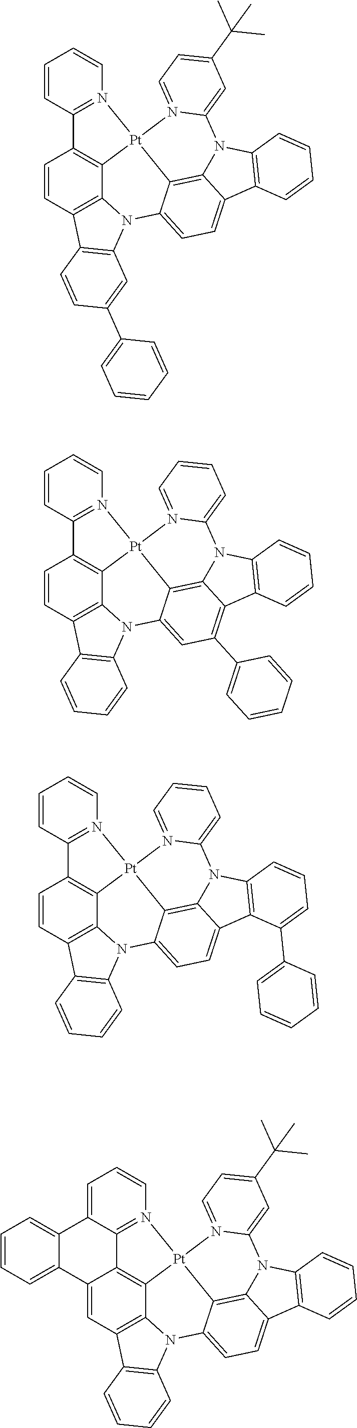

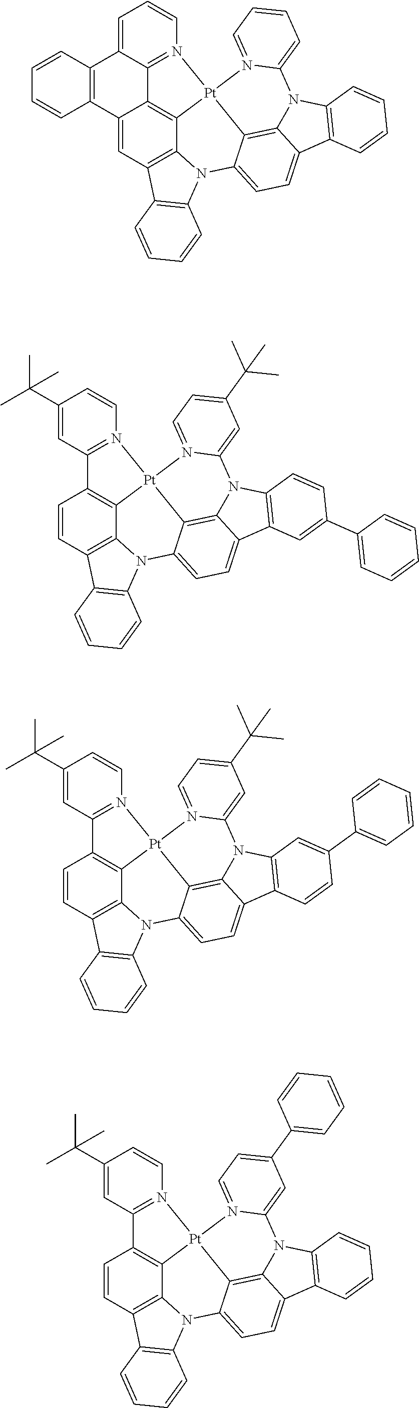

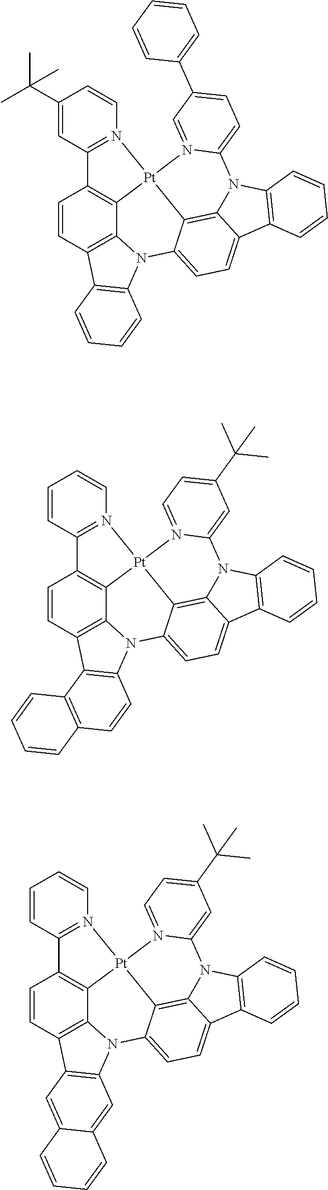

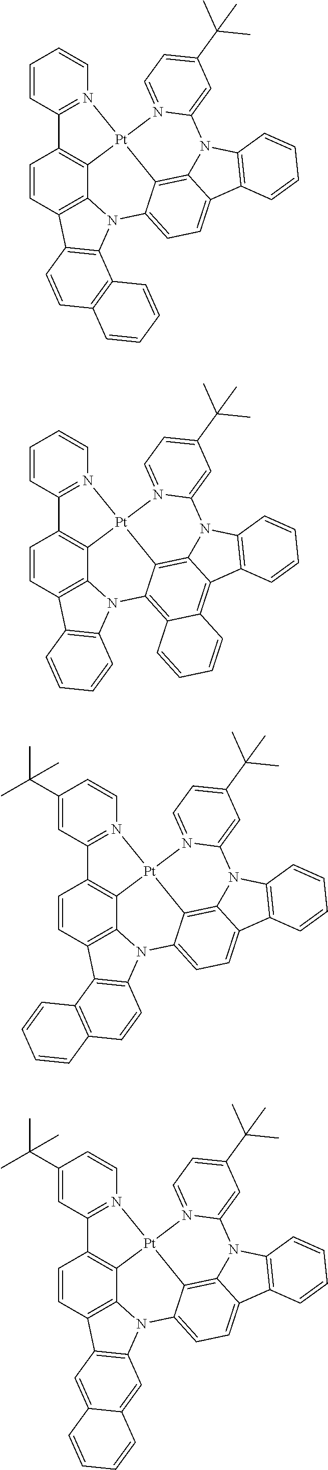

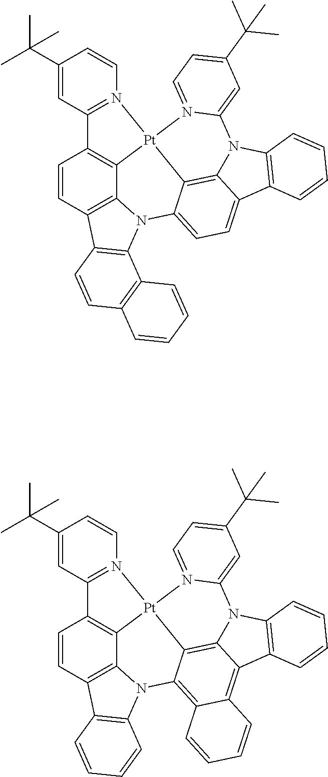

Such phosphorescent materials (phosphorescent compounds) may be used alone or in

When the emission layer includes at least one of a TADF material and a phosphorescent material, in addition to the condensed cyclic compound of the disclosure, the luminescence efficiency and device lifespan of the organic EL device may be significantly improved.

In an emission layer of an organic EL device, singlet excitons and triplet excitons are generated at a ratio of 1:3 by recombination of holes and electrons. In a device including only a fluorescent material as a luminescent material, only singlet excitons are involved in light emission, whereas in a device including a TADF material or a phosphorescent material as a luminescent material, both singlet excitons and triplet excitons may be used for light emission. Accordingly, the luminescence efficiency of the device including the TADF material or the phosphorescent material as a luminescent material may be significantly improved. Excitons generated on the TADF material or the phosphorescent material may generally have a long lifespan of 1 μs or more. As a result, the excitons are in an unstable state with high energy. Accordingly, while the excitons are present, material deterioration may occur, resulting in a decrease in device lifespan. When the TADF material or the phosphorescent material is present in the emission layer, in addition to the condensed cyclic compound, excitons are generated with high efficiency on the TADF material or the phosphorescent material. In addition, energy may be transferred from the excitons to the condensed cyclic compound through a Forster resonance energy transfer (FRET) mechanism. As a result, highly efficient fluorescence may be obtained from the condensed cyclic compound, and the time for which excitons are present on the TADF material or the phosphorescent material may be shortened. Accordingly, the possibility of material (device) deterioration may be significantly reduced, and the device lifespan may be significantly improved.

The amount of at least one of the TADF material and the phosphorescent material (in particular, the phosphorescent material) based on the total weight of the emission layer may be, but is not particularly limited to, 0.1 wt % or more. For example, the amount may be 0.5 wt % or more, or 1 wt % or more. The amount may be 3 wt % or more, or 5 wt % or more. The amount of at least one of the TADF material and the phosphorescent material (in particular, the phosphorescent material) based on the total weight of the emission layer may be 50 wt % or less. For example, the amount may be 40 wt % or less, or 30 wt % or less. When the emission layer includes both the TADF material and the phosphorescent material, the total amount thereof may be within the above ranges. Within the above ranges, an organic EL device having excellent luminescence color purity, higher luminescence efficiency, and a longer lifespan may be achieved.

When the emission layer includes at least one of the TADF material and the phosphorescent material (in particular, the phosphorescent material), the amount thereof may be, but is not particularly limited to, 100 parts by weight or more based on 100 parts by weight of the condensed cyclic compound. For example, the amount may be 150 parts by weight or more, or 200 parts by weight or more, based on 100 parts by weight of the condensed cyclic compound. The amount of at least one of the TADF material and the phosphorescent material (in particular, the phosphorescent material) may be 10,000 parts by weight or less based on 100 parts by weight of the condensed cyclic compound. For example, the amount may be 7,500 parts by weight or less, or 5,000 parts by weight or less, based on 100 parts by weight of the condensed cyclic compound. When the emission layer includes both the TADF material and the phosphorescent material, the total amount thereof may be within the above ranges. Within the above ranges, an organic EL device having excellent luminescence color purity, higher luminescence efficiency, and a longer lifespan may be achieved.

The emission layer is not particularly limited, and may include, for example, a known host material. The emission layer may include, for example, at least one of bis[2-(diphenylphosphino)phenyl] ether oxide (DPEPO), 4,4′-bis(carbazol-9-yl)biphenyl (CBP), 3,3′-bis(carbazol-9-yl)biphenyl (mCBP), 1,3-bis(carbazol-9-yl)benzene (mCP), 2,8-bis(diphenylphosphoryl)dibenzo[b,d] furan (PPF), 4,4′,4″-tris(carbazol-9-yl)triphenylamine (TCTA), and 1,3,5-tris(N-phenylbenzimidazol-2-yl)benzene (TPBi). However, the host material is not limited thereto, and the emission layer may include, for example, tris(8-hydroxyquinolino)aluminum (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazol-2-yl)benzene (TPBi), 3-tert-butyl-9,10-di(naphtho-2-yl)anthracene (TBADN), distyrylarylene (DSA), 4,4′-bis(9-carbazolyl)-2,2′-dimethyl-biphenyl (CDBP), 2-methyl-9,10-bis(naphthalene-2-yl)anthracene (MADN), bis[2-(diphenylphosphino)phenyl] ether oxide (DPEPO), hexaphenylcyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), or 2,8-bis(diphenylphosphoryl)dibenzofuran (PPF).

In addition, the emission layer may include, as the host material, a material having a highest occupied molecular orbital (HOMO) of −5.2 eV or less. In addition, the emission layer may include, as the host material, a material having a lowest unoccupied molecular orbital (LUMO) of −1.4 eV or less. By using a host material having low HOMO and LUMO and high electron transport properties, the driving durability in an organic EL device (in particular, a blue organic EL device) may be improved. Such a material is not particularly limited, and an example thereof may be a compound represented by Formula A, which is disclosed Soo-Ghang Ihn, et al., in “An Alternative Host Material for Long-Lifespan Blue Organic Light-Emitting Diodes Using Thermally Activated Delayed Fluorescence,” Soo-Ghang Ihn et al., Advanced Science News 2017, 4, 1600502. When the emission layer is formed in combination with such a host material, a blue luminescent material in the related art may become a deep hole trap, thereby causing undesirable effects such as an increase in driving voltage. The condensed cyclic compound of the disclosure has weak hole-trapping properties, and thus, it is expected to suppress the increase in driving voltage.

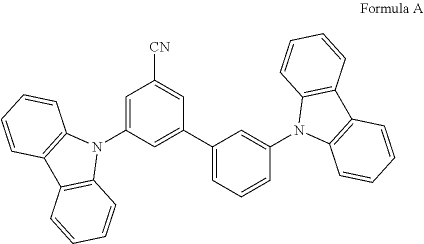 [SMILES: N#Cc1cc(-c2cccc(-n3c4ccccc4c4ccccc43)c2)cc(-n2c3ccccc3c3ccccc32)c1]

In addition, the emission layer may include, as the host material, the following compounds.

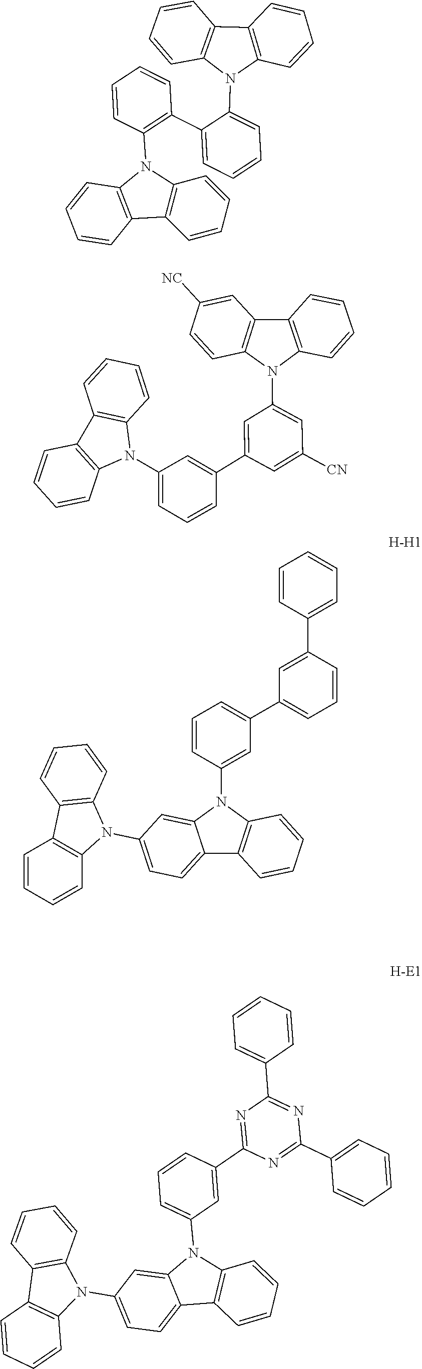

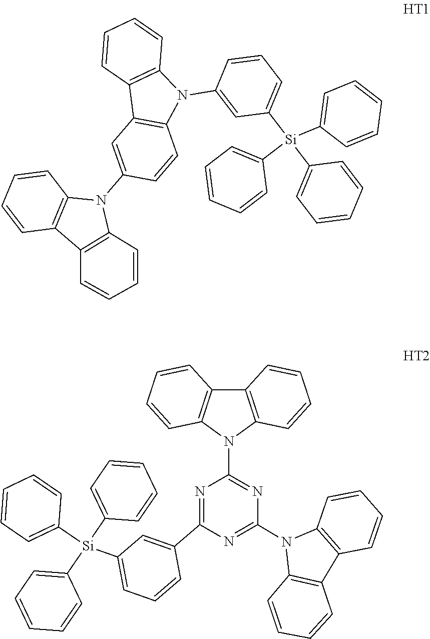 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

Among the above compounds, the emission layer may include, as the host material, at least one of Compound HT1 and Compound HT2, or may include, as the host material, both Compound HT1 and Compound HT2.

The amount of the host material based on the total weight of the emission layer may be, but is not particularly limited to, 5 wt % or more. For example, the amount may be 10 wt % or more, or 20 wt % or more. The amount of the host material based on the total weight of the emission layer may be 99 wt % or less. For example, the amount may be 95 wt % or less, or 90 wt % or less. Within the above ranges, an organic EL device having excellent luminescence color purity, high luminescence efficiency, and a long lifespan may be achieved.

When the emission layer includes the host material, the amount thereof may be, but is not particularly limited to, 1,000 parts by weight or more based on 100 parts by weight of the condensed cyclic compound. For example, the amount may be 2,000 parts by weight or more, or for example, 3,000 parts by weight or more, based on 100 parts by weight of the condensed cyclic compound. The amount of the host material may be 200,000 parts by weight or less based on 100 parts by weight of the condensed cyclic compound. For example, the amount may be 150,000 parts by weight or less, or 100,000 parts by weight or less, based on 100 parts by weight of the condensed cyclic compound. Within the above ranges, an organic EL device having excellent luminescence color purity, high luminescence efficiency, and a long lifespan may be achieved.

The emission layer is not particularly limited, and may include, for example, a known dopant material. For example, the emission layer may include a styryl derivative (for example, 1,4-bis[2-(3-N-ethylcarbazolyl)vinyl] benzene (BCzVB), 4-(di-p-tolylamino)-4′-[(di-p-tolylamino)styryl] stilbene (DPAVB), or N-4(-((E)-2-(6-((E)-4-(diphenylamino)styryl)naphthalene-2-yl)vinyl)phenyl)-N-phenylbenzeneamine (N-BDAVBi)), perylene or a derivative thereof (for example, 2,5,8,11-tetra-tert-butylperylene (TBP)), or pyrene or a derivative thereof (for example, 1,1-dipyrene, 1,4-dipyrenylbenzene, or 1,4-bis(N,N-diphenylamino)pyrene).

The emission layer may be a single layer including a single material or a single layer including a plurality of different materials. In addition, the emission layer may have a multi-layer structure including a plurality of layers including a plurality of different materials.

The thickness of the emission layer may be, but is not particularly limited to, about 1 nm to about 100 nm, or for example, about 10 nm to about 30 nm.

The emission wavelength of the emission layer (that is, the emission wavelength of the organic EL device including the emission layer) is not particularly limited. However, the emission layer may emit light having a peak in a wavelength range of about 360 nm to about 515 nm. The emission layer may emit, for example, light having a peak in a wavelength range of about 380 nm to about 505 nm. The emission layer may emit, for example, light having a peak in a wavelength range of about 400 nm to about 500 nm. The emission layer may emit, for example, light having a peak in a wavelength range of about 420 nm to about 470 nm. The emission layer may emit, for example, light having a peak in a wavelength range of about 430 nm to about 465 nm. Within the above ranges, excellent luminescence (in particular, excellent blue luminescence) may be achieved.

The emission spectrum width (the FWHM of the emission spectrum peak) of the emission layer (that is, the emission spectrum width of the organic EL device including the emission layer) is not particularly limited, but may be narrower. In this regard, the emission spectrum width may be 30 nm or less, for example, 25 nm or less, or for example, 24 nm or less (lower limit: greater than 0 nm). Within the above ranges, luminescence with higher color purity may be obtained.

Examples of the film-forming method of the emission layer may include, but are not particularly limited to, known film-forming methods such as vacuum deposition, spin coating, Langmuir-Blodgett (LB) deposition, ink-jet printing, laser-printing, laser-induced thermal imaging (LITI), and the like.

Hereinafter, the substrate, each region, and each layer will be described in detail.

The organic EL device 10 may include the substrate 1. As the substrate 1, a substrate used in a general organic EL device may be used. For example, the substrate 1 may be a glass substrate, a semiconductor substrate such as a silicon substrate, or a transparent plastic substrate.

The first electrode 2 may have conductivity. In the organic EL device 10 according to an embodiment, the first electrode 2 may be an anode. For example, the first electrode 2 may be a pixel electrode. The first electrode 2 may be a transmissive electrode, a transflective electrode, or a reflective electrode.

A material for forming the first electrode 2 is not particularly limited, and an example thereof may be a metal, a metal alloy, or a conductive compound. When the first electrode 2 is a transmissive electrode, the first electrode 2 may include a transparent metal oxide, for example, indium tin oxide (ITO), indium zinc oxide (IZO), zinc oxide (ZnO), indium tin zinc oxide (ITZO), or the like. When the first electrode 2 is a transflective electrode or a reflective electrode, the first electrode 2 may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg).

The first electrode 2 may be a single layer including a single material or a single layer including a plurality of different materials. For example, the first electrode 2 may have a multi-layer structure including a plurality of layers including a plurality of different materials.

The thickness of the first electrode 2 may be, but is not particularly limited to, about 10 nm to about 1,000 nm, for example, about 100 nm to about 300 nm.

The hole transport region 3 may be provided on the first electrode 2. The hole transport region 3 may include at least one of the hole injection layer 31, the hole transport layer 32, a hole buffer layer (not shown), and the electron-blocking layer 33.

The hole transport region 3 may be a single layer including a single material or a single layer including a plurality of different materials. In addition, the hole transport region 3 may have a multi-layer structure including a plurality of layers including a plurality of different materials.

For example, the hole transport region 3 may have a single-layer structure including the hole injection layer 31 or the hole transport layer 32. The hole transport region 3 may have a single-layer structure including a hole injection material and a hole transport material. The hole transport region 3 may have a hole injection layer 31/hole transport layer 32 structure, wherein constituting layers are sequentially stacked in the stated order from the first electrode 2. The hole transport region 3 may have a hole injection layer 31/hole transport layer 32/hole buffer layer (not shown) structure. The hole transport region 3 may have a hole injection layer 31/hole buffer layer (not shown) structure, wherein constituting layers are sequentially stacked in the stated order from the first electrode 2. The hole transport region 3 may have a hole transport layer 32/hole buffer layer (not shown) structure, wherein constituting layers are sequentially stacked in the stated order from the first electrode 2. The hole transport region 3 may have a hole injection layer 31/hole transport layer 32/electron-blocking layer 33 structure, wherein constituting layers are sequentially stacked in the stated order from the first electrode 2. However, the structure of the hole transport region 3 is not limited to the above examples.

The hole injection layer 31 or other layers constituting the hole transport region 3 are not particularly limited, and may include, for example, a known hole injection material. Examples of the hole injection material may include a phthalocyanine compound such as copper phthalocyanin, N,N′-diphenyl-N,N′-bis-[4-phenyl-m-toly-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), polyetherketone including triphenylamine (TPAPEK), 4-isopropyl-4′-methyldiphenyliodonium tetrakis(pentafluorophenyl)borate, dipyrazino[2,3-f:2′,3′-h] quinoxaline-2,3,6,7,10,11-hexacarbonitrile (HAT-CN), 1,3,4,5,7,8-hexafluorotetracyano-2,6-naphthoquinodimethane (F6-TCNNQ), and the like.

In addition, the hole transport layer 32 or other layers constituting the hole transport region 3 are not particularly limited, and may include, for example, a known hole transport material. Examples of the hole transport material may include N-phenylcarbazole, a carbazole-based derivative such as polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenyl-benzidine (NPB), 4,4′-cyclohexylidenebis[N,N-bis(4-methylphenyl)benzeneamine](TAPC), 4,4′-bis[N,N′-(3-tolyl)amino]-3,3′-dimethylbiphenyl (HMTPD), 1,3-bis(N-carbazolyl)benzene (mCP), Compound H1, Compound H2, Compound HT3, and the like.

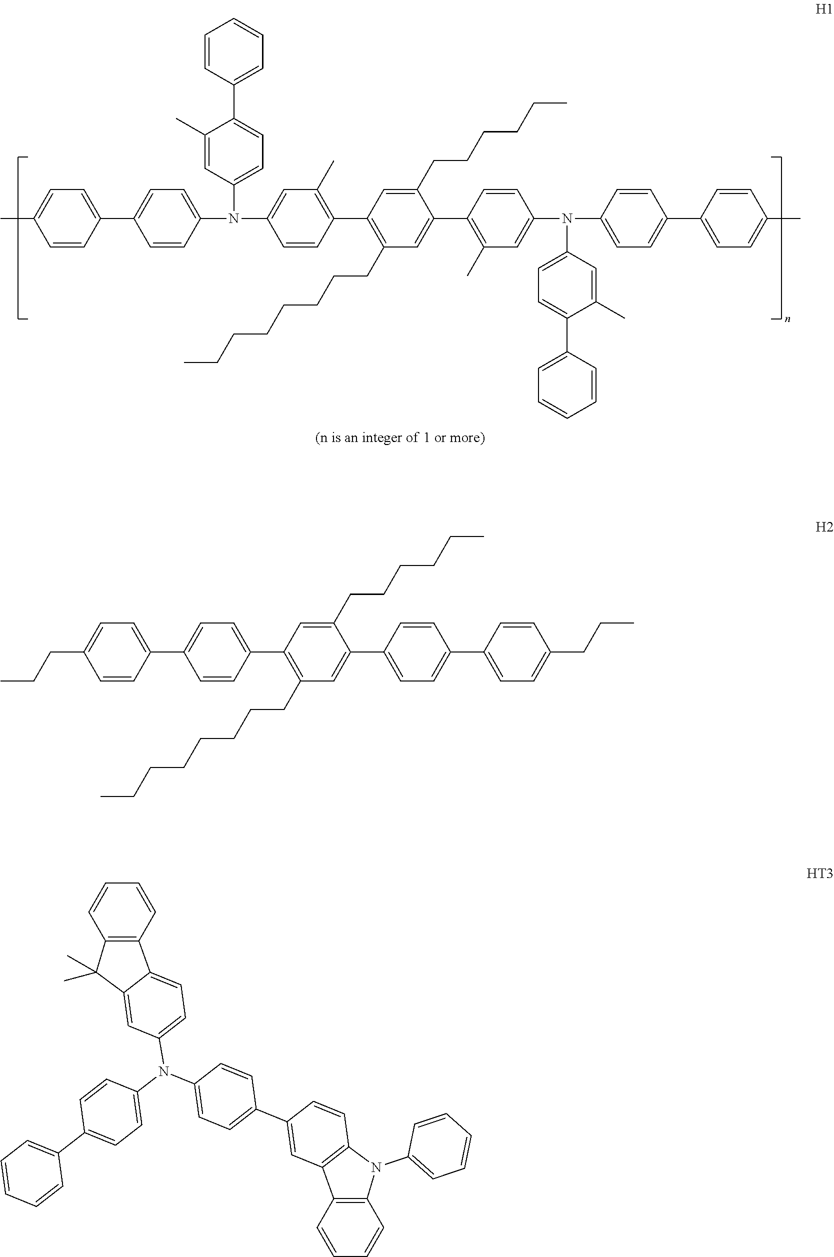

The hole transport region 3 may further include, in addition to the hole injection material or the hole transport material, a charge generation material to improve conductivity. The charge generation material may be homogeneously or non-homogeneously dispersed in the hole transport region 3 or each layer thereof. The charge generation material is not particularly limited, and an example thereof may be a known charge generation material. An example of the charge generation material may be a p-dopant. Examples of the p-dopant may include a quinone derivative such as tetracyanoquinonedimethane (TCNQ) or 2,3,5,6-tetrafluoro-tetracyanoquinodimethane (F4-TCNQ), a metal oxide such as tungsten oxide or molybdenum oxide, a cyano group-containing compound, and the like.

The hole buffer layer (not shown) may increase luminescence efficiency by compensating for an optical resonance distance according to the wavelength of light emitted by the emission layer 4. Materials included in the hole buffer layer (not shown) are not particularly limited, and materials used in a known hole buffer layer may be used. For example, the compounds that may be included in the hole transport region 3 may be used.

The electron-blocking layer 33 may prevent injection of electrons from the electron transport region 5 to the hole transport region 3. Materials included in the electron-blocking layer 33 are not particularly limited, and materials used in a known electron-blocking layer may be used. For example, the host materials included in the emission layer 4 and Compounds H-H1 and HT1 as host materials may be included.

The thickness of the hole transport region 3 may be, but is not particularly limited to, about 1 nm to about 1,000 nm, or for example, about 10 nm to about 500 nm. For example, regarding each layer constituting the hole transport region 3, the thickness of the hole injection layer 31 may be, but is not particularly limited to, about 3 nm to about 100 nm. The thickness of the hole transport layer 32 may be, but is not particularly limited to, about 3 nm to about 200 nm, or for example, about 3 nm to about 100 nm. The thickness of the electron-blocking layer 33 may be, but is not particularly limited to, about 1 nm to about 100 nm. The thickness of the hole buffer layer (not shown) is not particularly limited, as long as the hole buffer layer functions as a hole buffer layer and does not interfere with functions of an organic EL device. When the thickness of the hole transport region 3, the hole injection layer 31, the hole transport layer 32, or the electron-blocking layer 33 is within the above ranges, excellent hole transport characteristics may be obtained without a substantial increase in driving voltage.

Examples of the film-forming method of the hole transport region 3 or each layer thereof may include, but are not particularly limited to, known film-forming methods such as vacuum deposition, spin coating, LB deposition, ink-jet printing, laser-printing, LITI, and the like.

The emission layer 4 may be arranged on the hole transport region 3. Details of the emission layer 4 may be the same as described above.

The electron transport region 5 may be arranged on the emission layer 4. The electron transport region 5 may include at least one of the electron injection layer 51, the electron transport layer 52, and the hole-blocking layer 53, but embodiments are not limited thereto.

The electron transport region 5 may be a single layer including a single material or a single layer including a plurality of different materials. For example, the electron transport region 5 may have a multi-layer structure including a plurality of layers including a plurality of different materials. The electron transport region 5 may have a single-layer structure including the electron injection layer 51 or the electron transport layer 52. The electron transport region 5 may have a single-layer structure including an electron injection material and an electron transport material. For example, the electron transport region 5 may have an electron transport layer 52/electron injection layer 51 structure, wherein constituting layers are sequentially stacked in the stated order from the emission layer 4. The electron transport region 5 may have a hole-blocking layer 53/electron transport layer 52/electron injection layer 51 structure, wherein constituting layers are sequentially stacked in the stated order from the emission layer 4. However, the structure of the electron transport region 5 is not limited to the above examples. The electron injection layer 51 or other layers constituting the electron transport region 5 are not particularly limited, and may include, for example, a known electron injection material. Examples of the electron injection material may include lithium quinolate (LiQ), Li₂O, BaO, a lanthanide metal such as Yb, a metal halide such LiF, NaCl, CsF, or RbCl, and the like. The electron injection layer 51 is not particularly limited, and may include, for example, an electron transport material and an insulating organic metal salt to be described below. The organic metal salt is not particularly limited, and may be, for example, a material having an energy band gap of 4 eV or more. Examples of the organic metal salt may include an acetate metal salt, a benzoate metal salt, an acetoacetate metal salt, an acetylacetonate metal salt, a stearate metal salt, and the like.

The electron transport layer 52 or other layers constituting the electron transport region 5 are not particularly limited, and may include, for example, a known electron transport material. Examples of the electron transport material may include an anthracene-based compound, tris(8-hydroxyquinolinolato)aluminum) (Alq₃), 1,3,5-tri[(3-pyridyl)-pen-3-yl] benzene, 2,4,6-tris(3′-pyridine-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benzo[d] imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinoline-10-olato) (Bebq₂), 9,10-di(naphthalene-2-yl)anthracene (ADN), lithium quinolate (LiQ), Compound ET1, Compound H91, and the like.

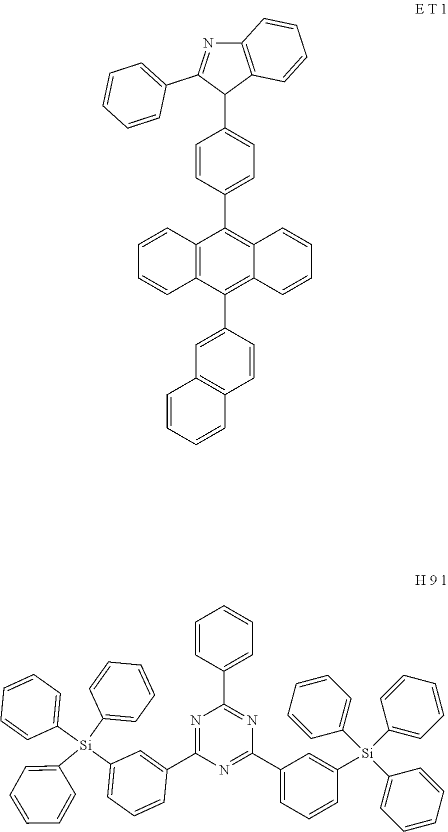 [SMILES: c1ccc(C2=Nc3ccccc3C2c2ccc(-c3c4ccccc4c(-c4ccc5ccccc5c4)c4ccccc34)cc2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

The hole-blocking layer 53 may prevent injection of holes from the hole transport region 3 to the electron transport region 5. Materials included in the hole-blocking layer 53 are not particularly limited, and materials used in a known hole-blocking layer may be used. The hole-blocking layer 53 may include, for example, a known hole-blocking material. Examples of the hole-blocking material may include 2,9-dimethyl-4,7-diphenyl-1,10-phenanthroline (BCP), 4,7-diphenyl-1,10-phenanthroline (BPhen), and the like. In addition, examples of the hole-blocking material may include the host materials included in the emission layer 4 and Compounds H-E1 and HT2 as host materials.

The thickness of the electron transport region 5 may be, but is not particularly limited to, about 0.1 nm to about 210 nm. The thickness of the electron transport region 5 may be about 30 nm to about 150 nm, or for example, about 100 nm to about 150 nm. For example, regarding each layer constituting the electron transport region 5, the thickness of the electron transport layer 52 may be, but is not particularly limited to, about 10 nm to about 100 nm, or for example, about 15 nm to about 50 nm. The thickness of the hole-blocking layer 53 may be, but is not particularly limited to, about 10 nm to about 100 nm, or for example, about 15 nm to about 50 nm. The thickness of the electron injection layer 51 may be, but is not particularly limited to, about 0.1 nm to about 10 nm, or for example, about 0.3 nm to about 9 nm. When the thickness of the electron injection layer 51 is within the above ranges, excellent electron injection characteristics may be obtained without a substantial increase in driving voltage. For example, when the thickness of the electron transport region 5, the electron injection layer 51, the electron transport layer 52, or the hole-blocking layer 53 is within the above ranges, excellent electron transport characteristics may be obtained without a substantial increase in driving voltage.

Examples of the film-forming method of the electron transport region 5 and each layer thereof may include, but are not particularly limited to, known film-forming methods such as vacuum deposition, spin coating, LB deposition, ink-jet printing, laser-printing, LITI, and the like.

The second electrode 6 may be arranged on the electron transport region 5. The second electrode 6 may have conductivity. In the organic EL device 10 according to an embodiment, the second electrode 6 may be a common electrode or a cathode. In addition, the second electrode 6 may be a transmissive electrode, a transflective electrode, or a reflective electrode.

A material for forming the second electrode 6 is not particularly limited, and an example thereof may be a metal, a metal alloy, or a conductive compound. When the second electrode 6 is a transmissive electrode, the second electrode 6 may include a transparent metal oxide, for example, ITO, IZO, ZnO, ITZO, or the like. When the second electrode 6 is a transflective electrode or a reflective electrode, the second electrode 6 may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg).

The second electrode 6 may be a single layer including a single material or a single layer including a plurality of different materials. For example, the second electrode 6 may have a multi-layer structure including a plurality of layers including a plurality of different materials.

The thickness of the second electrode 6 may be, but is not particularly limited to, about 10 nm to about 1,000 nm.

The second electrode 6 may be connected to an auxiliary electrode (not shown). When the second electrode 6 is connected to the auxiliary electrode, the resistance of the second electrode 6 may be reduced.

In addition, a capping layer (not shown) may be further arranged on the second electrode 6. The capping layer (not shown) is not particularly limited, and may include, for example, α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tri-9-carbazolyltriphenylamine (TCTA), N,N′-bis(naphthalene-1-yl), and the like.

In addition, materials constituting each layer and each electrode may be used alone or in combination of two or more.

In the organic EL device 10 of FIGS. 1 to 3, the condensed cyclic compound or the material for an organic EL device may be included in the emission layer 4, or may be included in an organic layer other than the emission layer 4. In addition, the condensed cyclic compound or the material for an organic EL device may be included in the emission layer 4 and an organic layer other than the emission layer 4.

In the organic EL device 10 of FIGS. 1 to 3, when a voltage is applied to each of the first electrode 2 and the second electrode 6, holes provided from the first electrode 2 may move toward the emission layer 4 through the hole transport region 3, and electrons provided from the second electrode 6 may move toward the emission layer 4 through the electron transport region 5. The holes and electrons may recombine in the emission layer 4 to produce excitons, and the excitons may transition from an excited state to a ground state to thereby generate light.

The disclosure includes the following aspects and embodiments.

1. A compound having a structure in which one or more polycyclic groups structure(s) represented by Formula 2 is connected to ring Ar¹ or ring Ar² in a structure represented by Formula 1, and
at least one group structure, but not more than four group structures, each represented by Formula 3 are added to at least one of ring Ar⁵ or ring Ar⁶ in the polycyclic group structure represented by Formula 2:

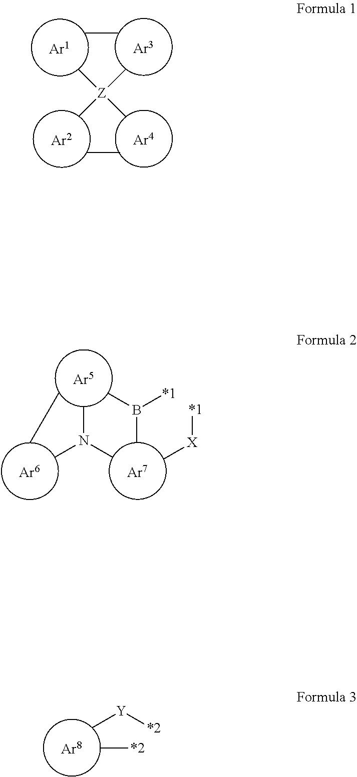

wherein, in Formulae 1,2, and 3, Ar¹ to Ar⁸ may each independently be a substituted or unsubstituted aromatic hydrocarbon ring having 6 to 30 ring-forming atoms or a substituted or unsubstituted heteroaromatic ring having 5 to 30 ring-forming atoms,
in Formula 1, Z may be C or Si,
in Formula 2, X may be —O—, —S—, —NR²¹—, or —CR²²R²³—, wherein R²¹, R²², and R²³ may each independently be hydrogen, deuterium, a substituted or unsubstituted alkyl group, a substituted or unsubstituted aryl group, or a substituted or unsubstituted heteroaryl group, wherein, if X is —NR²¹—, then R²¹ may be bonded to a ring-forming atom of Ar⁷,
in Formula 2, binding sites *1 are bonded to adjacent ring-forming atoms of Ar¹, or binding sites *1 are bonded to adjacent ring-forming atoms of Ar², in the structure represented by Formula 1 to form a six-membered ring, and
in Formula 3, Y may be —O—, —S—, or —NR³¹—, wherein R³¹ may be hydrogen, deuterium, a substituted or unsubstituted alkyl group, a substituted or unsubstituted aryl group, or a substituted or unsubstituted heteroaryl group, and binding sites *2 are bonded to adjacent two ring-forming atoms of Ar⁵, or binding sites *2 are bonded to adjacent ring-forming atoms of Ar⁶, in the structure represented by Formula 2 to form a five-membered ring.

2. The compound as described in 1., wherein the polycyclic group structure of Formula 2 is represented by Formula 4, and
at least one group structure, but not more than four group structures, each represented by Formula 5 are connected to at least one of ring Ar⁵′ or of ring Ar⁶ in the structure represented by Formula 4:

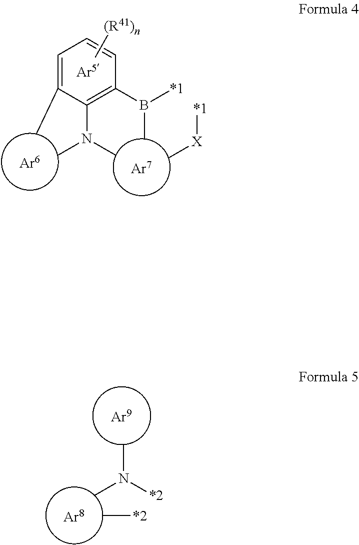

wherein, in Formula 4,
R⁴¹ may be deuterium, a substituted or unsubstituted alkyl group, a substituted or unsubstituted aryl group, or a substituted or unsubstituted heteroaryl group,
n may be 0, 1, 2, or 3, wherein, when n is 2 or more, two or more R⁴¹(s) may be identical to or different from each other, and
Ar⁶, Ar⁷, X, and a binding site *1 may each be the same as described in connection with Formula 2,
wherein, in Formula 5,
Ar⁹ may be a substituted or unsubstituted aromatic hydrocarbon ring having 6 to 30 ring-forming atoms or a substituted or unsubstituted heteroaromatic ring having 5 to 30 ring-forming atoms,
binding sites *2 are bonded to adjacent ring-forming atoms of Ar^{5′}, or binding sites *2 are bonded to adjacent ring-forming atoms of Ar⁶, in the structure represented by Formula 5, and
Ar⁸ may be the same as described in Formula 3.

3. The compound as described in 1, or 2., including a group structure represented by Formula 6 that connects to ring Ar¹ or ring Ar² in the structure represented by Formula 1:

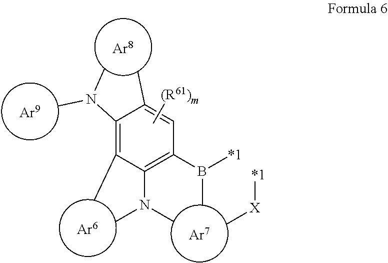

wherein, in Formula 6,
R⁶¹ may be deuterium, a substituted or unsubstituted alkyl group, a substituted or unsubstituted aryl group, or a substituted or unsubstituted heteroaryl group,
m may be 0 or 1,
Ar⁶, Ar⁷, X, and binding sites *1 are each be the same as described in Formula 2,
Ar⁸ may be the same as described in Formula 3, and
Ar⁹ may be the same as described in Formula 5.

4. The compound as described in 1, or 2., including a group structure represented by Formula 7 is connected to ring Ar¹ or ring Ar², in the structure represented by Formula 1:

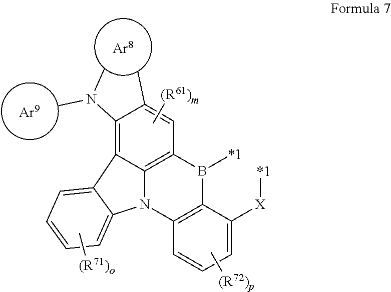

wherein, in Formula 7,
R⁷¹ and R⁷² may each independently be deuterium, a substituted or unsubstituted alkyl group, a substituted or unsubstituted aryl group, or a substituted or unsubstituted heteroaryl group,
o may be 0, 1, 2, 3, or 4, wherein, when o is 2 or more, two or more R⁷¹(s) may be identical to or different from each other,
p may be 0, 1, 2, or 3, wherein, when p is 2 or more, two or more R⁷²(s) may be identical to or different from each other,
X and a binding site *1 are as described in Formula 2,
Ar⁸ is as described in Formula 3,
Ar⁹ is as described in Formula 5, and
R⁶¹ and m are as described in Formula 6.

5. A composition including the compound as described in any one of 1. to 4.

6. The composition as described in 5., further including at least one of a TADF material and a phosphorescent material.

7. The composition as described in 6., wherein the phosphorescent material is a platinum complex.

8. A material for an organic EL device, the material including one or more compounds as described in any one of 1. to 4.

9. An organic EL device having an organic layer including one or more compounds as described in any one of 1. to 4.

10. The organic EL device as described in 9., wherein the organic layer is an emission layer.

### EXAMPLES

Hereinafter, the disclosure will be described in more detail with reference to the following examples and comparative examples, but the technical scope of the disclosure is not limited thereto.

### Synthesis of Compound 1

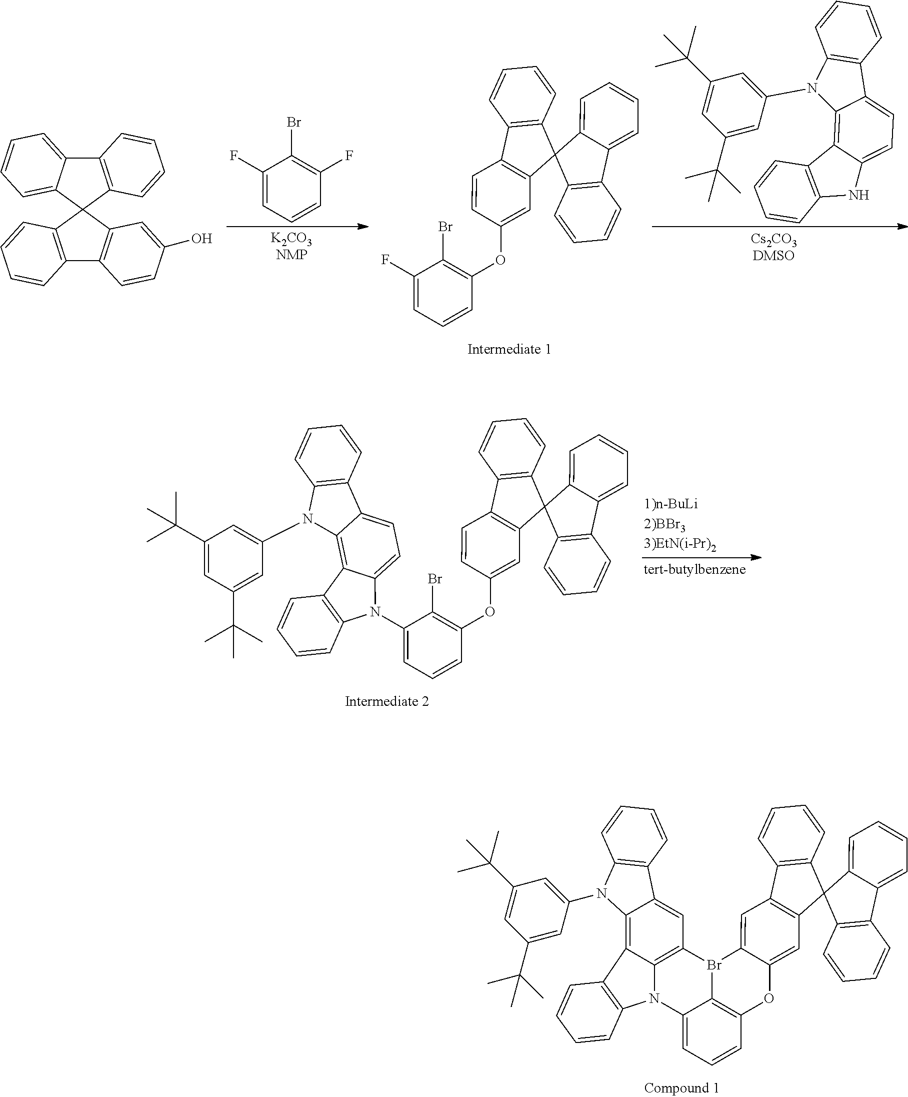

### Synthesis of Intermediate 1

3.6 g (10.83 mmol, 1.0 equiv.) of 2-hydroxy-9,9′-spirobi[9H-fluorene], 2.7 g (14.08 mmol, 1.3 equiv.) of 1-bromo-2,6-difluorobenzene, 1.5 g (10.83 mmol, 1.0 equiv.) of potassium carbonate, and 20 ml of 1-methyl-2-pyrrolidone were added to a reaction vessel, and the mixture stirred under reflux for 8 hours in a nitrogen atmosphere. After completion of the reaction, the reaction solution was diluted with toluene and filtered using Celite. The filtrate was concentrated and subjected to dispersion washing with methanol to obtain Intermediate 1 (amount: 3.94 g, yield: 72%).

### Synthesis of Intermediate 2

3.94 g (7.79 mmol, 1.05 equiv.) of Intermediate 1, 3.3 g (7.42 mmol, 1.0 equiv.) of 12-(3,5-di-tert-butylphenyl)-5,12-dihydroindolo[3,2-a] carbazole, 3.63 g (11.1 mmol, 1.5 equiv.) of cesium carbonate, and 8 ml of dimethyl sulfoxide were added to a reaction vessel, and the mixture was heated and stirred at 160° C. for 24 hours in a nitrogen atmosphere. After completion of the reaction, the reaction solution was diluted with toluene and filtered using Celite. After adding water to the filtrate, the resulting solution was separated, and an organic layer obtained therefrom was dried with magnesium sulfate and then concentrated. Purification of the concentrate was performed using column chromatography to obtain Intermediate 2 (amount: 3.0 g, yield: 43%).

### Synthesis of Compound 1

3.0 g (3.23 mmol, 1.0 equiv.) of Intermediate 2 and 16 ml of tert-butyl benzene were added to a reaction vessel, and the mixture was stirred. In a nitrogen atmosphere, the reaction solution was cooled to −50° C., 1.8 ml (4.8 mmol, 1.5 equiv.) of 2.6 M n-butyllithium hexane solution was added dropwise, followed by stirring for 1 hour. Then, 0.89 g (3.55 mmol, 1.1 equiv.) of boron tribromide was added, followed by stirring at 0° C. for 1 hour. Then, 0.84 g (2.0 equiv., 6.45 mmol) of N,N-diisopropylethylamine was added, followed by heating and stirring at 150° C. for 12 hours. After completion of the reaction, the reaction solution was cooled to room temperature, and an organic layer was extracted using water and dichloromethane. The organic layer was separated and dried with magnesium sulfate and then concentrated. Purification of the concentrate was performed using silica gel column chromatography to obtain Compound 1 (amount: 0.77 g, yield: 27%).

Structural identification of Compound 1 was performed using liquid chromatography mass spectrometry (LC/MS). In detail, the sample (Compound 1) was dissolved in tetrahydrofuran at a concentration of 0.1 wt %, and mass spectrometry was performed using an LC/MS measuring device 1260 Infinity-quadruple electrode 6100MS (manufactured by Agilent Technology Co., Ltd.). The obtained result value: LC-MS: 859 ([M+H]⁺).

### Synthesis of Compound 2

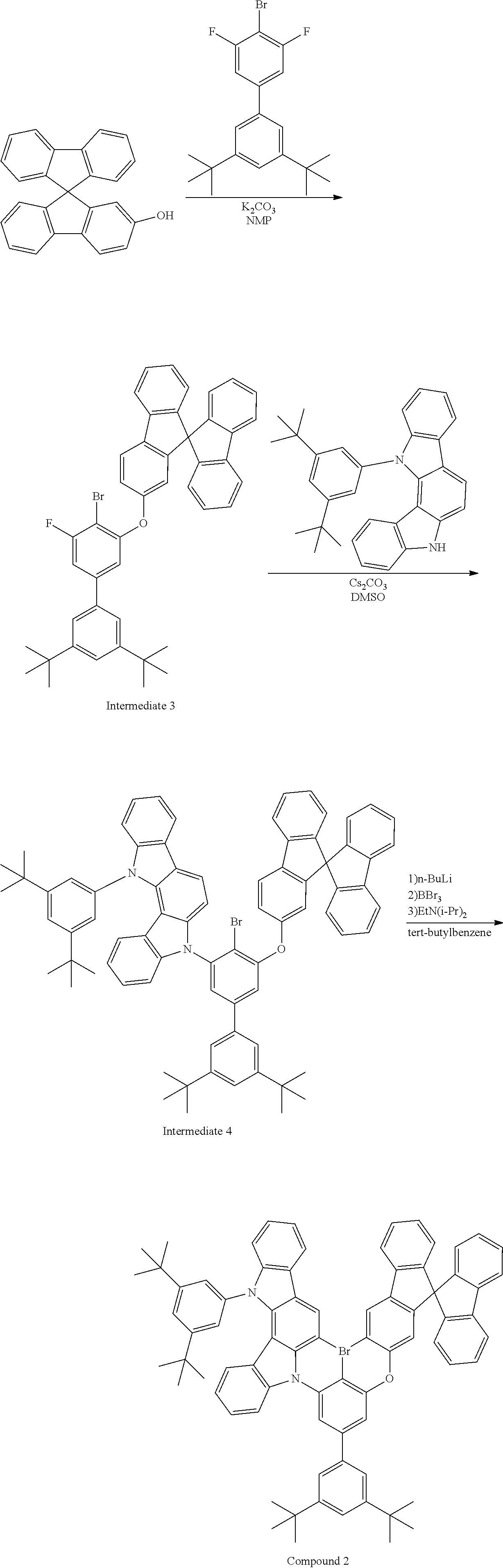

### Synthesis of Intermediate 3

Intermediate 3 was prepared in the same manner as in the synthesis of Intermediate 1, except that 1-bromo-2,6-difluorobenzene was changed to 4′-bromo-3′,5′-difluoro-3,5-ditertbutyl-1,1′-biphenyl (amount: 10.5 g, yield: 59%).

### Synthesis of Intermediate 4

Intermediate 4 was prepared in the same manner as in the synthesis of Intermediate 2, except that Intermediate 1 was changed to Intermediate 3 (amount: 6.8 g, yield: 42%).

### Synthesis of Compound 2

Compound 2 was prepared in the same manner as in synthesis of Compound 1, except that Intermediate 2 was changed to Intermediate 4 (amount: 0.8 g, yield: 12%). Structural identification of Compound 2 was performed in the same manner as that of Compound 1: LC-MS: 1048 ([M+H]⁺).

### Synthesis of Compound 3

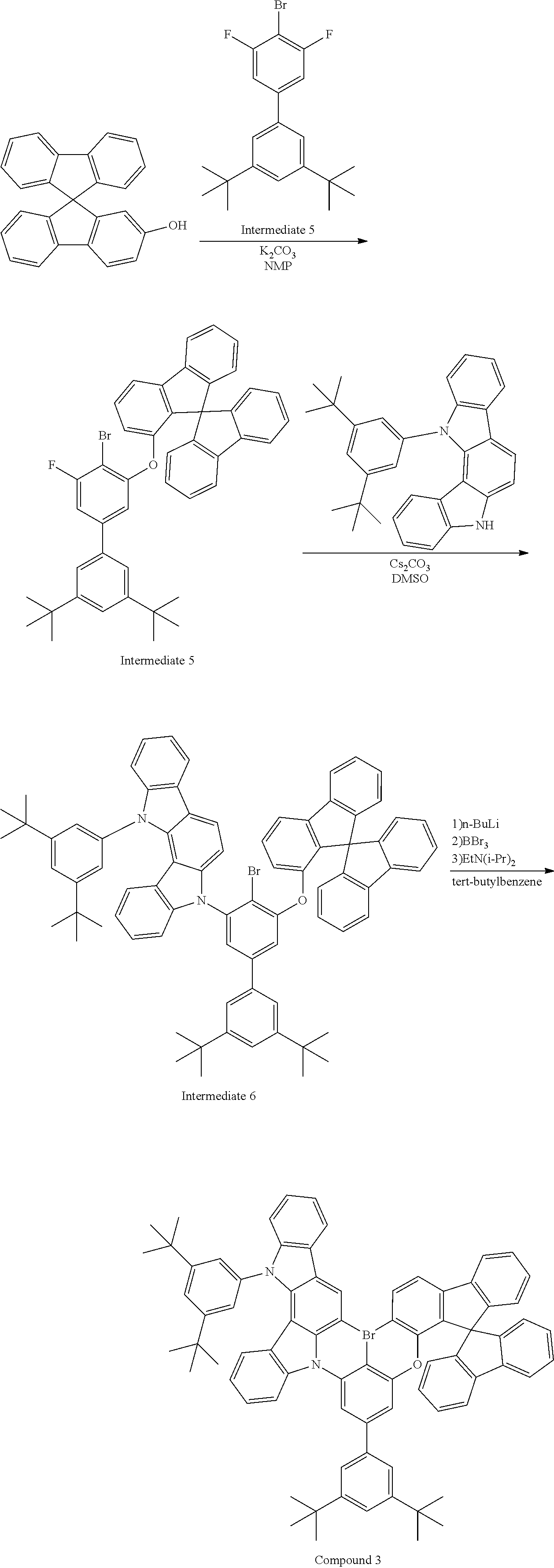

### Synthesis of Intermediate 5

Intermediate 5 was prepared in the same manner as in synthesis of Intermediate 1, except that 2-hydroxy-9,9′-spirobi[9H-fluorene] was changed to 1-hydroxy-9,9′-spirobi[9H-fluorene], and 1-bromo-2,6-difluorobenzene was changed to 4′-bromo-3′,5′-difluoro-3,5-ditertbutyl-1,1′-biphenyl (amount: 9.5 g, yield: 54%).

### Synthesis of Intermediate 6

Intermediate 6 was prepared in the same manner as in synthesis of Intermediate 2, except that Intermediate 1 was changed to Intermediate 5 (amount: 7.8 g, yield: 50%).

### Synthesis of Compound 3

Compound 3 was prepared in the same manner as in synthesis of Compound 1, except that Intermediate 2 was changed to Intermediate 6 (amount: 1.0 g, yield: 20%).

Structural identification of Compound 3 was performed in the same manner as that of Compound 1: LC-MS: 1048 ([M+H]⁺).

### Synthesis of Compound 4

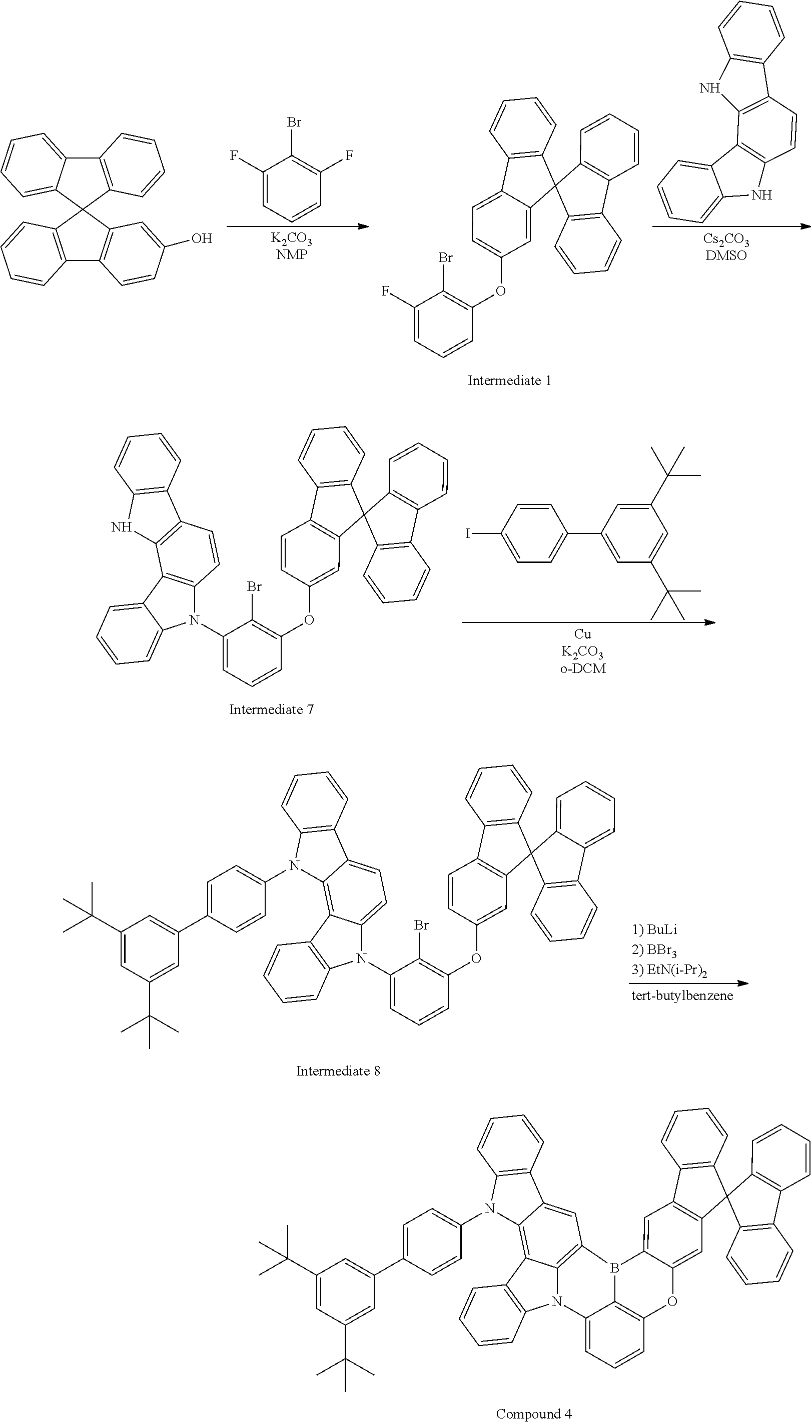

### Synthesis of Intermediate 7

15.0 g (29.7 mmol, 1.0 equiv.) of Intermediate 1, 9.1 g (35.6 mmol, 1.2 equiv.) of 5,12-dihydroindolo[3,2-a] carbazole, 14.5 g (44.5 mmol, 1.5 equiv.) of cesium carbonate, and 30 ml of dimethyl sulfoxide were added to a reaction vessel, and the mixture was heated and stirred at 160° C. for 30 hours in a nitrogen atmosphere. After completion of the reaction, the reaction solution was diluted with toluene and filtered using Celite. Water was added to the filtrate to extract an organic layer, and the separated organic layer was dried with magnesium sulfate and concentrated. Purification of the concentrate was performed using silica gel column chromatography to obtain Intermediate 7 (amount: 10.0 g, yield: 45%).

### Synthesis of Intermediate 8

5.0 g (6.7 mmol, 1.0 equiv.) of Intermediate 7, 3.4 g (8.8 mmol, 1.3 equiv.) of 3,5-di-tert-butyl-4′-iodo-1,1′-biphenyl, 2.8 g (20.2 mmol, 3.0 equiv.) of potassium carbonate, 0.214 mg (3.37 mmol, 0.5 equiv.) of copper powder, and 7 ml of o-dichlorobenzene were added to a reaction vessel, and the mixture was stirred under reflux for 24 hours in a nitrogen atmosphere. After completion of the reaction, the reaction solution was diluted with toluene and filtered using Celite. The filtrate was concentrated and purified by silica gel column chromatography to obtain Intermediate 8 (amount: 6.2 g, yield: 92%).

### Synthesis Compound 4

2.0 g (3.28 mmol, 1.0 equiv.) of Intermediate 8 and 2.5 mol of tert-butyl benzene were added to a reaction vessel, and the mixture was stirred. In a nitrogen atmosphere, the reaction solution was cooled to −50° C., 0.7 ml (1.1 mmol, 2.2 equiv.) of 1.6 M tert-butyllithium pentane solution was added dropwise, followed by stirring at room temperature (25° C.) for 1 hour. The materials with low boiling points were removed by distillation. The resulting solution was cooled to 0° C., 0.05 ml (0.6 mmol, 1.1 equiv.) of boron tribromide was added, followed by stirring at room temperature (25° C.) for 1 hour. Then, 0.17 ml (1.0 mmol, 2.0 equiv.) of N,N-diisopropylethylamine was added, followed by heating and stirring at 150° C. for 20 hours. After completion of the reaction, the reaction solution was cooled to room temperature, and an organic layer was extracted using water and toluene. The organic layer was separated and dried with magnesium sulfate and concentrated. Purification of the concentrate was performed using silica gel column chromatography to obtain Compound 4 (amount: 0.13 g, yield: 28%). Structural identification of Compound 4 was performed in the same manner as that of Compound 1: LC-MS: 936 ([M+H]⁺).

### Simulation Evaluation of Condensed Cyclic Compound

According to “High-Performance Dibenzoheteraborin-Based Thermally Activated Delayed Fluorescence Emitters: Molecular Architectonics for Concurrently Achieving Narrowband Emission and Efficient Triplet-Singlet Spin Conversion,” In Seob Park, et al. in, Advanced Functional Materials 2018, 28, 1802031, the spectrum width of fluorescence (the FWHM of the fluorescence spectrum peak) has a close relationship with the reorganization energy [E(S₀@S₁)-E(S₀@S₀)] that is expressed by the difference between the ground state (S₀) energy of the stable structure in the first excitation singlet state (S₁) [E(S₀@S₁)] and the ground state (S₀) energy of the stable structure in the ground state (S₀) [E(S₀@S₀)].

### Calculation of Oscillator Strength f, Reorganization Energy, and Fluorescence Wavelength of Compounds of Disclosure and Comparative Compound R1

For the compounds described herein and the Cyclic Compound R1 (Comparative Compound 1) known in the art, the following calculations were performed according to DFT. The oscillator strength f, reorganization energy, and fluorescence wavelength of Compounds 1 to 3 and Comparative Compound 1 were calculated.

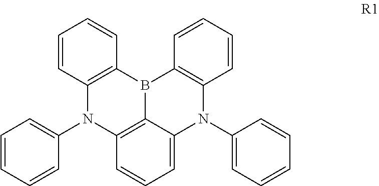 [SMILES: c1ccc(N2c3ccccc3B3c4ccccc4N(c4ccccc4)c4cccc2c43)cc1]

The ground state (S₀) energy of the stable structure in the first excitation singlet state (S₁) [E(S₀@S₁)] and the ground state (S₀) energy of the stable structure in the ground state (S₀) [E(S₀@S₀)] were calculated, and from the difference, the reorganization energy [E(S₀@S₁)]-[E(S₀@S₀)](eV) was calculated.

In addition, the first excitation singlet state (S₁) energy of the stable structure in the first excitation singlet state (S₁) [E(S₁@S₁)] was calculated, and from the difference between this value and the ground state (S₀) energy of the stable structure in the ground state (S₀) [E(S₀@S₀)], the adiabatic first excitation singlet state (S₁) energy [E(S₁@S₁)]-[E(S₀@S₀)](eV) was calculated.

The fluorescence wavelength (nm) obtained by converting the adiabatic first excitation singlet state (S₁) energy into a light wavelength (nm) was determined. In addition, the oscillator strength f of the stable structure in the first excitation singlet state (S₁) was determined.

The DFT calculations were performed using Gaussian 16 (Gaussian Inc.) as calculation software, according to the following calculation methods (I), (II), and (III):
(I) S₀ calculation method: structural optimization calculation by DFT including functional B3LYP, basis function 6-31G(d, p), and toluene solvent effect (PCM);
(II) S₁ calculation method: structural optimization calculation by time-dependent DFT (TDDFT) including functional B3LYP, basis function 6-31 G(d, p), and toluene solvent effect (PCM); and
(III) S₀ calculation method: calculation on input structure by DFT including functional B3LYP, basis function 6-31G(d, p), and toluene solvent effect (PCM).

In detail, the calculation of each item was performed using the following calculation methods:
Ground state (S₀) energy of stable structure in ground state (S₀) [E(S₀@S₀)]: Calculation method (I);
First excitation singlet state (S₁) energy of stable structure in first excitation singlet state (S₁) [E(S₁@S₁)]: Calculation method (II);
Ground state (S₀) energy of stable structure in first excitation singlet state (S₁) [E(S₀@S₁)]: Calculation methods (II) and (III);
Reorganization energy [E(S₀@S)]-[E(S₀@S₀)]: Calculation methods (I), (II), and (III);
Adiabatic first excitation singlet state (S₁) energy [E(S₁@S₁)]-[E(S₀@S₀)]: Calculation methods (I) and (II);
(Fluorescence wavelength (nm): Calculation methods (I) and (II); and
Oscillator strength f of stable structure in first excitation singlet state (S₁): Calculation method (II).

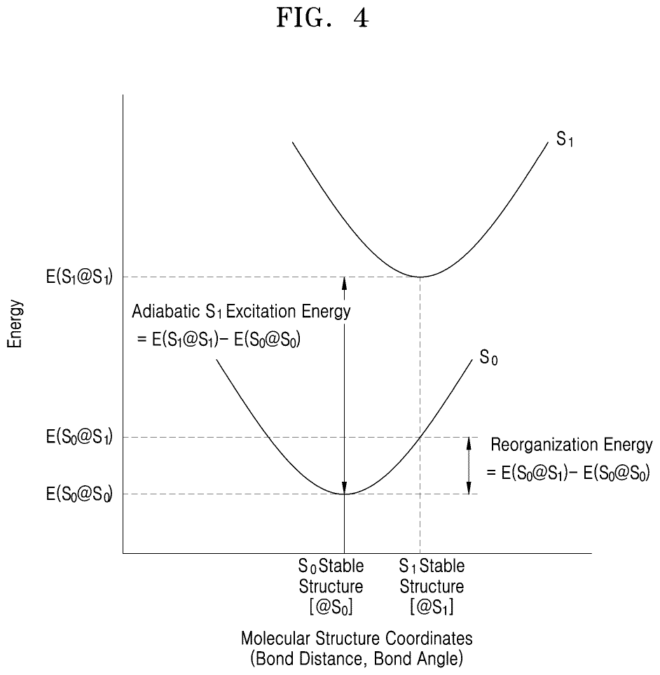

FIG. 4 is an explanatory diagram qualitatively illustrating each energy relationship. The calculation results are shown in Table 1.

TABLE 1

| | Calculation by DFT | | |
|---|---|---|---|
| | Oscillator | Reorganization | Fluorescence |
| Compound | strength f | energy (eV) | wavelength (nm) |
| Compound 1 | 0.56 | 0.05 | 434 |
| Compound 2 | 0.54 | 0.06 | 440 |
| Compound 3 | 0.51 | 0.09 | 441 |
| Compound 4 | 0.59 | 0.05 | 434 |
| Compound 5 | 0.43 | 0.08 | 442 |
| Compound 6 | 0.43 | 0.08 | 446 |
| Compound 7 | 0.48 | 0.10 | 453 |
| Compound 8 | 0.48 | 0.11 | 453 |
| Compound 9 | 0.47 | 0.05 | 438 |
| Compound 10 | 0.51 | 0.05 | 433 |
| Compound 11 | 0.48 | 0.07 | 436 |
| Compound 12 | 0.53 | 0.07 | 432 |
| Compound 13 | 0.45 | 0.06 | 428 |
| Compound 14 | 0.51 | 0.06 | 424 |
| Compound 18 | 0.55 | 0.11 | 451 |
| Compound 20 | 0.56 | 0.05 | 434 |
| Compound 26 | 0.48 | 0.08 | 427 |
| Compound 27 | 0.56 | 0.09 | 434 |
| Compound 28 | 0.31 | 0.11 | 437 |
| Compound 31 | 0.37 | 0.07 | 433 |
| Compound 32 | 0.35 | 0.08 | 434 |
| Compound 33 | 0.40 | 0.06 | 426 |
| Compound 34 | 0.48 | 0.07 | 441 |
| Compound 28 | 0.42 | 0.07 | 441 |
| Compound 37 | 0.29 | 0.11 | 422 |
| Compound 38 | 0.60 | 0.07 | 442 |
| Compound 39 | 0.59 | 0.07 | 448 |
| Compound 42 | 0.50 | 0.08 | 441 |
| Compound 43 | 0.32 | 0.11 | 437 |
| Compound 44 | 0.33 | 0.11 | 436 |
| Compound 45 | 0.34 | 0.10 | 437 |
| Compound 46 | 0.34 | 0.10 | 436 |
| Compound 48 | 0.51 | 0.09 | 438 |
| Compound 49 | 0.39 | 0.06 | 434 |
| Compound 50 | 0.55 | 0.06 | 440 |
| Compound 51 | 0.38 | 0.06 | 434 |
| Compound 52 | 0.41 | 0.06 | 433 |
| Compound 53 | 0.40 | 0.06 | 433 |
| Compound 54 | 0.35 | 0.08 | 434 |
| Compound 55 | 0.38 | 0.07 | 434 |
| Compound 56 | 0.51 | 0.05 | 434 |
| Compound 57 | 0.53 | 0.09 | 438 |
| Compound 58 | 0.54 | 0.05 | 435 |
| Compound 59 | 0.59 | 0.05 | 434 |
| Compound 60 | 0.58 | 0.05 | 433 |
| Compound 61 | 0.56 | 0.05 | 438 |
| Compound 62 | 0.41 | 0.06 | 430 |
| Compound 63 | 0.41 | 0.06 | 430 |
| Compound 64 | 0.42 | 0.06 | 426 |
| Compound 65 | 0.43 | 0.06 | 426 |
| Compound 66 | 0.43 | 0.06 | 426 |
| Compound 67 | 0.42 | 0.06 | 430 |
| Compound 68 | 0.40 | 0.06 | 431 |
| Compound 69 | 0.54 | 0.06 | 437 |
| Compound 70 | 0.44 | 0.05 | 429 |
| Compound 71 | 0.41 | 0.06 | 429 |
| Compound 72 | 0.47 | 0.08 | 427 |
| Compound 73 | 0.51 | 0.09 | 442 |
| Compound 74 | 0.51 | 0.09 | 442 |
| Compound 75 | 0.52 | 0.09 | 438 |
| Compound 76 | 0.43 | 0.11 | 435 |
| Compound 77 | 0.43 | 0.10 | 435 |
| Compound 78 | 0.45 | 0.08 | 429 |
| Compound 79 | 0.37 | 0.06 | 435 |
| Compound 80 | 0.37 | 0.06 | 432 |
| Compound 81 | 0.38 | 0.07 | 434 |
| Compound 82 | 0.38 | 0.07 | 437 |
| Compound 86 | 0.54 | 0.06 | 432 |
| Compound 87 | 0.52 | 0.07 | 432 |
| Compound 88 | 0.53 | 0.07 | 432 |
| Compound 89 | 0.51 | 0.06 | 448 |
| Compound 90 | 0.50 | 0.05 | 448 |
| Compound 91 | 0.61 | 0.06 | 449 |
| Compound 92 | 0.64 | 0.05 | 448 |
| Compound 93 | 0.63 | 0.05 | 448 |
| Compound 94 | 0.64 | 0.05 | 452 |
| Compound 95 | 0.63 | 0.05 | 452 |
| Compound 99 | 0.47 | 0.06 | 451 |
| Compound 101 | 0.55 | 0.06 | 448 |
| Compound 102 | 0.58 | 0.06 | 448 |
| Compound 103 | 0.56 | 0.06 | 447 |
| Compound 104 | 0.55 | 0.06 | 442 |
| Compound 105 | 0.54 | 0.06 | 442 |
| Compound 106 | 0.56 | 0.06 | 444 |
| Compound 107 | 0.56 | 0.05 | 444 |
| Comparative | 0.21 | 0.11 | 415 |
| Compound 1 | | | |

As shown in Table 1, the maximum reorganization energy value of the condensed cyclic compounds of listed in Table 1 was 0.11 eV (e.g., see Compounds 8, 18, 28, 37, 43, 44, and 76, each of which has the same calculated value as that of Comparative Compound 1), however, most of the condensed cyclic compounds of Table 1 each have a calculated reorganization energy value that is less than that of Comparative Compound 1.

Accordingly, a person of ordinary skill would expect that the condensed cyclic compounds described herein would have an FWHM equal to or less than that of Comparative Compound 1, and therefore, each compound will have a color purity equal to or higher than that of Comparative Compound 1.

In addition, it was confirmed that the condensed cyclic compounds each have oscillator strength f of sufficient magnitude and excellent fluorescence efficiency.

From the above results, it was confirmed that the compounds each have small reorganization energy, large oscillator strength f, and a suitable blue fluorescence wavelength, as compared with Comparative Compound 1. Accordingly, it was confirmed that the compounds each had a narrow emission spectrum width, and thus may each serve as a blue luminescent material capable of realizing high color purity and improving the luminescence efficiency of an organic EL device.

### Evaluation of Compound

### Method of Preparing Thin Film

Compounds 1 to 3 or Comparative Compound 1 were co-deposited on a quartz substrate at a weight ratio of 1 wt % with respect to a host compound at a vacuum pressure of 10-5 Pa to prepare a thin film (hereinafter, also referred to as “host dispersion film”) having a thickness of 50 nm. Compound HT1 and Compound HT2 were used as host compounds and Pt1 was used as a phosphorescent complex, and the weight ratio of Compound HT1:Compound HT2:Phosphorescent Complex Pt1 was 60:40:13. In addition, the structures of Compounds HT1 and HT2 and Phosphorescent Complex Pt1 are as follows.

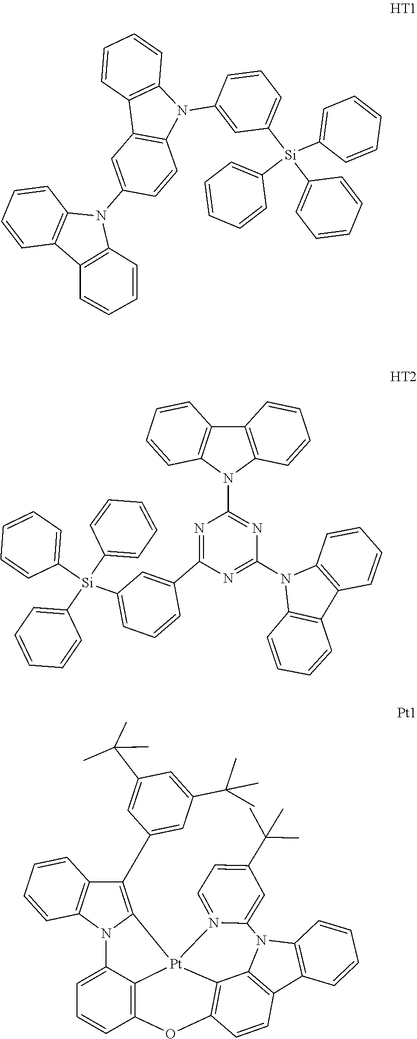

### Measurement of PL (FWHM)

The thin film (host dispersion film) prepared above was cut into a strip having a width of 6 nm, and PL measurement was performed at room temperature by using a spectrofluorometer F-7000 manufactured by Hitachi High-Tech Co., Ltd. From the obtained emission spectrum, the peak wavelength (maximum emission wavelength) and the wavelength width at (FWHM) were determined. The evaluation results are shown in Table 2.

### Measurement of PL Quantum Yield (PLQY)

For the thin film (host dispersion film) prepared above, the PLQY was measured using a Quantaurus-QY absolute PLQY measuring device C11347-01 manufactured by Hamamatsu Photonics Co., Ltd. In the measurement, the excitation wavelength was scanned at intervals of 10 nm from 280 nm to 350 nm, and the excitation wavelength region in which the compound absorption value showed 20% or more of the excitation light intensity ratio was adopted. The value of PLQY was the highest value in the adopted excitation wavelength region. The evaluation results are shown in Table 2.

TABLE 2

| Compound | Peak wavelength (nm) | PLQY | FWHM (nm) |
|---|---|---|---|
| Compound 1 | 461 | 0.88 | 22 |
| Compound 2 | 466 | 0.93 | 22 |
| Compound 3 | 464 | 0.90 | 23 |
| Comparative | 460 | 0.74 | 26 |
| Compound 1 (R1) | | | |

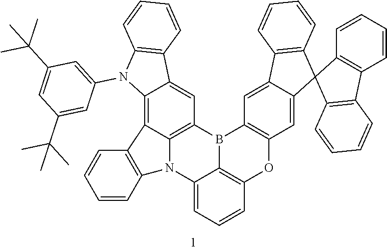 [SMILES: CC(C)(C)c1cc(-n2c3ccccc3c3cc4c5c(c6ccccc6n5-c5cccc6c5B4c4cc5c(cc4O6)C4(c6ccccc6-c6ccccc64)c4ccccc4-5)c32)cc(C(C)(C)C)c1]

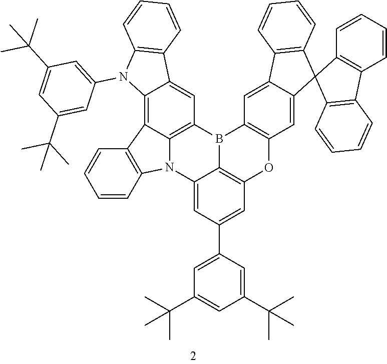 [SMILES: CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2cc4c(cc2O3)C2(c3ccccc3-c3ccccc32)c2ccccc2-4)cc(C(C)(C)C)c1]

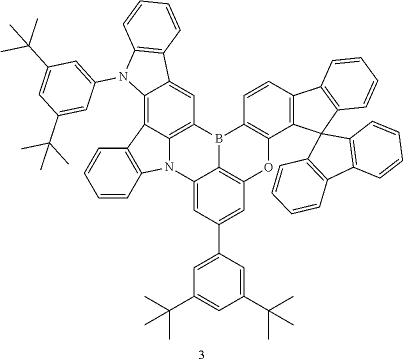 [SMILES: CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2ccc4c(c2O3)C2(c3ccccc3-c3ccccc32)c2ccccc2-4)cc(C(C)(C)C)c1]

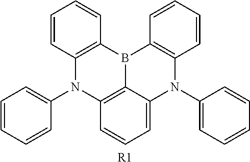

From the results of Table 2, it was confirmed that Compounds 1, 2, and 3 each exhibit a narrow emission spectrum with a blue wavelength as the peak wavelength. Moreover, Compounds 1, 2 and 3 each exhibits a lower FWHM than Comparative Compound 1 and thereby achieves blue luminescence with high color purity. In addition, it was confirmed that Compounds 1, 2, and 3 each exhibit a higher PLQY than Comparative Compound 1.

### Manufacture of Organic EL Device

### Device Manufacturing Example 1

An ITO glass substrate on which an electrode pattern was formed was cut to a size of 50 mm×50 mm×0.7 mm, sonicated in acetone, isopropyl alcohol, and pure water, in the stated order, each for 15 minutes, and then cleaned by exposure to UV ozone for 30 minutes. The following layers were deposited on the ITO electrode (anode) of the glass substrate by using a vacuum deposition apparatus.

First, HAT-CN (see the formula below) was deposited on the ITO electrode to form a hole injection layer having a thickness of 10 nm. Compound HT3 (see the formula below) was deposited on the hole injection layer to form a hole transport layer having a thickness of 140 nm. Compound HT1 (see the formula below) was deposited on the hole transport layer to form an electron-blocking layer having a thickness of 5 nm. As a result, a hole transport region was formed.

Compound HT1, Compound HT2, Phosphorescent Complex Pt1 (see the formulae below) and Compound 1 obtained above were co-deposited on the hole transport region formed above to form an emission layer having a thickness of 40 nm. The formation of the emission layer was performed such that the weight ratio of Compound HT1, Compound HT2, and Phosphorescent Complex Pt1 in the emission layer was Compound HT1:Compound HT2:Phosphorescent Complex Pt1=60:40:13. In addition, the formation of the emission layer was performed such that the concentration of Compound 1 was 1.0 wt % based on the total weight of Compound HT1, Compound HT2, Phosphorescent Complex Pt1, and Compound 1 (that is, the total weight of the emission layer). In addition, Compounds HT1 and HT2 are host materials.

Compound HT2 was vacuum-deposited on the emission layer obtained above to form a hole-blocking layer having a thickness of 5 nm. Compound H91 and LiQ were co-deposited on the hole-blocking layer at a weight ratio of Compound H91:LiQ=5:5 (unit: parts by weight) to form an electron transport layer having a thickness of 30 nm. LiQ was deposited on the electron transport layer to form an electron injection layer having a thickness of 1 nm. As a result, an electron transport region was formed.

Al (cathode) was deposited on the electron injection layer to a thickness of 100 nm to thereby manufacture Organic EL Device 1.

In a glove box of a nitrogen atmosphere with water concentration of 1 ppm or less and oxygen concentration of 1 ppm or less, a glass sealing tube with a desiccating agent and an ultraviolet curing resin (manufactured by MORESCO Co., Ltd., product name WB90US) were used to seal Organic EL Device 1 manufactured above.

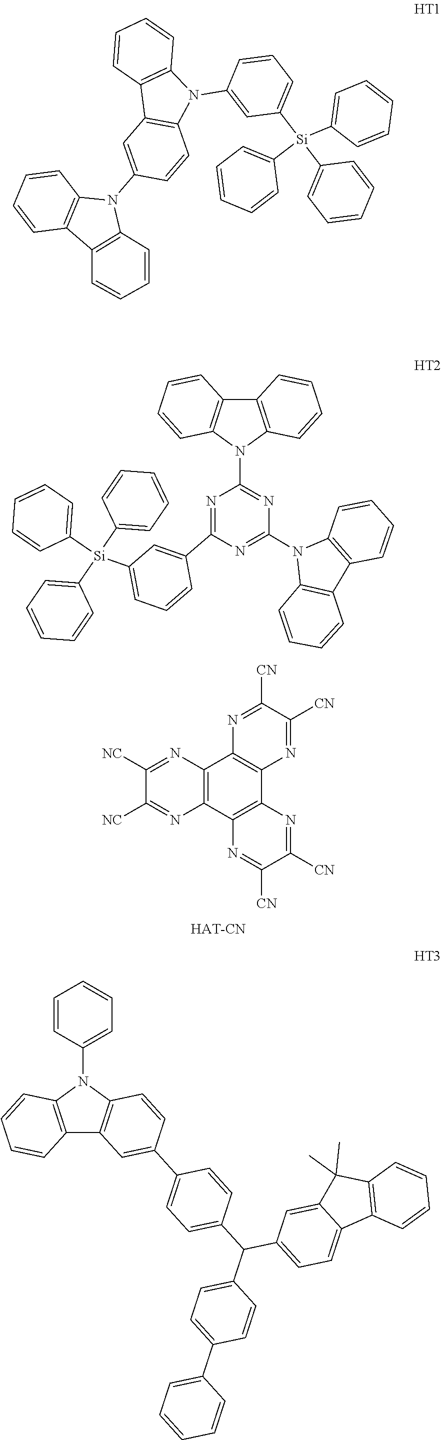

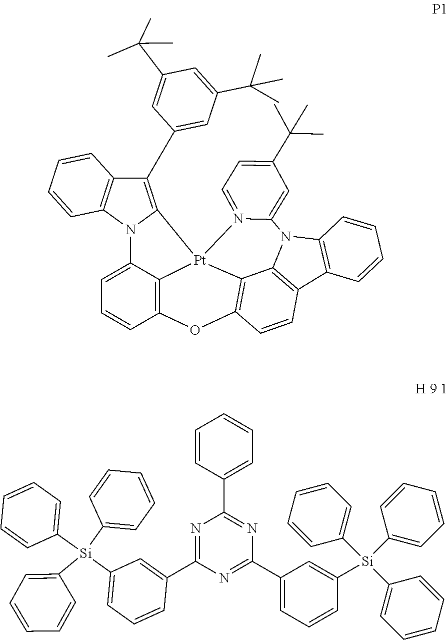

### Device Manufacturing Example 2

Organic EL Device 2 was manufactured in the same manner as in Device Manufacturing Example 1, except that, in the formation of the emission layer Compound 2 was used instead of Compound 1. The device was sealed as described above to complete the manufacture of Organic EL Device 2.

### Device Manufacturing Example 3

Organic EL Device 3 was manufactured in the same manner as in Device Manufacturing Example 1, except that, in the formation of the emission layer Compound 3 was used instead of Compound 1. The device was sealed to complete the manufacture of Organic EL Device 3.

### Comparative Device Manufacturing Example 1

Comparative Organic EL Device 1 was manufactured in the same manner as in Device Manufacturing Example 1, except that, in the formation of the emission layer Comparative Compound 1 was used instead of Compound 1. The device was sealed to complete the manufacture of Comparative Organic EL Device 1.

### Evaluation of Organic EL Device

### Luminance, External Quantum Efficiency (EQE), and Device Lifespan

The emission peak wavelength at the luminance of 1,000 candela per square meter (cd/m²), emission spectrum width, EQE, and device lifespan were evaluated according to the following method.

The organic EL device was allowed to emit light while the voltage applied to the device was varied using a DC constant voltage power supply (source meter 2400 manufactured by KEITHLEY), and the luminance, emission spectrum, and luminescence amount at this time were measured using a luminance meter (SR-3 manufactured by Topcon).

The EQE was calculated from the emission spectrum, luminance, and current value at the time of measurement. The EQE at the luminance of 1,000 cd/m² was defined as EQE [%].

In addition, the device lifespan (durability) was defined as LT₉₅ by measuring the amount of time taken for the emission luminance to decay to 95% of the initial luminance as the device is driven on a current value having an initial luminance of 1,000 cd/m². In addition, the LT₉₅ in Table 3 is a relative (normalized) value and corresponds to the LT₉₅ (unit: hr) of Comparative Organic EL Device 1 set to 1.

### Emission Peak Wavelength and Emission Spectrum Width (FWHM, FWQM)

The emission peak wavelength and the emission spectrum width were obtained from measuring the emission spectrum. The wavelength representing the maximum value of the emission spectrum was defined as the emission peak wavelength, the wavelength width corresponding to half of the maximum value was defined as FWHM, and the wavelength width corresponding to ¼ (quarter) of the maximum value was defined as FWQM.

In addition, in this evaluation, the emission peak wavelength is not particularly limited, but may be within a blue emission region, and may be 455 nm to 475 nm, or for example, 455 nm to 465 nm.

In this evaluation, the emission spectrum width (FWHM and FWQM) may be smaller, and it is generally accepted by those in the art that the smaller the emission spectrum width the higher the color purity. The evaluation results of each organic EL device are shown in Table 3.

TABLE 3

| Device | EML | Emission peak | FWHM | FWQM | EQE | LT₉₅ |
|---|---|---|---|---|---|---|
| No. | compound | wavelength (nm) | (nm) | (nm) | (%) | (relative value) |
| Organic EL Device 1 | Compound 1 | 461 | 23 | 49 | 17.0 | 2.2 |
| Organic EL Device 2 | Compound 2 | 465 | 23 | 42 | 19.5 | 4.0 |
| Organic EL Device 3 | Compound 3 | 464 | 24 | 44 | 18.6 | 3.1 |
| Comparative | Comparative | 461 | 25 | 54 | 14.0 | 1.0 |
| Organic EL Device 1 | Compound 1 | | | | | |

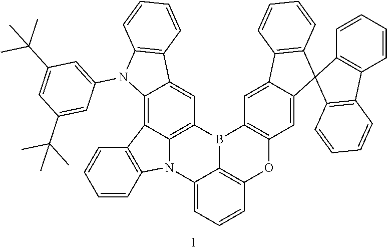 [SMILES: CC(C)(C)c1cc(-n2c3ccccc3c3cc4c5c(c6ccccc6n5-c5cccc6c5B4c4cc5c(cc4O6)C4(c6ccccc6-c6ccccc64)c4ccccc4-5)c32)cc(C(C)(C)C)c1]

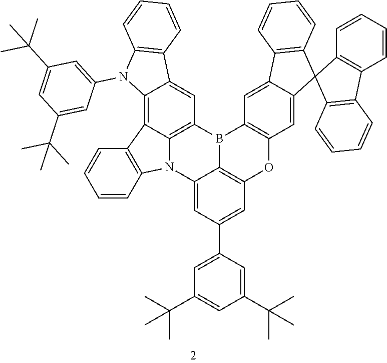 [SMILES: CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2cc4c(cc2O3)C2(c3ccccc3-c3ccccc32)c2ccccc2-4)cc(C(C)(C)C)c1]

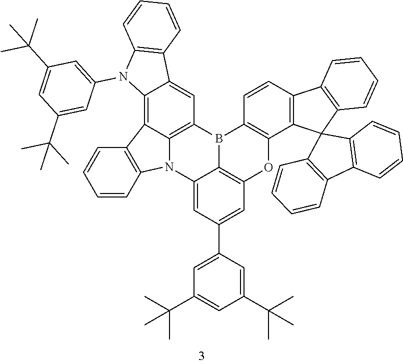 [SMILES: CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2ccc4c(c2O3)C2(c3ccccc3-c3ccccc32)c2ccccc2-4)cc(C(C)(C)C)c1]

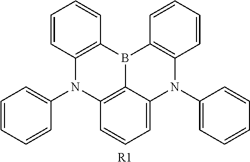

From the results of Table 3, it was confirmed that Organic EL Devices 1, 2, and 3 using Compounds 1, 2, and 3, respectively, each exhibit blue luminescence with reduced FWHM and FWQM, i.e., a more narrow peal emission, and therefore, relatively high color purity, as compared to Comparative Organic EL Device 1. In addition, it was confirmed that because Compounds 1, 2, and 3 each exhibit a relatively greater EQE, Organic EL Devices 1 and 2 each had excellent luminescence efficiency and device lifespan. In particular, it was confirmed that Organic EL Device 2 with Compound 2 had an EQE improved by 1.3 times and a lifespan improved by 4 times, as compared with Comparative Organic EL Device 1.

By using the compounds described and claimed herein as a luminescent material, a blue EL device having a more narrow peak emission, higher efficiency, and a longer lifespan can be achieved in comparison to a similar designed device with the exception of using a known luminescent material For example, a device with an emission wavelength of 465 nm or less, relatively higher color purity, greater EQE, and/or greater device lifetime may be obtained.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A compound comprising:
a polycyclic group structure represented by Formula 2 connected to at least one of ring Ar¹ or ring Ar² of a structure represented by Formula 1; and
at least one group structure, but not more than four group structures, each represented by Formula 3 connected to at least one of ring Ar⁵ or ring Ar⁶ of the polycyclic group structure represented by Formula 2: 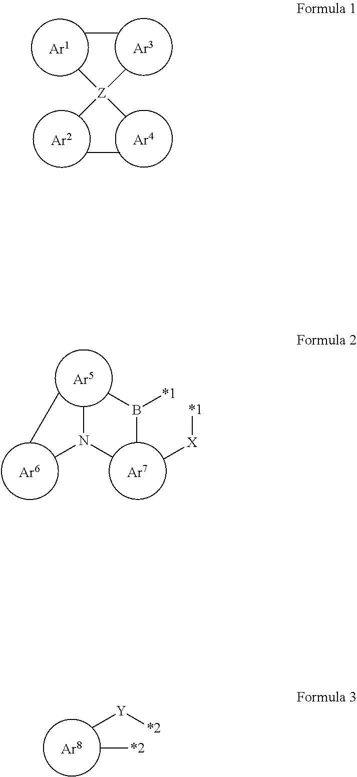
wherein, in Formulae 1, 2, and 3,
Ar¹ to Ar⁸ are each independently a substituted or unsubstituted aromatic hydrocarbon ring having 6 to 30 ring-forming atoms, or a substituted or unsubstituted heteroaromatic ring having 5 to 30 ring-forming atoms,
in Formula 1, Z is C or Si,
in Formula 2, X is —O—, —S—, —NR²¹—, or —CR²²R²³—,
R²¹, R²², and R²³ are each independently hydrogen, deuterium, a substituted or unsubstituted alkyl group, a substituted or unsubstituted aryl group, or a substituted or unsubstituted heteroaryl group,
wherein if X is —NR²¹—, then R²¹ is bonded to a ring-forming atom of Ar⁷, and
binding sites *1 are bonded to adjacent ring-forming atoms of Ar¹, or binding sites *1 are bonded to adjacent ring-forming atoms of Ar², in the structure represented by Formula 1 to form a six-membered ring, and
in Formula 3, Y is —O—, —S—, or —NR³¹—,
R³¹ is hydrogen, deuterium, a substituted or unsubstituted alkyl group, a substituted or unsubstituted aryl group, or a substituted or unsubstituted heteroaryl group, and
binding sites *2 are bonded to adjacent ring-forming atoms of Ar⁵, or binding sites *2 are bonded to adjacent ring-forming atoms of Ar⁶, in the polycyclic structure represented by Formula 2 to form a five-membered ring.

2. The compound of claim 1, comprising the group structure represented by Formula 3 is connected to the ring Ar⁵, and X is O or —NR²¹.

3. The compound of claim 1, wherein, in Formula 1, Ar¹ to Ar⁴ are each independently selected from:
a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, or a pyranthrene ring, each of which is unsubstituted; and
a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, or a pyranthrene ring, each of which is substituted with a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, a substituted or unsubstituted arylheteroarylamino group, or a combination thereof,
wherein the substituents of the substituted alkyl group, the substituted aryl group, the substituted heteroaryl group, the substituted alkoxy group, the substituted aryloxy group, the substituted heteroaryloxy group, the substituted diarylamino group, the substituted diheteroarylamino group, and the substituted arylheteroarylamino group, are each independently selected from a deuterium atom, a halogen atom, an unsubstituted alkyl group, an unsubstituted aryl group, an unsubstituted heteroaryl group, an unsubstituted alkoxy group, an unsubstituted aryloxy group, an unsubstituted heteroaryloxy group, an unsubstituted diarylamino group, an unsubstituted diheteroarylamino group, or an unsubstituted arylheteroarylamino group.

4. The compound of claim 3, wherein, in Formula 1, Ar¹ and Ar² are each independently selected from:
a benzene ring; and
a benzene ring substituted with a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, a substituted or unsubstituted arylheteroarylamino group, or a combination thereof,
wherein the substituents of the substituted alkyl group, the substituted aryl group, the substituted heteroaryl group, the substituted alkoxy group, the substituted aryloxy group, the substituted heteroaryloxy group, the substituted diarylamino group, the substituted diheteroarylamino group, and the substituted arylheteroarylamino group, are each independently selected from a deuterium atom, a halogen atom, an unsubstituted alkyl group, an unsubstituted aryl group, an unsubstituted heteroaryl group, an unsubstituted alkoxy group, an unsubstituted aryloxy group, an unsubstituted heteroaryloxy group, an unsubstituted diarylamino group, an unsubstituted diheteroarylamino group, and an unsubstituted arylheteroarylamino group.

5. The compound of claim 1, wherein the structure of Formula 1 is represented by one of Formulae 1-1 to 1-6: 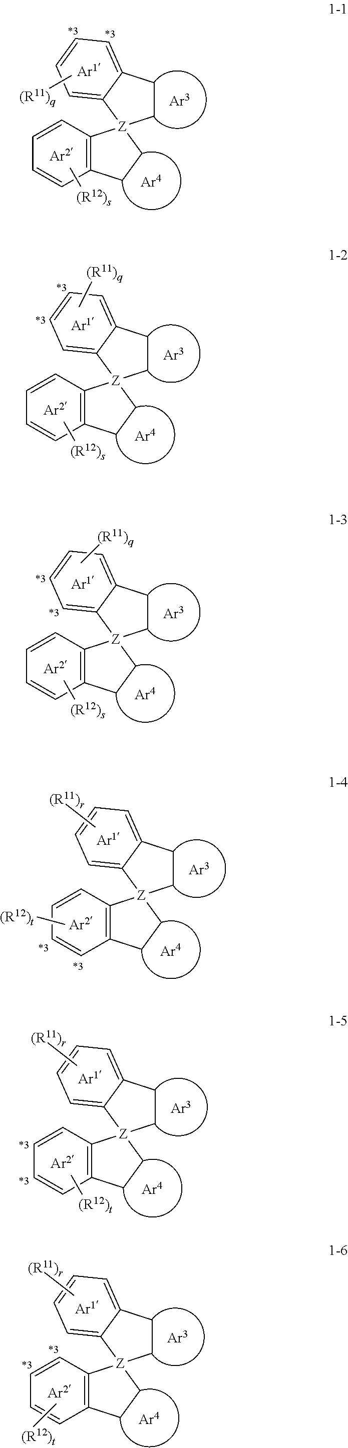
wherein, in Formulae 1-1 to 1-6,
R¹¹ and R¹² are each independently deuterium, a substituted or unsubstituted alkyl group, a substituted or unsubstituted aryl group, or a substituted or unsubstituted heteroaryl group,
q and t are each independently 0, 1, or 2, wherein, when q is 2, two R¹¹(s) are identical to or different from each other, and when t is 2, two R¹²(s) are identical to or different from each other,
s and r are each independently 0, 1, 2, 3, or 4, wherein, when s is 2 or more, two or more R¹²(s) are identical to or different from each other, and when r is 2 or more, two or more R¹¹(s) are identical to or different from each other,
binding sites *3 designate the adjacent ring-forming atoms that connect with the binding sites *1 in the polycyclic group represented by Formula 2, and
Ar³, Ar⁴, and Z are each as described in Formula 1.

6. The compound of claim 1, wherein the polycyclic group structure of Formula 2 is represented by Formula 4, and
at least one group structure, but not more than four group structures, each represented by Formula 5 are connected to at least one of ring Ar^{5′} or ring Ar⁶ in the structure represented by Formula 4: 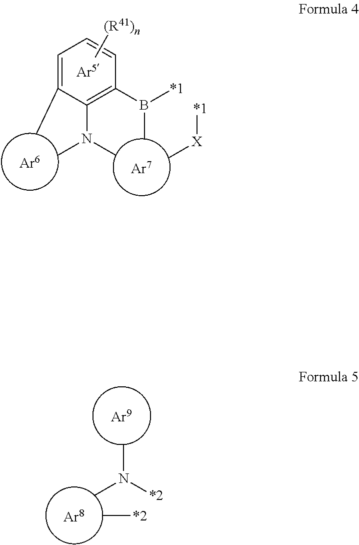
wherein, in Formula 4,
R⁴¹ is deuterium, a substituted or unsubstituted alkyl group, a substituted or unsubstituted aryl group, or a substituted or unsubstituted heteroaryl group,
n is 0, 1, 2, or 3, wherein, when n is 2 or more, two or more R⁴¹(s) are identical to or different from each other, and
Ar⁶, Ar⁷, X, and binding sites *1 are each as described in Formula 2,
wherein, in Formula 5,
Ar⁹ is a substituted or unsubstituted aromatic hydrocarbon ring having 6 to 30 ring-forming atoms or a substituted or unsubstituted heteroaromatic ring having 5 to 30 ring-forming atoms,
the binding sites *2 are bonded to the adjacent ring-forming atoms of Ar⁵, or the binding sites *2 are bonded to the adjacent ring-forming atoms of Ar⁶, in the structure represented by Formula 5, and
Ar⁸ is as described in Formula 3.

7. The compound of claim 6, comprising a group structure represented by Formula 6 that connects to the ring Ar¹ or the ring Ar² in the structure represented by Formula 1: 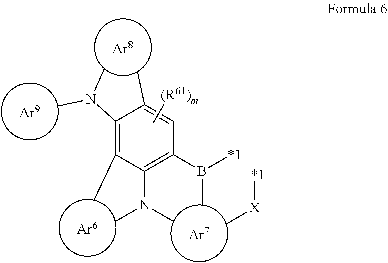
wherein, in Formula 6,
R⁶¹ is deuterium, a substituted or unsubstituted alkyl group, a substituted or unsubstituted aryl group, or a substituted or unsubstituted heteroaryl group,
m is 0 or 1,
Ar⁶, Ar⁷, X, and the binding sites *1 are each as described in Formula 2,
Ar⁸ is as described in Formula 3, and
Ar⁹ is as described in Formula 5.

8. The compound of claim 6, comprising a group structure represented by Formula 7 connected to the ring Ar¹ or the ring Ar² in the structure represented by Formula 1: 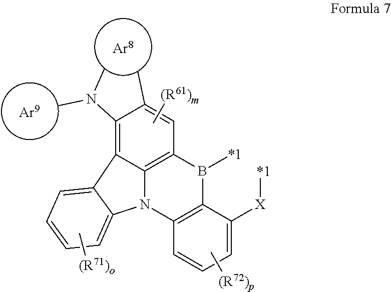
wherein, in Formula 7,
R⁷¹ and R⁷² are each independently deuterium, a substituted or unsubstituted alkyl group, a substituted or unsubstituted aryl group, or a substituted or unsubstituted heteroaryl group,
o is 0, 1, 2, 3, or 4, wherein, when o is 2 or more, two or more R⁷¹(s) are identical to or different from each other,
p is 0, 1, 2, or 3, wherein, when p is 2 or more, two or more R⁷²(s) are identical to or different from each other,
X and a binding site *1 are as described in Formula 2,
Ar⁸ is as described in Formula 3,
Ar⁹ is as described in Formula 5
R⁶¹ and m are as described in Formula 6.

9. The compound of claim 1, wherein, in Formula 2, X is —O— or —S—.

10. The compound of claim 1, wherein substituents substituted to the substituted aromatic hydrocarbon ring, the substituted heteroaromatic ring, the substituted alkyl group, the substituted aryl group, and the substituted heteroaryl group are each independently selected from:
a deuterium atom, a halogen atom, an alkyl group, an aryl group, a heteroaryl group, an alkoxy group, an aryloxy group, a heteroaryloxy group, a diarylamino group, a diheteroarylamino group, and an arylheteroarylamino group; and
an alkyl group, an aryl group, a heteroaryl group, an alkoxy group, an aryloxy group, a heteroaryloxy group, a diarylamino group, a diheteroarylamino group, and an arylheteroarylamino group, each of which is substituted with a deuterium atom, a halogen atom, an alkyl group, an aryl group, a heteroaryl group, an alkoxy group, an aryloxy group, a heteroaryloxy group, a diarylamino group, a diheteroarylamino group, an arylheteroarylamino group, or a combination thereof.

11. The compound of claim 1, represented by one of Compounds 1 to 109:

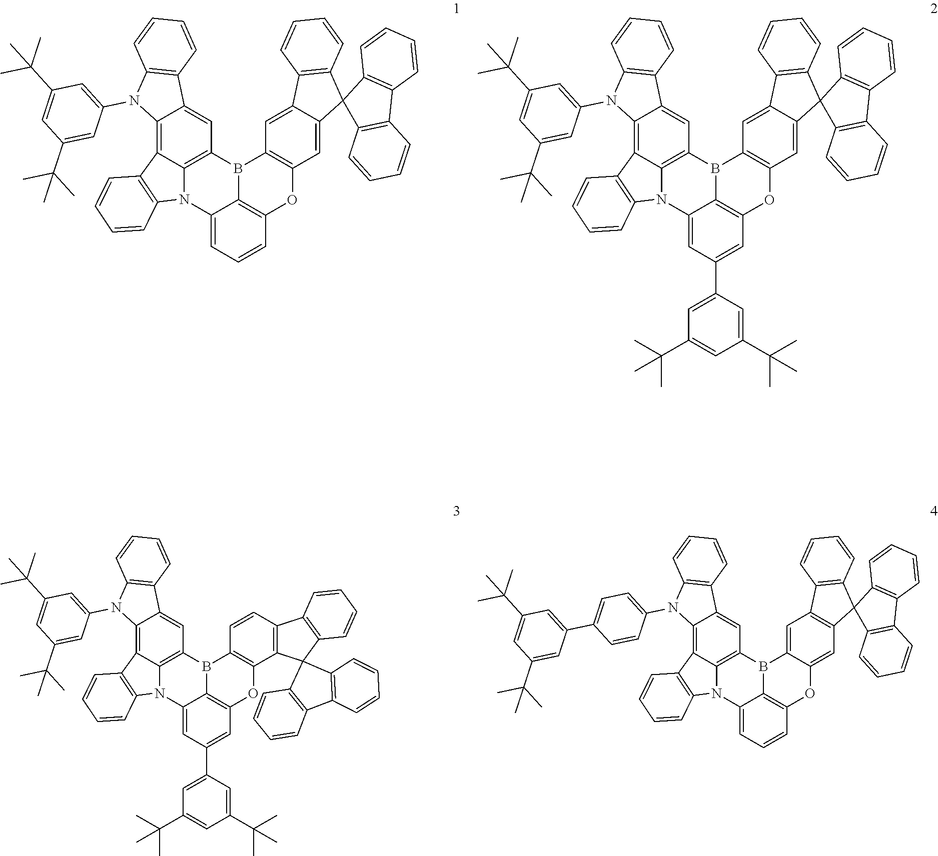

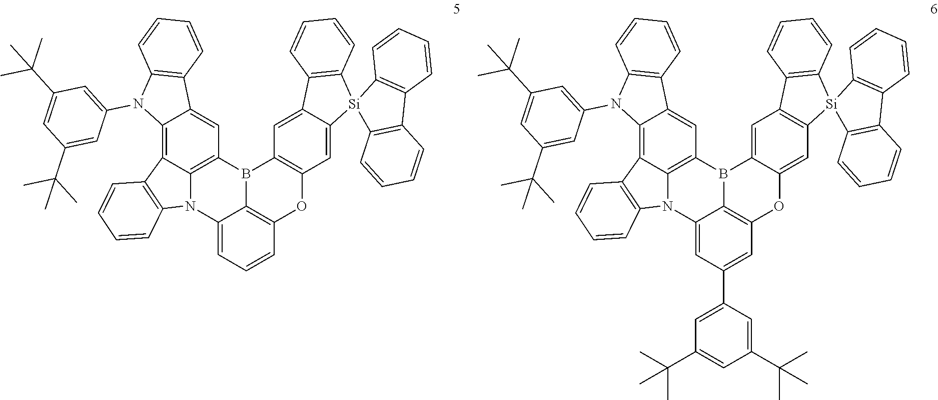 [SMILES: CC(C)(C)c1cc(-n2c3ccccc3c3cc4c5c(c6ccccc6n5-c5cccc6c5B4c4cc5c(cc4O6)[Si]4(c6ccccc6-c6ccccc64)c4ccccc4-5)c32)cc(C(C)(C)C)c1 ; CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2cc4c(cc2O3)[Si]2(c3ccccc3-c3ccccc32)c2ccccc2-4)cc(C(C)(C)C)c1]

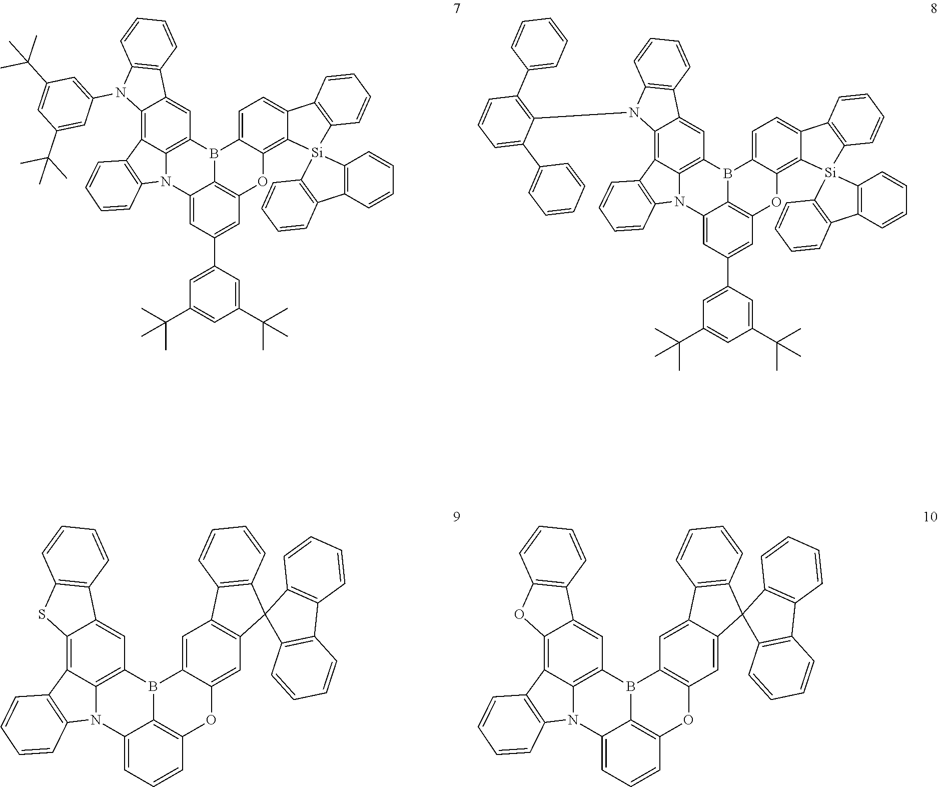 [SMILES: CC(C)(C)c1cc(-c2cc3c4c(c2)-n2c5ccccc5c5c2c(cc2c6ccccc6n(-c6cc(C(C)(C)C)cc(C(C)(C)C)c6)c25)B4c2ccc4c(c2O3)[Si]2(c3ccccc3-c3ccccc32)c2ccccc2-4)cc(C(C)(C)C)c1 ; CC(C)(C)c1cc(-c2cc3c4c(c2)-n2c5ccccc5c5c2c(cc2c6ccccc6n(-c6c(-c7ccccc7)cccc6-c6ccccc6)c25)B4c2ccc4c(c2O3)[Si]2(c3ccccc3-c3ccccc32)c2ccccc2-4)cc(C(C)(C)C)c1 ; c1ccc2c(c1)-c1ccccc1C21c2ccccc2-c2cc3c(cc21)Oc1cccc2c1B3c1cc3c4ccccc4sc3c3c4ccccc4n-2c13 ; c1ccc2c(c1)-c1ccccc1C21c2ccccc2-c2cc3c(cc21)Oc1cccc2c1B3c1cc3c4ccccc4oc3c3c4ccccc4n-2c13]

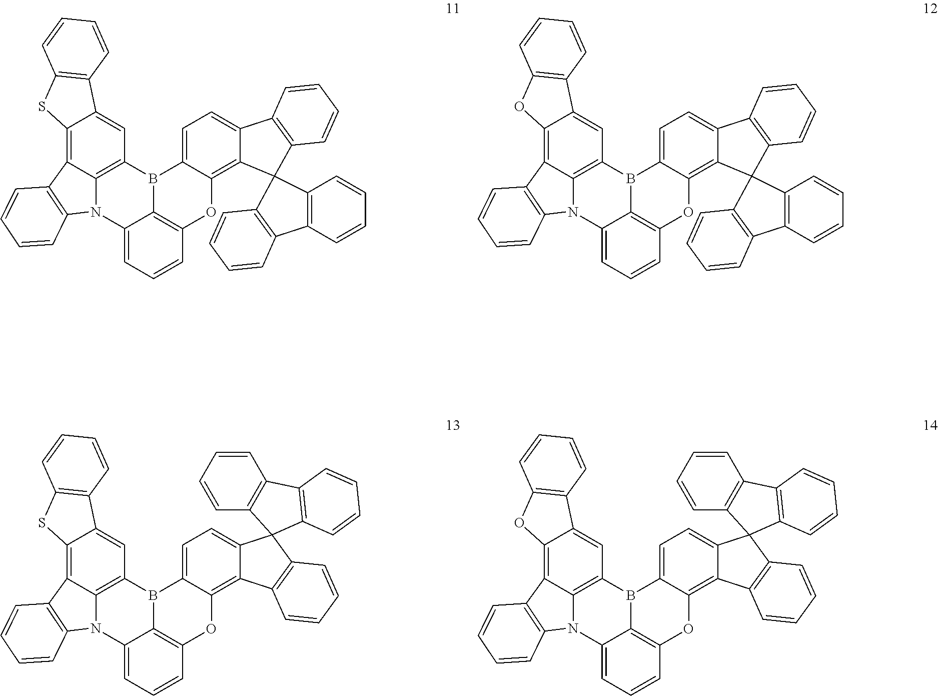 [SMILES: c1ccc2c(c1)-c1ccccc1C21c2ccccc2-c2ccc3c(c21)Oc1cccc2c1B3c1cc3c4ccccc4sc3c3c4ccccc4n-2c13 ; c1ccc2c(c1)-c1ccccc1C21c2ccccc2-c2ccc3c(c21)Oc1cccc2c1B3c1cc3c4ccccc4oc3c3c4ccccc4n-2c13 ; c1ccc2c(c1)-c1ccccc1C21c2ccccc2-c2c1ccc1c2Oc2cccc3c2B1c1cc2c4ccccc4sc2c2c4ccccc4n-3c12 ; c1ccc2c(c1)-c1ccccc1C21c2ccccc2-c2c1ccc1c2Oc2cccc3c2B1c1cc2c4ccccc4oc2c2c4ccccc4n-3c12]

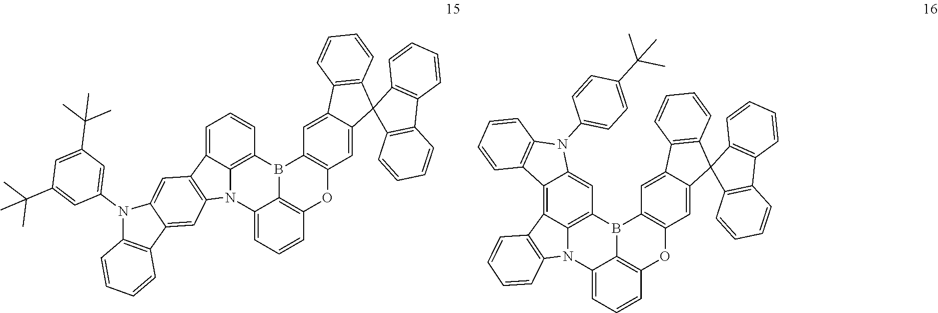 [SMILES: CC(C)(C)c1cc(-n2c3ccccc3c3cc4c(cc32)c2cccc3c2n4-c2cccc4c2B3c2cc3c(cc2O4)C2(c4ccccc4-c4ccccc42)c2ccccc2-3)cc(C(C)(C)C)c1 ; CC(C)(C)c1ccc(-n2c3ccccc3c3c4c5ccccc5n5c4c(cc32)B2c3cc4c(cc3Oc3cccc-5c32)C2(c3ccccc3-c3ccccc32)c2ccccc2-4)cc1]

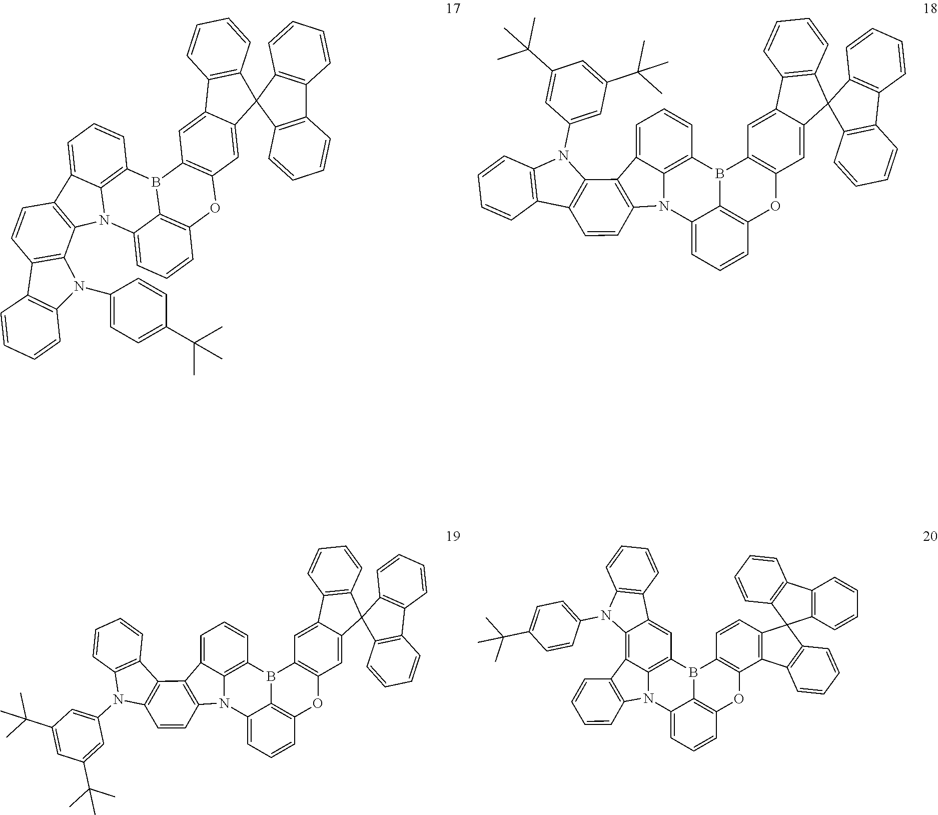 [SMILES: CC(C)(C)c1ccc(-n2c3ccccc3c3ccc4c5cccc6c5n(c4c32)-c2cccc3c2B6c2cc4c(cc2O3)C2(c3ccccc3-c3ccccc32)c2ccccc2-4)cc1 ; CC(C)(C)c1cc(-n2c3ccccc3c3ccc4c(c5cccc6c5n4-c4cccc5c4B6c4cc6c(cc4O5)C4(c5ccccc5-c5ccccc54)c4ccccc4-6)c32)cc(C(C)(C)C)c1 ; CC(C)(C)c1cc(-n2c3ccccc3c3c4c5cccc6c5n(c4ccc32)-c2cccc3c2B6c2cc4c(cc2O3)C2(c3ccccc3-c3ccccc32)c2ccccc2-4)cc(C(C)(C)C)c1 ; CC(C)(C)c1ccc(-n2c3ccccc3c3cc4c5c(c6ccccc6n5-c5cccc6c5B4c4ccc5c(c4O6)-c4ccccc4C54c5ccccc5-c5ccccc54)c32)cc1]

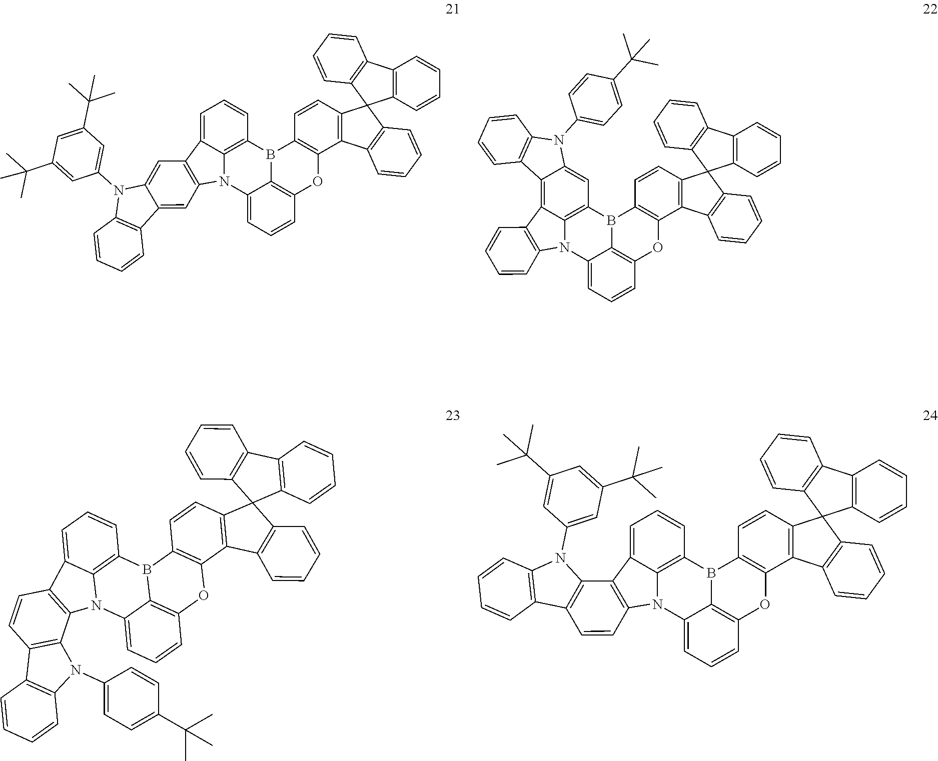 [SMILES: CC(C)(C)c1cc(-n2c3ccccc3c3cc4c(cc32)c2cccc3c2n4-c2cccc4c2B3c2ccc3c(c2O4)-c2ccccc2C32c3ccccc3-c3ccccc32)cc(C(C)(C)C)c1 ; CC(C)(C)c1ccc(-n2c3ccccc3c3c4c5ccccc5n5c4c(cc32)B2c3ccc4c(c3Oc3cccc-5c32)-c2ccccc2C42c3ccccc3-c3ccccc32)cc1 ; CC(C)(C)c1ccc(-n2c3ccccc3c3ccc4c5cccc6c5n(c4c32)-c2cccc3c2B6c2ccc4c(c2O3)-c2ccccc2C42c3ccccc3-c3ccccc32)cc1 ; CC(C)(C)c1cc(-n2c3ccccc3c3ccc4c(c5cccc6c5n4-c4cccc5c4B6c4ccc6c(c4O5)-c4ccccc4C64c5ccccc5-c5ccccc54)c32)cc(C(C)(C)C)c1]

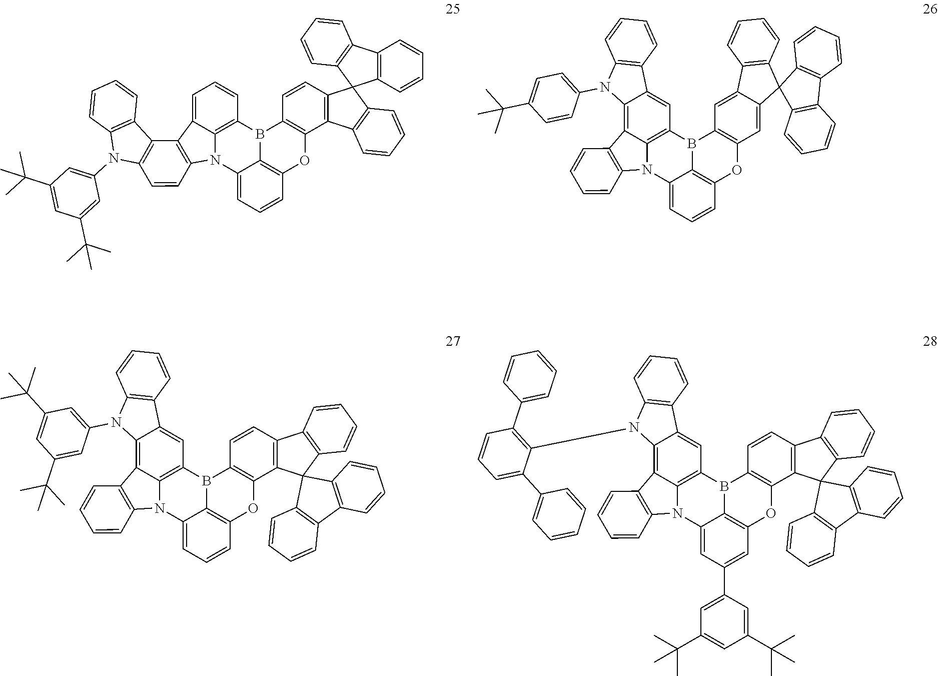

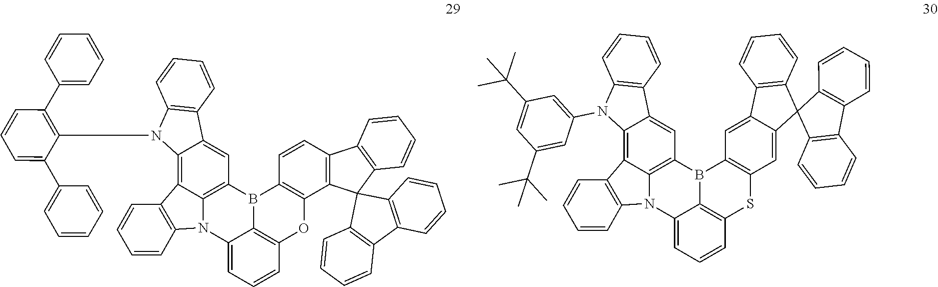 [SMILES: c1ccc(-c2cccc(-c3ccccc3)c2-n2c3ccccc3c3cc4c5c(c6ccccc6n5-c5cccc6c5B4c4ccc5c(c4O6)C4(c6ccccc6-c6ccccc64)c4ccccc4-5)c32)cc1 ; CC(C)(C)c1cc(-n2c3ccccc3c3cc4c5c(c6ccccc6n5-c5cccc6c5B4c4cc5c(cc4S6)C4(c6ccccc6-c6ccccc64)c4ccccc4-5)c32)cc(C(C)(C)C)c1]

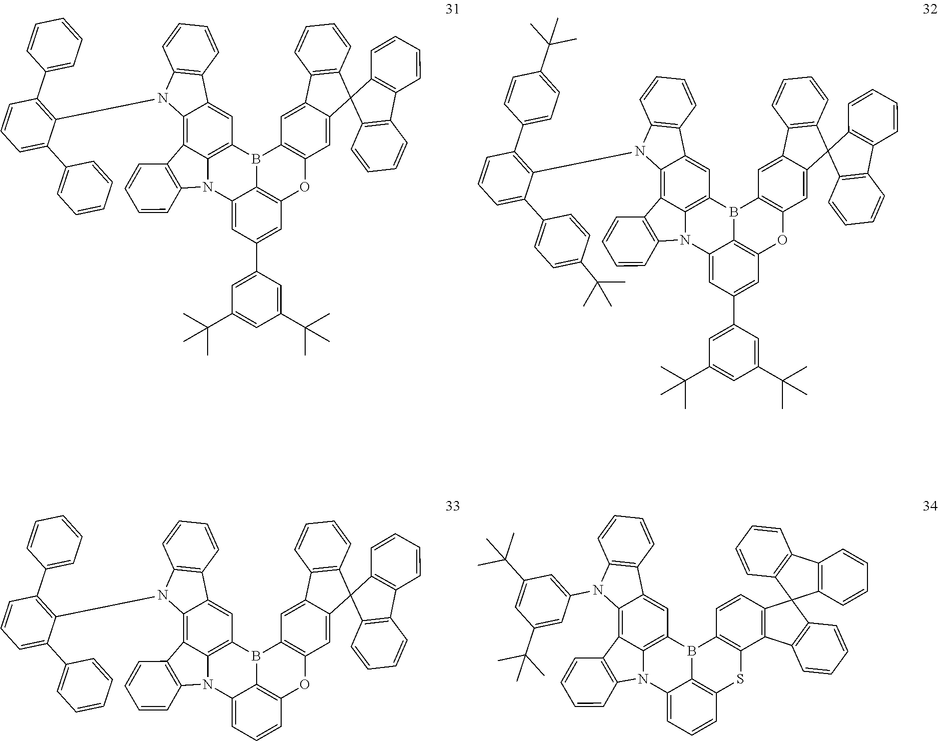

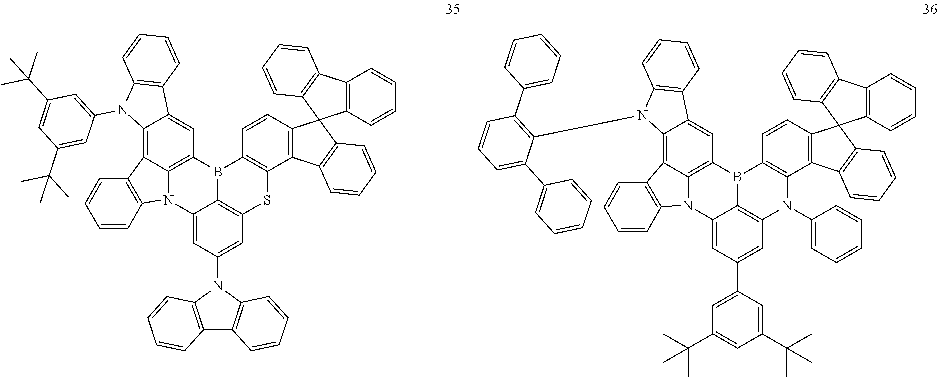 [SMILES: CC(C)(C)c1cc(-n2c3ccccc3c3cc4c5c(c6ccccc6n5-c5cc(-n6c7ccccc7c7ccccc76)cc6c5B4c4ccc5c(c4S6)-c4ccccc4C54c5ccccc5-c5ccccc54)c32)cc(C(C)(C)C)c1 ; CC(C)(C)c1cc(-c2cc3c4c(c2)-n2c5ccccc5c5c2c(cc2c6ccccc6n(-c6c(-c7ccccc7)cccc6-c6ccccc6)c25)B4c2ccc4c(c2N3c2ccccc2)-c2ccccc2C42c3ccccc3-c3ccccc32)cc(C(C)(C)C)c1]

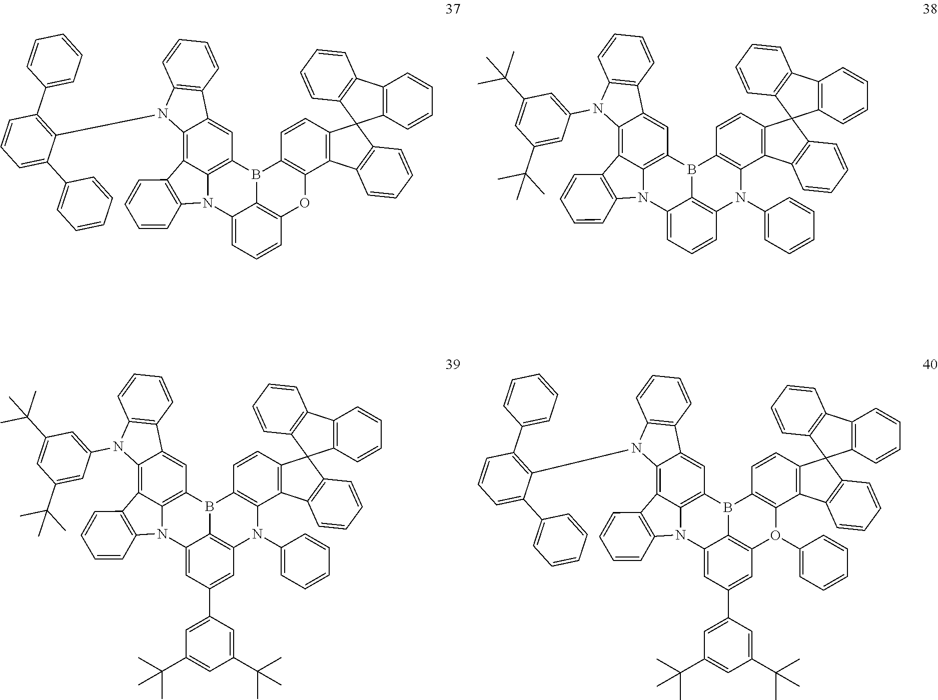

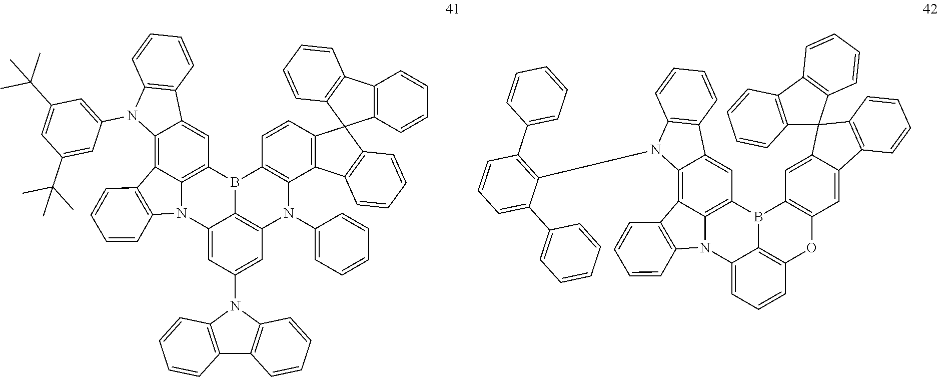 [SMILES: CC(C)(C)c1cc(-n2c3ccccc3c3cc4c5c(c6ccccc6n5-c5cc(-n6c7ccccc7c7ccccc76)cc6c5B4c4ccc5c(c4N6c4ccccc4)-c4ccccc4C54c5ccccc5-c5ccccc54)c32)cc(C(C)(C)C)c1 ; c1ccc(-c2cccc(-c3ccccc3)c2-n2c3ccccc3c3cc4c5c(c6ccccc6n5-c5cccc6c5B4c4cc5c(cc4O6)-c4ccccc4C54c5ccccc5-c5ccccc54)c32)cc1]

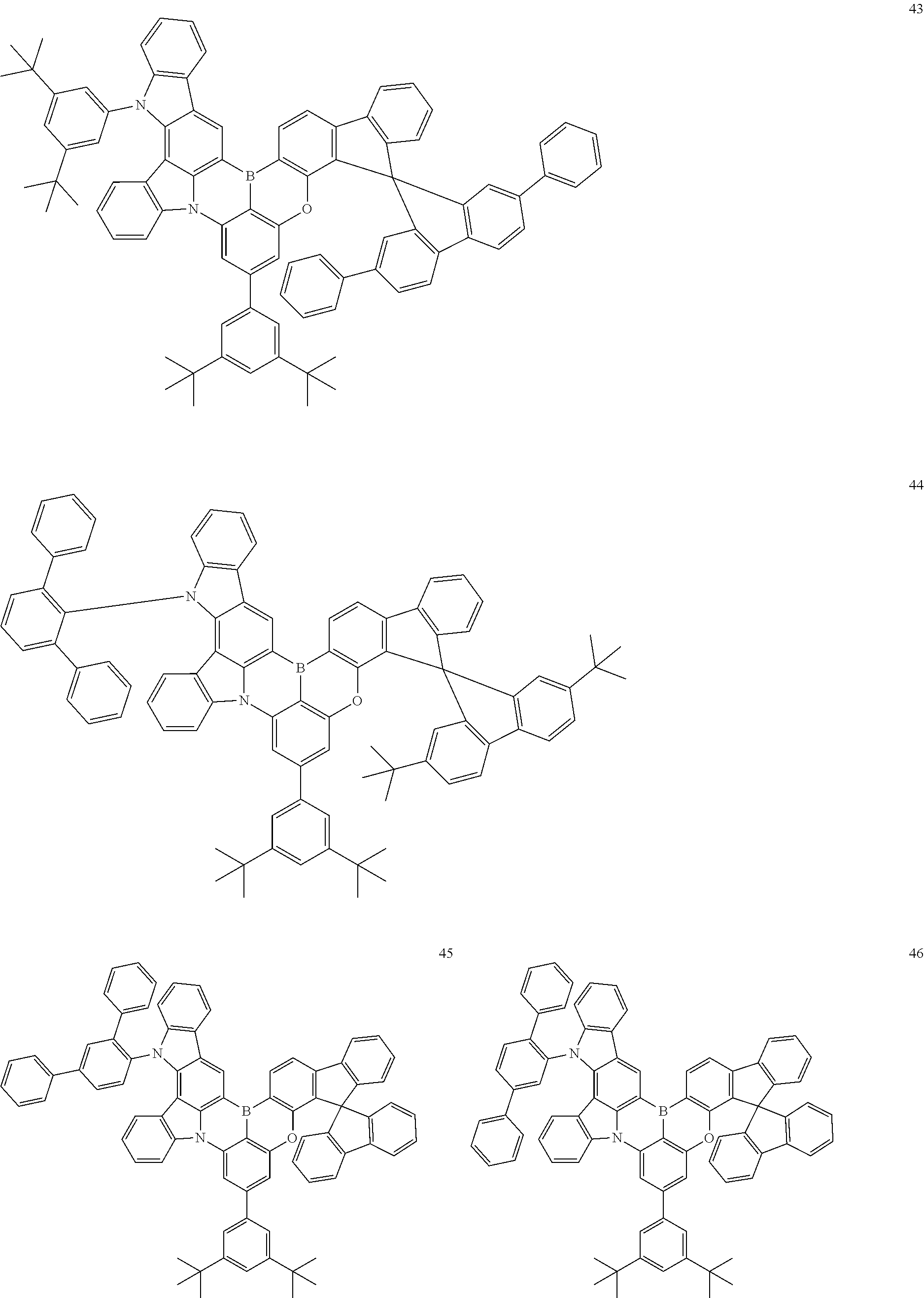

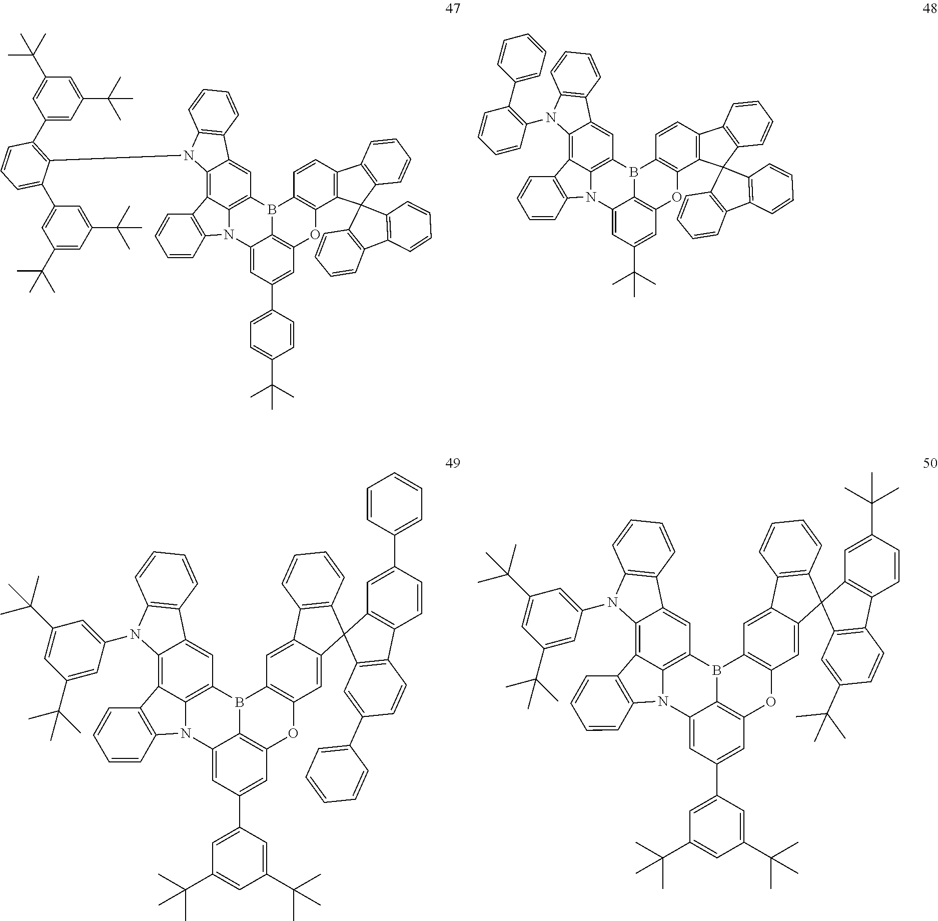

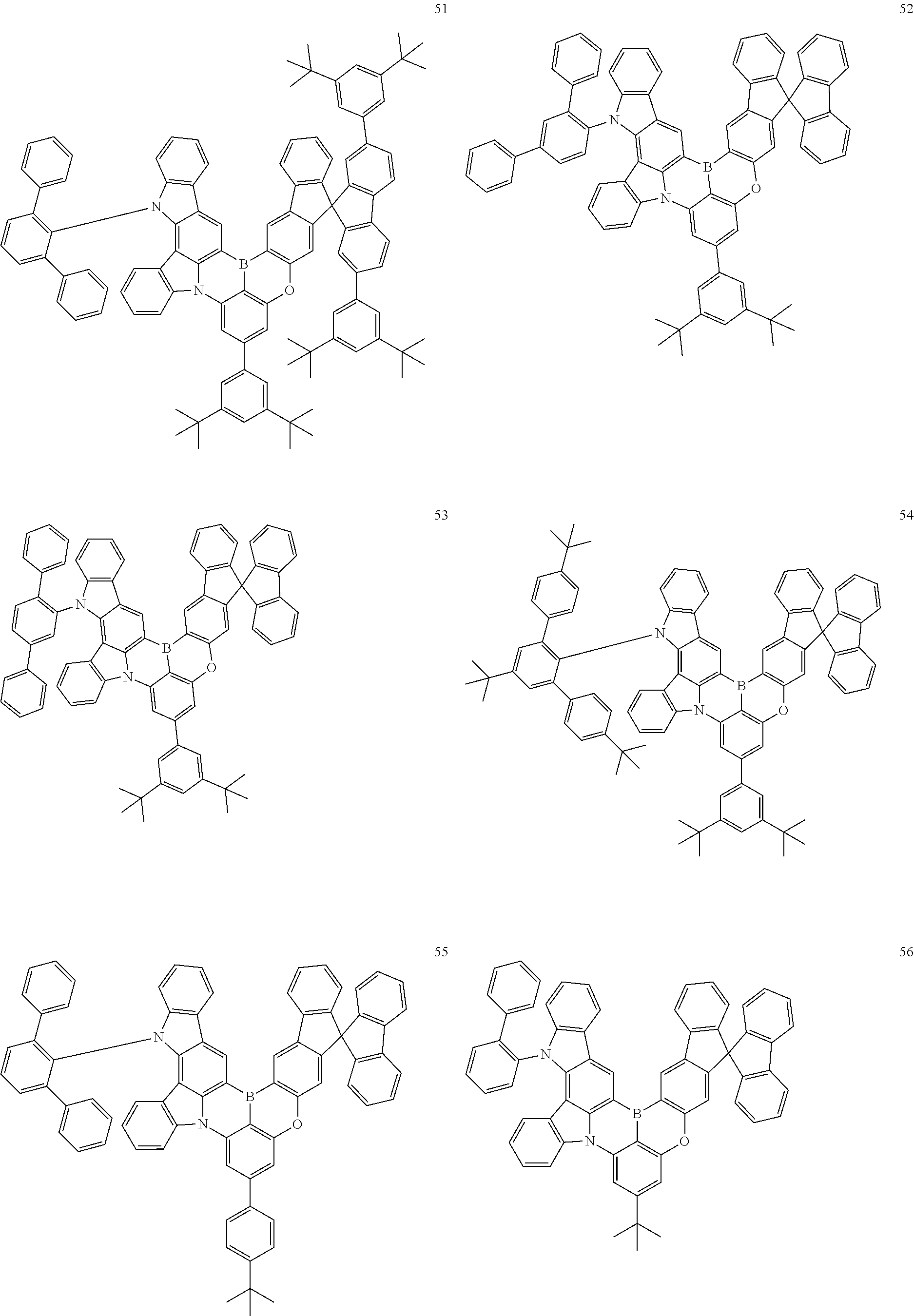

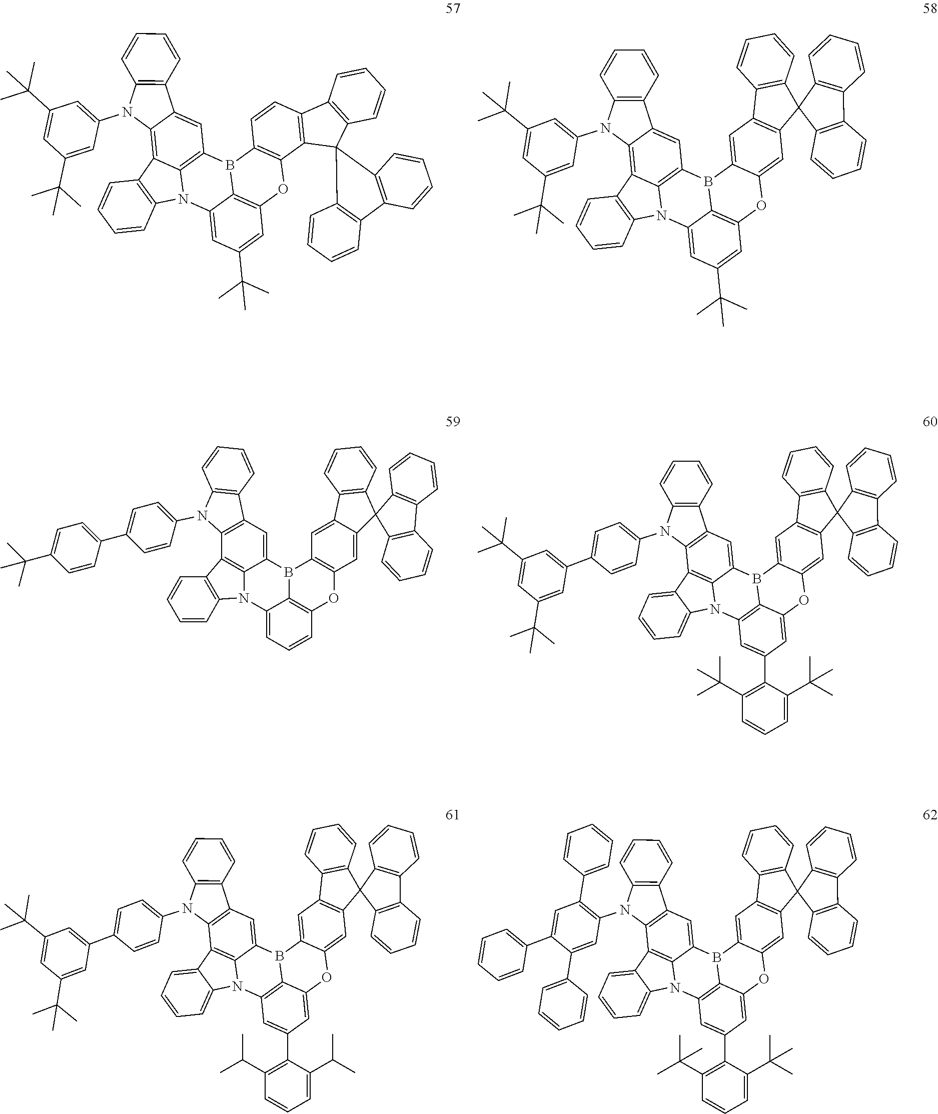

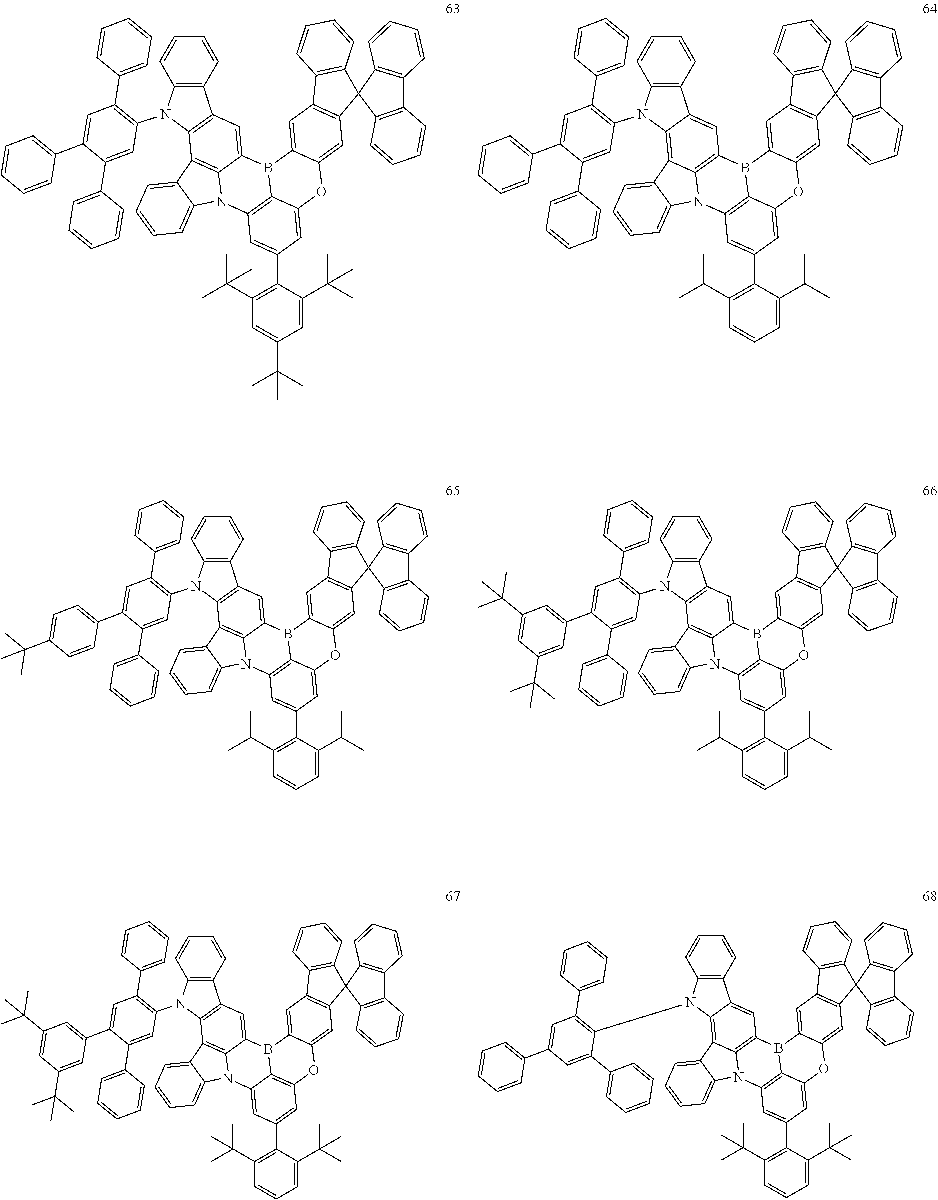

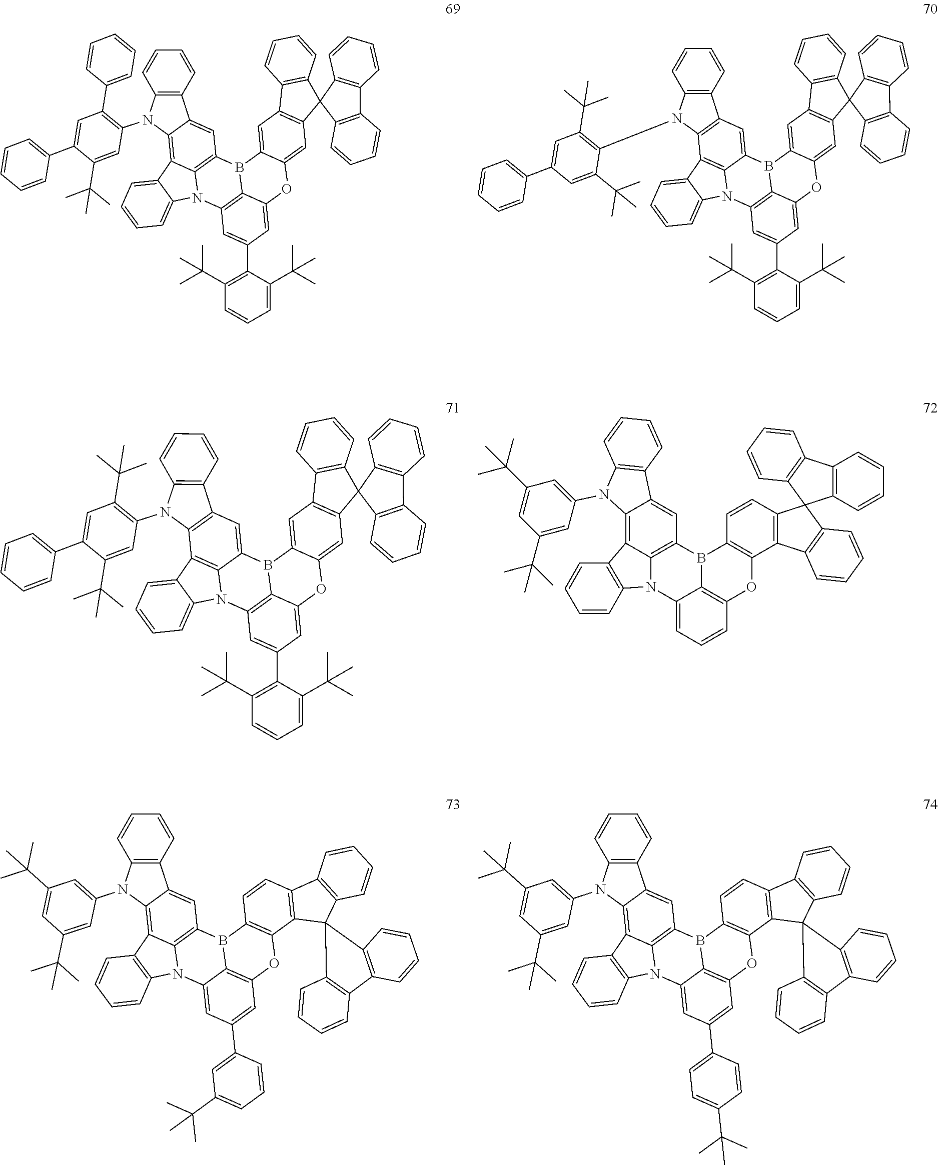

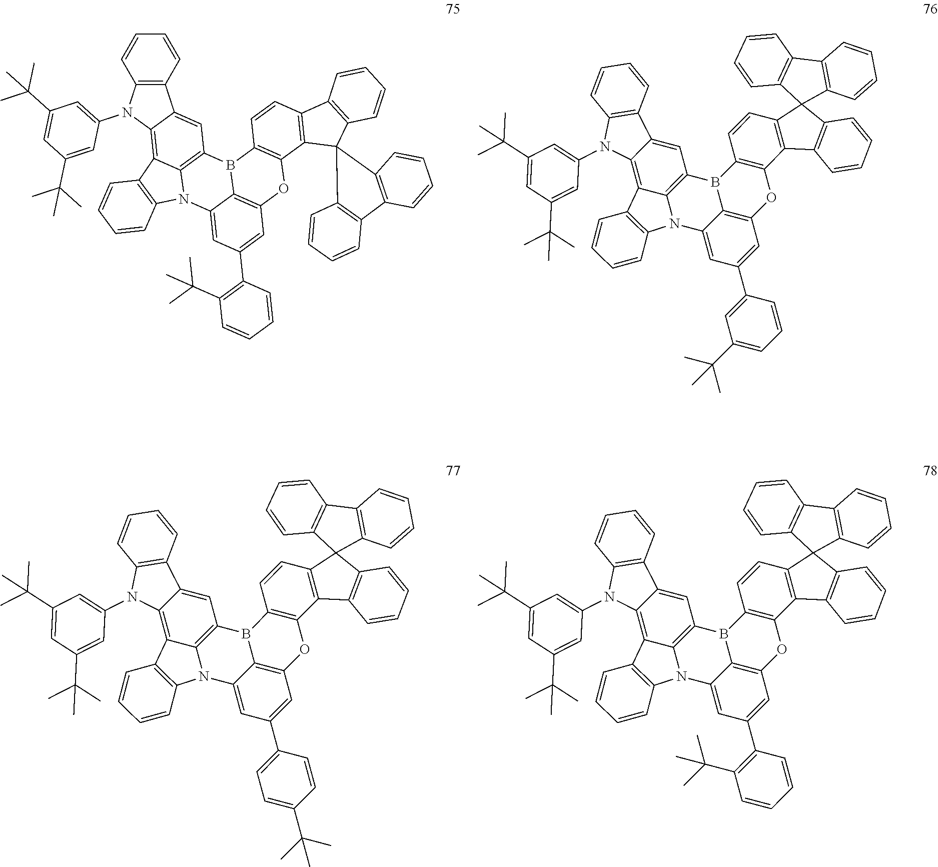

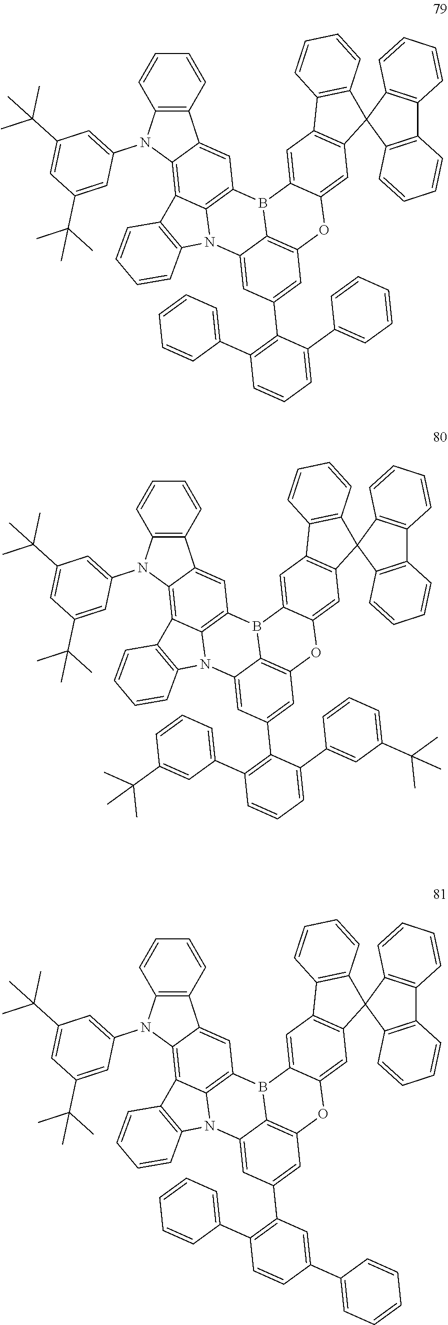

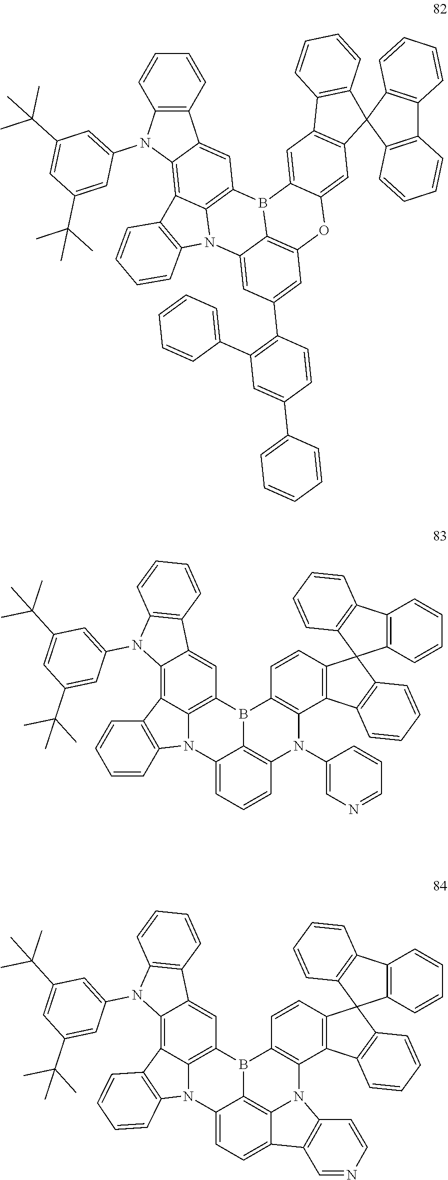 [SMILES: CC(C)(C)c1cc(-n2c3ccccc3c3cc4c5c(c6ccccc6n5-c5cc(-c6ccc(-c7ccccc7)cc6-c6ccccc6)cc6c5B4c4cc5c(cc4O6)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cccc6c5B4c4ccc5c(c4N6c4cccnc4)-c4ccccc4C54c5ccccc5-c5ccccc54)c32)cc(C(C)(C)C)c1 ; CC(C)(C)c1cc(-n2c3ccccc3c3cc4c5c(c6ccccc6n5-c5ccc6c7cnccc7n7c6c5B4c4ccc5c(c4-7)-c4ccccc4C54c5ccccc5-c5ccccc54)c32)cc(C(C)(C)C)c1]

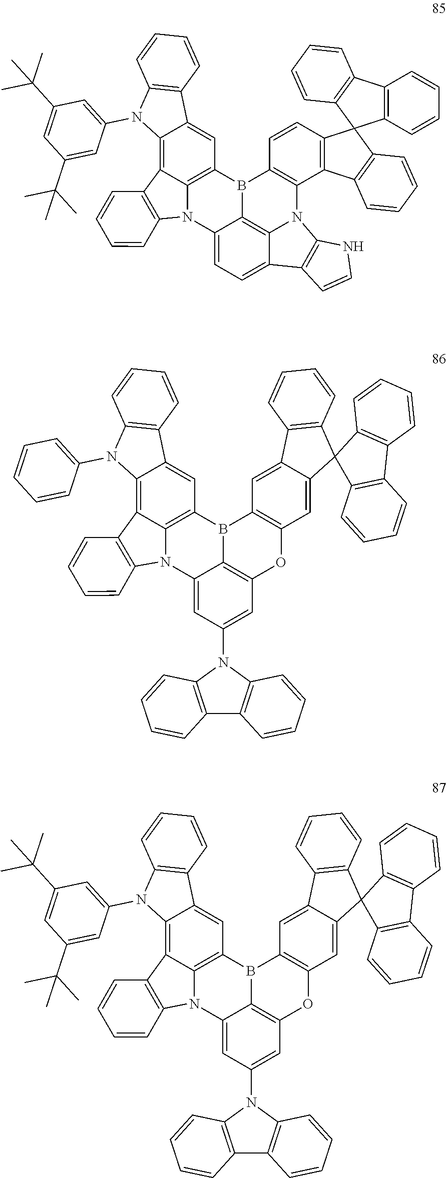 [SMILES: CC(C)(C)c1cc(-n2c3ccccc3c3cc4c5c(c6ccccc6n5-c5ccc6c7cc[nH]c7n7c6c5B4c4ccc5c(c4-7)-c4ccccc4C54c5ccccc5-c5ccccc54)c32)cc(C(C)(C)C)c1 ; c1ccc(-n2c3ccccc3c3cc4c5c(c6ccccc6n5-c5cc(-n6c7ccccc7c7ccccc76)cc6c5B4c4cc5c(cc4O6)C4(c6ccccc6-c6ccccc64)c4ccccc4-5)c32)cc1 ; CC(C)(C)c1cc(-n2c3ccccc3c3cc4c5c(c6ccccc6n5-c5cc(-n6c7ccccc7c7ccccc76)cc6c5B4c4cc5c(cc4O6)C4(c6ccccc6-c6ccccc64)c4ccccc4-5)c32)cc(C(C)(C)C)c1]

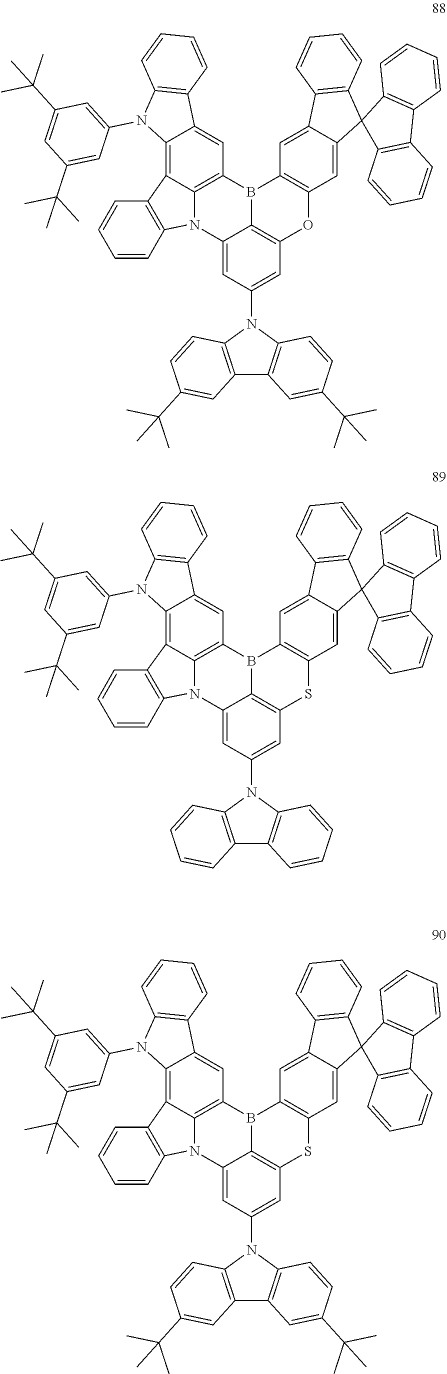 [SMILES: CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4O6)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccccc7c7ccccc76)cc6c5B4c4cc5c(cc4S6)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4S6)C4(c6ccccc6-c6ccccc64)c4ccccc4-5)c32)cc(C(C)(C)C)c1]

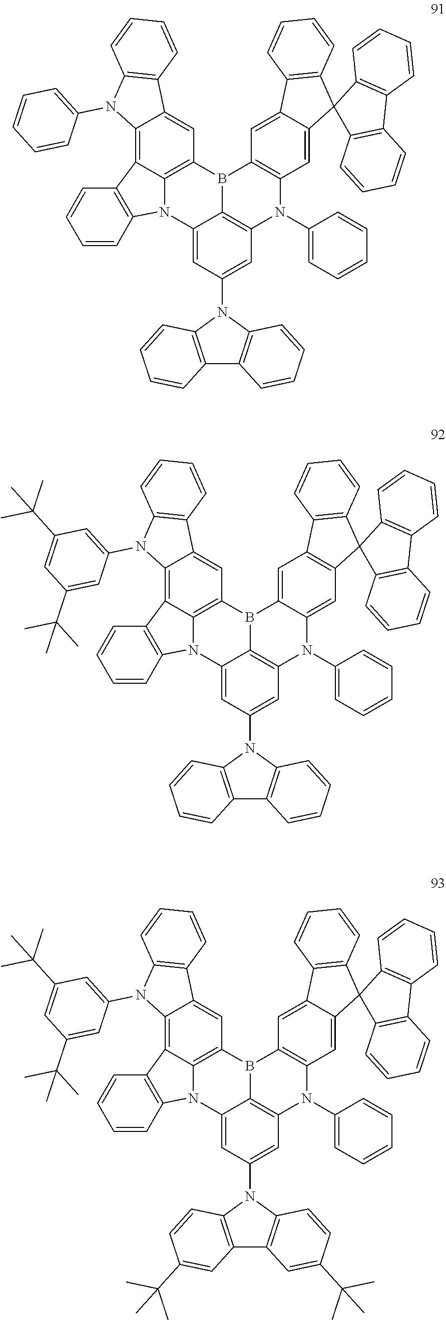 [SMILES: c1ccc(N2c3cc4c(cc3B3c5c2cc(-n2c6ccccc6c6ccccc62)cc5-n2c5ccccc5c5c2c3cc2c3ccccc3n(-c3ccccc3)c25)-c2ccccc2C42c3ccccc3-c3ccccc32)cc1 ; CC(C)(C)c1cc(-n2c3ccccc3c3cc4c5c(c6ccccc6n5-c5cc(-n6c7ccccc7c7ccccc76)cc6c5B4c4cc5c(cc4N6c4ccccc4)C4(c6ccccc6-c6ccccc64)c4ccccc4-5)c32)cc(C(C)(C)C)c1 ; CC(C)(C)c1cc(-n2c3ccccc3c3cc4c5c(c6ccccc6n5-c5cc(-n6c7ccc(C(C)(C)C)cc7c7cc(C(C)(C)C)ccc76)cc6c5B4c4cc5c(cc4N6c4ccccc4)C4(c6ccccc6-c6ccccc64)c4ccccc4-5)c32)cc(C(C)(C)C)c1]

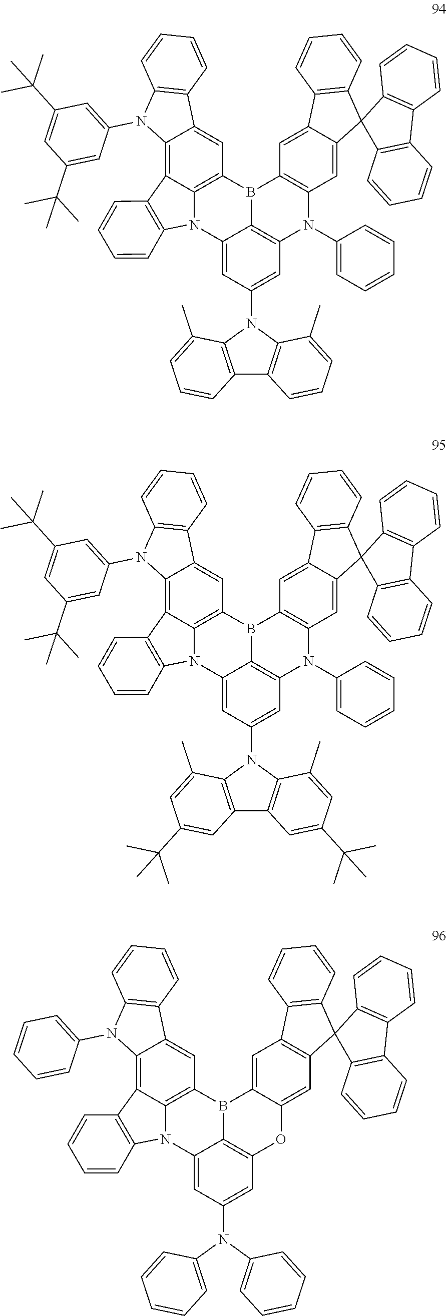 [SMILES: Cc1cccc2c3cccc(C)c3n(-c3cc4c5c(c3)-n3c6ccccc6c6c3c(cc3c7ccccc7n(-c7cc(C(C)(C)C)cc(C(C)(C)C)c7)c36)B5c3cc5c(cc3N4c3ccccc3)C3(c4ccccc4-c4ccccc43)c3ccccc3-5)c12 ; Cc1cc(C(C)(C)C)cc2c3cc(C(C)(C)C)cc(C)c3n(-c3cc4c5c(c3)-n3c6ccccc6c6c3c(cc3c7ccccc7n(-c7cc(C(C)(C)C)cc(C(C)(C)C)c7)c36)B5c3cc5c(cc3N4c3ccccc3)C3(c4ccccc4-c4ccccc43)c3ccccc3-5)c12 ; c1ccc(N(c2ccccc2)c2cc3c4c(c2)-n2c5ccccc5c5c2c(cc2c6ccccc6n(-c6ccccc6)c25)B4c2cc4c(cc2O3)C2(c3ccccc3-c3ccccc32)c2ccccc2-4)cc1]

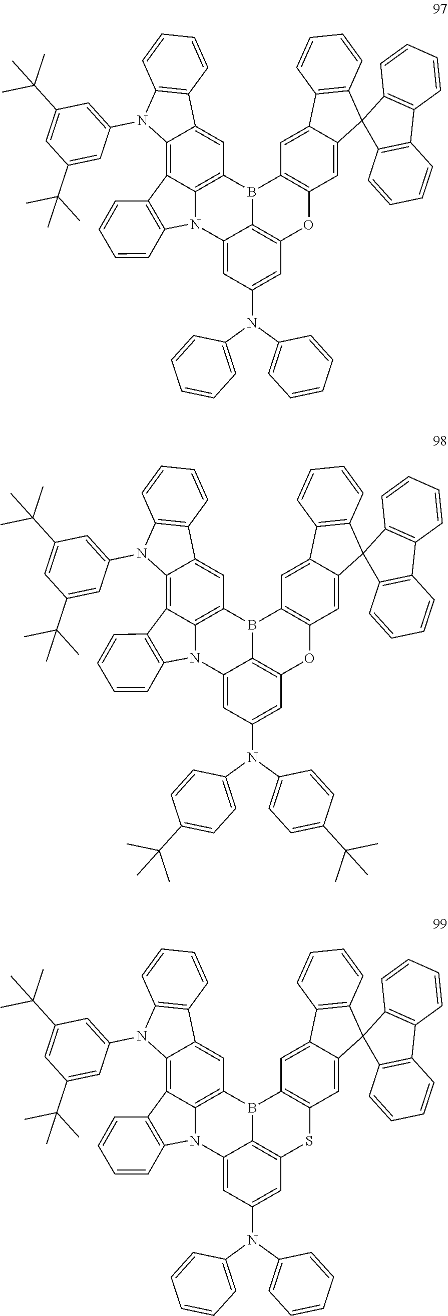 [SMILES: CC(C)(C)c1cc(-n2c3ccccc3c3cc4c5c(c6ccccc6n5-c5cc(N(c6ccccc6)c6ccccc6)cc6c5B4c4cc5c(cc4O6)C4(c6ccccc6-c6ccccc64)c4ccccc4-5)c32)cc(C(C)(C)C)c1 ; CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2O3)C2(c3ccccc3-c3ccccc32)c2ccccc2-4)cc1 ; CC(C)(C)c1cc(-n2c3ccccc3c3cc4c5c(c6ccccc6n5-c5cc(N(c6ccccc6)c6ccccc6)cc6c5B4c4cc5c(cc4S6)C4(c6ccccc6-c6ccccc64)c4ccccc4-5)c32)cc(C(C)(C)C)c1]

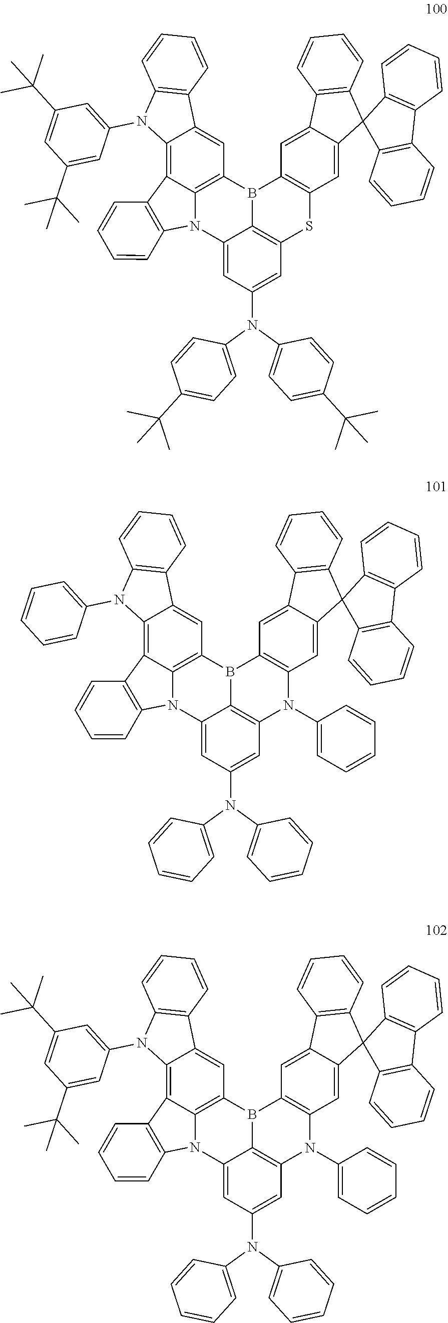 [SMILES: CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2S3)C2(c3ccccc3-c3ccccc32)c2ccccc2-4)cc1 ; c1ccc(N(c2ccccc2)c2cc3c4c(c2)-n2c5ccccc5c5c2c(cc2c6ccccc6n(-c6ccccc6)c25)B4c2cc4c(cc2N3c2ccccc2)C2(c3ccccc3-c3ccccc32)c2ccccc2-4)cc1 ; CC(C)(C)c1cc(-n2c3ccccc3c3cc4c5c(c6ccccc6n5-c5cc(N(c6ccccc6)c6ccccc6)cc6c5B4c4cc5c(cc4N6c4ccccc4)C4(c6ccccc6-c6ccccc64)c4ccccc4-5)c32)cc(C(C)(C)C)c1]

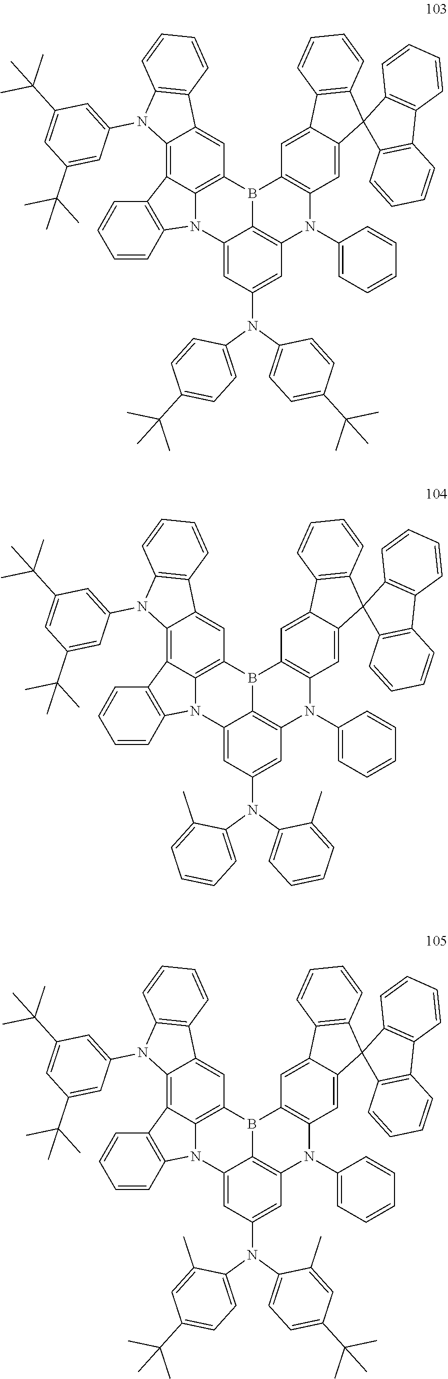 [SMILES: CC(C)(C)c1ccc(N(c2ccc(C(C)(C)C)cc2)c2cc3c4c(c2)-n2c5ccccc5c5c2c(cc2c6ccccc6n(-c6cc(C(C)(C)C)cc(C(C)(C)C)c6)c25)B4c2cc4c(cc2N3c2ccccc2)C2(c3ccccc3-c3ccccc32)c2ccccc2-4)cc1 ; Cc1ccccc1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1ccccc1C ; Cc1cc(C(C)(C)C)ccc1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1ccc(C(C)(C)C)cc1C]

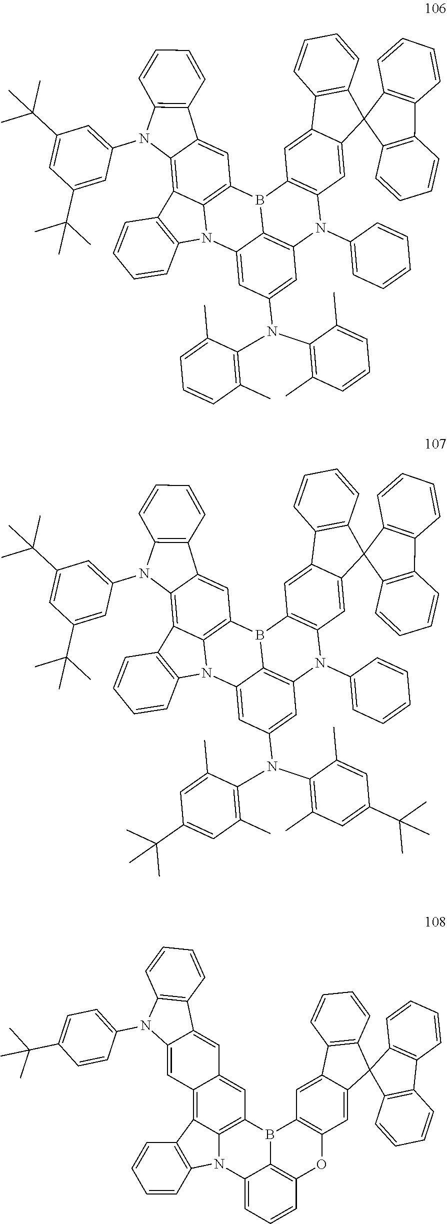 [SMILES: Cc1cccc(C)c1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1c(C)cccc1C ; Cc1cc(C(C)(C)C)cc(C)c1N(c1cc2c3c(c1)-n1c4ccccc4c4c1c(cc1c5ccccc5n(-c5cc(C(C)(C)C)cc(C(C)(C)C)c5)c14)B3c1cc3c(cc1N2c1ccccc1)C1(c2ccccc2-c2ccccc21)c1ccccc1-3)c1c(C)cc(C(C)(C)C)cc1C ; CC(C)(C)c1ccc(-n2c3ccccc3c3cc4cc5c6c(c4cc32)c2ccccc2n6-c2cccc3c2B5c2cc4c(cc2O3)C2(c3ccccc3-c3ccccc32)c2ccccc2-4)cc1]

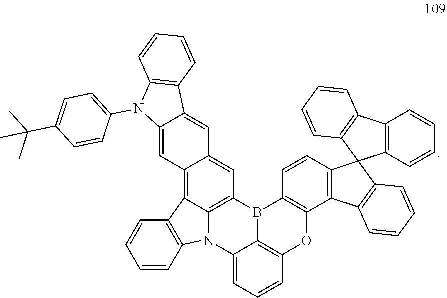 [SMILES: CC(C)(C)c1ccc(-n2c3ccccc3c3cc4cc5c6c(c4cc32)c2ccccc2n6-c2cccc3c2B5c2ccc4c(c2O3)-c2ccccc2C42c3ccccc3-c3ccccc32)cc1]

12. The compound of claim 1, having a peak emission wavelength in a blue region.

13. A composition comprising one or more compounds of claim 1.

14. The composition of claim 13, further comprising at least one of a thermally activated delayed fluorescence material and a phosphorescent material.

15. The composition of claim 14, wherein the phosphorescent material is a platinum complex.

16. A material for an organic electroluminescent device, the material comprising one or more compounds of claim 1.

17. The material of claim 16, further comprising:
a host material; and
a thermally activated delayed fluorescence material or a phosphorescent material.

18. An organic electroluminescent device having an organic layer comprising one or more compounds of claim 1.

19. The organic electroluminescent device of claim 18, wherein the organic layer includes an emission layer, and
the emission layer comprises the one or more compounds.

20. The organic electroluminescent device of claim 19, wherein the emission layer comprises a host material and a dopant material, and
the dopant material comprises the one or more compounds.
